(19) United States
(12) Patent Application Publication
(10) Pub. No.: US 2025/0374625 A1
(43) Pub. Date: Dec. 4, 2025

(54) TRANSISTOR

(71) Applicant: Semiconductor Energy Laboratory Co., Ltd., Atsugi-shi (JP)

(72) Inventors: Shunpei YAMAZAKI, Setagaya (JP); Hiromi SAWAI, Kawasaki (JP); Ryosuke MOTOYOSHI, Hadano (JP); Fumito ISAKA, Zama (JP); Takanori MATSUZAKI, Atsugi (JP)

(21) Appl. No.: 19/220,712

(22) Filed: May 28, 2025

(30) Foreign Application Priority Data
Jun. 4, 2024 (JP) 2024-091007
Jul. 4, 2024 (JP) 2024-107923
Jul. 12, 2024 (JP) 2024-112390

(51) Int. Cl. H10D 62/40; H10B 12/00; H10D 1/68; H10D 30/01; H10D 30/67; H10D 86/60

(52) U.S. Cl. CPC H10D 62/405; H10D 30/6728; H10D 30/6731; H10D 30/6736; H10D 30/6755; H10D 30/6757; H10B 12/33; H10D 1/714; H10D 1/716; H10D 30/0318; H10D 86/60

(57) ABSTRACT

A transistor having excellent electrical characteristics is provided. The transistor includes an indium oxide film and a metal oxide film over the indium oxide film. A region of the indium oxide film where a channel is formed is a single crystal. The metal oxide film contains indium, gallium, and zinc. The <111> orientation of the single crystal region of the indium oxide film is parallel or substantially parallel to the <001> orientation of a crystal in the metal oxide film. The indium oxide film can be provided over a silicon oxide film or a silicon nitride film. Alternatively, the indium oxide film can be provided over a metal oxide film containing indium, tin, and silicon.

### BACKGROUND OF THE INVENTION

### 1. Field of the Invention

One embodiment of the present invention relates to a transistor, a semiconductor device, a memory device, a display device, and an electronic device. One embodiment of the present invention also relates to methods for fabricating a transistor and a semiconductor device.

Note that one embodiment of the present invention is not limited to the above technical field. Examples of the technical field of one embodiment of the present invention include a semiconductor device, a display device, a light-emitting device, a power storage device, a memory device, an electronic device, a lighting device, an input device (e.g., a touch sensor), an input/output device (e.g., a touch panel), a method for driving any of them, and a method for manufacturing any of them.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display device, a light-emitting device, a lighting device, and an electronic device themselves are semiconductor devices and also include a semiconductor device.

### 2. Description of the Related Art

A technique by which a transistor is formed using a semiconductor thin film formed over a substrate having an insulating surface has been attracting attention. The transistor is used in a wide range of electronic devices such as an integrated circuit (IC) and a display device. As semiconductor materials usable for the transistor, silicon-based semiconductor materials have been widely used, but oxide semiconductors have been attracting attention as alternative materials.

A transistor including an oxide semiconductor is known to have an extremely low leakage current in the off state. For example, Patent Document 1 discloses a low-power-consumption central processing unit (CPU) utilizing a characteristic of a low leakage current of the transistor including an oxide semiconductor. For another example, Patent Document 2 discloses a memory device that can retain stored data for a long time by utilizing a characteristic of a low leakage current of the transistor including an oxide semiconductor.

Examples of an oxide semiconductor that can be used for an active layer of a transistor include indium oxide and indium gallium zinc oxide. Non-Patent Document 1 discloses a thin film transistor in which hydrogenated polycrystalline indium oxide formed by low-temperature solid phase crystallization is used for an active layer.

### REFERENCES

### Patent Documents

[Patent Document 1] Japanese Published Patent Application No. 2012-257187
[Patent Document 2] Japanese Published Patent Application No. 2011-151383

### Non-Patent Documents

[Non-Patent Document 1] Y. Magari, et al., “High-mobility hydrogenated polycrystalline In₂O₃ (In₂O₃:H) thin-film transistors”, Nature Communications, 13, 1078 (2022) [Non-Patent Document 2] Takashi Koida, “High-mobility transparent conductive film”, National Institute of Advanced Industrial Science and Technology, AIST Photovoltaic Technology Research Symposium 2019, Internet URL: https://unit.aist.go.jp/rpd-envene/PV/ja/results/2019/oral/T13.pdf [Non-Patent Document 3] C. Chen and S. P. Ong, “A universal graph deep learning interatomic potential for the periodic table”, Nat. Comput. Sci., 2, 2022, pp. 718-728

### SUMMARY OF THE INVENTION

An object of one embodiment of the present invention is to provide a transistor with excellent electrical characteristics. An object of one embodiment of the present invention is to provide a transistor with a high on-state current. An object of one embodiment of the present invention is to provide a transistor with small parasitic capacitance. An object of one embodiment of the present invention is to provide a highly reliable transistor, semiconductor device, memory device, or display device. An object of one embodiment of the present invention is to provide a transistor, a semiconductor device, or a memory device which can be scaled down or highly integrated. An object of one embodiment of the present invention is to provide a semiconductor device, a memory device, or a display device with low power consumption. An object of one embodiment of the present invention is to provide a memory device with high operating speed. An object of one embodiment of the present invention is to provide a display device with a high resolution or a high aperture ratio. An object of one embodiment of the present invention is to provide a method for fabricating the above-described transistor, semiconductor device, memory device, or display device.

Note that the description of these objects does not preclude the existence of other objects. One embodiment of the present invention does not necessarily achieve all of these objects. Other objects can be derived from the description of the specification, the drawings, and the claims.

One embodiment of the present invention is a transistor including an indium oxide film and a metal oxide film over the indium oxide film. A region of the indium oxide film where a channel is formed is a single crystal. The metal oxide film contains indium, gallium, and zinc. A<111>orientation of the single crystal region of the indium oxide film is parallel or substantially parallel to a <001> orientation of a crystal in the metal oxide film.

One embodiment of the present invention is a transistor including an indium oxide film and a metal oxide film over the indium oxide film. A crystal grain boundary is not observed in a region of the indium oxide film where a channel is formed. The metal oxide film contains indium, gallium, and zinc. A<111> orientation of a crystal in the indium oxide film is parallel or substantially parallel to a <001> orientation of a crystal in the metal oxide film.

In the above-described transistor, the indium oxide film is preferably provided over a silicon oxide film or a silicon nitride film.

One embodiment of the present invention is a transistor including a first metal oxide film over a substrate and an indium oxide film over the first metal oxide film. A<001> orientation of a crystal in the first metal oxide film is perpendicular or substantially perpendicular to a surface of the substrate. A crystal grain boundary is not observed in a region of the indium oxide film where a channel is formed. A resistivity of the first metal oxide film is lower than a resistivity of the indium oxide film.

One embodiment of the present invention is a transistor including a first metal oxide film over a substrate and an indium oxide film over the first metal oxide film. The first metal oxide film contains indium and tin. A crystal grain boundary is not observed in a region of the indium oxide film where a channel is formed. A resistivity of the first metal oxide film is lower than a resistivity of the indium oxide film.

In the above-described transistor, it is preferable that a <111> orientation of a crystal in the indium oxide film be perpendicular or substantially perpendicular to the surface of the substrate.

It is preferable that the above-described transistor include a second metal oxide film over the indium oxide film, the second metal oxide film contain indium, gallium, and zinc, and a <001>orientation of a crystal in the second metal oxide film be perpendicular or substantially perpendicular to the surface of the substrate.

One embodiment of the present invention is a transistor including a first indium oxide film over a substrate and a second indium oxide film over the first indium oxide film. A crystal axis of a crystal in the second indium oxide film is aligned or substantially aligned with a crystal axis of a crystal in the first indium oxide film. A resistivity of the first indium oxide film is lower than a resistivity of the second indium oxide film.

It is preferable that the above-described transistor include a second metal oxide film over the second indium oxide film, the second metal oxide film contain indium, gallium, and zinc, the second metal oxide film have a crystal structure, and a c-axis of the crystal structure be perpendicular or substantially perpendicular to a surface of the substrate.

One embodiment of the present invention is a transistor including a first metal oxide film over a substrate, an indium oxide film over the first metal oxide film, and a second metal oxide film over the indium oxide film. The first metal oxide film contains indium, tin, and silicon. A crystal grain boundary is not observed in a region of the indium oxide film where a channel is formed. The second metal oxide film contains indium, gallium, and zinc. The second metal oxide film has a crystal structure. A c-axis of the crystal structure is perpendicular or substantially perpendicular to a surface of the substrate. The first metal oxide film has an amorphous structure. A resistivity of the first metal oxide film is lower than a resistivity of the indium oxide film.

One embodiment of the present invention is a semiconductor device including any of the above-described transistors and a p-channel transistor containing silicon in its channel formation region, in which the transistor is positioned above the p-channel transistor and a CMOS circuit is formed using the transistor and the p-channel transistor.

With one embodiment of the present invention, a transistor with excellent electrical characteristics can be provided. With one embodiment of the present invention, a transistor with a high on-state current can be provided. With one embodiment of the present invention, a transistor with small parasitic capacitance can be provided. With one embodiment of the present invention, a highly reliable transistor, semiconductor device, memory device, or display device can be provided. With one embodiment of the present invention, a transistor, a semiconductor device, or a memory device which can be scaled down or highly integrated can be provided. With one embodiment of the present invention, a semiconductor device, a memory device, or a display device with low power consumption can be provided. With one embodiment of the present invention, a memory device with high operating speed can be provided. With one embodiment of the present invention, a display device with a high resolution or a high aperture ratio can be provided. With one embodiment of the present invention, a method for fabricating the above-described transistor, semiconductor device, memory device, or display device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIGS. 1A to 1D are cross-sectional views illustrating examples of stacked-layer structures.

FIGS. 2A and 2B are schematic perspective views illustrating an example of a semiconductor device.

FIG. 3A is a plan view illustrating an example of a semiconductor device, and FIGS. 3B to 3D are cross-sectional views illustrating the example of the semiconductor device.

FIGS. 4A and 4B are cross-sectional views illustrating an example of a semiconductor device.

FIG. 5 is a cross-sectional view illustrating an example of a semiconductor device.

FIG. 6A is a cross-sectional view illustrating an indium oxide film, and FIGS. 6B and 6C show the carrier concentration dependence of Hall mobility.

FIGS. 7A to 7C are cross-sectional views illustrating an example of a semiconductor device.

FIGS. 8A to 8F illustrate crystal planes.

FIGS. 9A to 9F illustrate crystal structures of metal oxides.

FIG. 10 is a cross-sectional view illustrating an example of a semiconductor device.

FIG. 11 is a cross-sectional view illustrating an example of a semiconductor device.

FIGS. 12A and 12B are cross-sectional views illustrating examples of a semiconductor device.

FIG. 13 is a cross-sectional view illustrating an example of a semiconductor device.

FIGS. 14A to 14C are cross-sectional views illustrating examples of a semiconductor device.

FIGS. 15A to 15D are cross-sectional views illustrating examples of a semiconductor device.

FIGS. 16A and 16B are cross-sectional views illustrating examples of a semiconductor device.

FIGS. 17A and 17B are cross-sectional views illustrating examples of a semiconductor device.

FIG. 18 is a cross-sectional view illustrating an example of a semiconductor device.

FIG. 19A is a plan view illustrating an example of a semiconductor device, and FIGS. 19B and 19C are cross-sectional views illustrating the example of the semiconductor device.

FIGS. 20A and 20B are cross-sectional views illustrating examples of a semiconductor device.

FIG. 21A is a plan view illustrating an example of a semiconductor device, and FIGS. 21B to 21D are cross-sectional views illustrating the example of the semiconductor device.

FIG. 22A is a plan view illustrating an example of a memory device, and FIGS. 22B and 22C are cross-sectional views illustrating the example of the memory device.

FIGS. 23A to 23C are cross-sectional views illustrating examples of a memory device.

FIG. 24A is a plan view illustrating an example of a memory device, and FIGS. 24B and 24C are cross-sectional views illustrating the example of the memory device.

FIGS. 25A and 25B are cross-sectional views illustrating an example of a memory device.

FIG. 26A is a plan view illustrating an example of a memory device, and FIG. 26B is a cross-sectional view illustrating the example of the memory device.

FIG. 27 is a cross-sectional view illustrating an example of a memory device.

FIG. 28 is a cross-sectional view illustrating an example of a memory device.

FIG. 29 is a block diagram illustrating a structure example of a semiconductor device.

FIGS. 30A to 30H illustrate circuit configuration examples of memory cells.

FIGS. 31A and 31B are perspective views illustrating structure examples of a semiconductor device.

FIG. 32 is a block diagram illustrating a CPU.

FIGS. 33A and 33B are perspective views of a semiconductor device.

FIGS. 34A and 34B are perspective views of semiconductor devices.

FIG. 35A is an equivalent circuit diagram of a logic circuit, FIG. 35B is a circuit symbol of the logic circuit, and FIG. 35C is a timing chart showing an operation of the logic circuit.

FIG. 36 is a cross-sectional view illustrating an example of a semiconductor device.

FIGS. 37A and 37D are equivalent circuit diagrams of logic circuits, and FIGS. 37B, 37C, 37E, and 37F are circuit symbols of logic circuits.

FIG. 38A is an equivalent circuit diagram of a DFF circuit, and FIG. 38B is a circuit symbol of the DFF circuit.

FIG. 39A illustrates a configuration example of a shift register circuit, and FIG. 39B is a timing chart showing an operation of the shift register circuit.

FIG. 40 is a conceptual diagram showing a hierarchy of memory devices.

FIGS. 41A and 41B illustrate examples of electronic components.

FIGS. 42A to 42C illustrate an example of a large computer, FIG. 42D illustrates an example of space equipment, and FIG. 42E illustrates an example of a storage system that can be used in a data center.

FIGS. 43A to 43C are cross-sectional images in Example.

FIGS. 44A and 44B are cross-sectional TEM images in Example.

FIG. 45A is a cross-sectional TEM image in Example, and FIG. 45B shows an FFT pattern in Example.

FIGS. 46A1, 46A2, 46B1, 46B2, 46C1, 46C2, 46D1, and 46D2 illustrate crystal structures of metal oxides.

FIGS. 47A and 47B are cross-sectional views of transistors in Example.

FIGS. 48A and 48B show the Id-Vg characteristics of transistors in Example.

FIGS. 49A and 49B show the Id-Vg characteristics of transistors in Example.

FIG. 50 is a cross-sectional TEM image in Example.

FIGS. 51A and 51B are cross-sectional TEM images in Example.

FIG. 52 is a cross-sectional TEM image in Example.

FIG. 53A is a cross-sectional TEM image in Example, FIG. 53B is a cross-sectional TEM image and shows FFT patterns in Example, and FIG. 53C shows the FFT pattern in Example.

FIGS. 54A and 54B are cross-sectional TEM images in Example.

FIG. 55 is a cross-sectional TEM image in Example.

FIGS. 56A and 56B are cross-sectional TEM images in Example.

FIGS. 57A and 57B are cross-sectional TEM images in Example.

FIGS. 58A to 58D illustrate crystallization of a semiconductor layer.

FIG. 59A is a cross-sectional HAADF-STEM image in Example, and FIG. 59B shows EDX analysis results in Example.

FIG. 60A is a cross-sectional HAADF-STEM image in Example, and FIG. 60B shows EDX analysis results in Example.

FIG. 61 shows the Id-Vg characteristics of transistors in Example.

FIG. 62A is a circuit diagram in Example, and FIG. 62B shows a method for measuring off-state currents of transistors in Example.

FIGS. 63A and 63B are SEM images in Example.

FIGS. 64A and 64B show evaluation results of transistors.

FIGS. 65A and 65B show evaluation results of transistors.

FIGS. 66A and 66B show evaluation results of transistors.

FIG. 67 shows temperature dependence of off-state current.

FIG. 68 shows temperature dependence of off-state current.

FIG. 69 is a circuit diagram used for circuit simulation.

FIGS. 70A and 70B are timing charts showing operations of a circuit.

FIGS. 71A and 71B show results of circuit simulation.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

A transistor is a kind of semiconductor element and enables amplification of current or voltage, switching operation for controlling conduction or non-conduction, and the like. A transistor in this specification includes, in its category, an insulated-gate field-effect transistor (IGFET) and a thin film transistor (TFT).

In this specification and the like, a transistor including an oxide semiconductor or a metal oxide in its semiconductor layer and a transistor including an oxide semiconductor or a metal oxide in its channel formation region are each sometimes referred to as an oxide semiconductor (OS) transistor. A transistor including silicon in its channel formation region is sometimes referred to as a

Si transistor.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

Note that in this specification and the like, an oxynitride refers to a material in which an oxygen content is higher than a nitrogen content. A nitride oxide refers to a material in which a nitrogen content is higher than an oxygen content. For example, silicon oxynitride refers to a material in which an oxygen content is higher than a nitrogen content, and silicon nitride oxide refers to a material in which a nitrogen content is higher than an oxygen content.

Note that in this specification and the like, the term “content percentage” refers to the proportion of a component contained in a film. In the case where an oxide semiconductor layer contains a metal element X, a metal element Y, and a metal element Z whose atomic numbers are respectively represented by Ax, Ay, and Az, the content percentage of the metal element X can be represented by Ax/(Ax+Ay+Az). Moreover, in the case where the atomic ratio between the metal element X, the metal element Y, and the metal element Z contained in an oxide semiconductor layer is represented by Bx: By. Bz, the content percentage of the metal element X can be represented by Bx/(Bx+BY+Bz).

Note that the terms “film” and “layer” can be used interchangeably depending on the case or the circumstances. For example, the term “conductive layer” can be replaced with the term “conductive film”. For another example, the term “insulating film” can be replaced with the term “insulating layer”.

In this specification and the like, the term “parallel” indicates that the angle formed between two straight lines is greater than or equal to −10° and less than or equal to 10°. Thus, the case where the angle is greater than or equal to −5° and less than or equal to 5° is also included. The term “substantially parallel” indicates that the angle formed between two straight lines is greater than or equal to −20° and less than or equal to 20°. The term “perpendicular” indicates that the angle formed between two straight lines is greater than or equal to 80° and less than or equal to 100°. Thus, the case where the angle is greater than or equal to 85° and less than or equal to 95° is also included. The term “substantially perpendicular” indicates that the angle formed between two straight lines is greater than or equal to 70° and less than or equal to 110°.

In this specification and the like, the term “electrically connected” includes the case where components are connected through an “object having any electric function”. There is no particular limitation on the “object having any electric function” as long as electric signals can be transmitted and received between components that are connected through the object. Examples of the “object having any electric function” include a switching element such as a transistor, a resistor, a coil, and elements with a variety of functions as well as an electrode and a wiring.

Note that in this specification and the like, “electrical connection” does not include the case where two nodes are connected to each other with an insulator (e.g., a dielectric of a capacitor, a gate insulating film of a transistor, or an interlayer insulating film) provided between the two nodes.

Note that in this specification and the like, a tapered shape refers to a shape such that at least part of a side surface of a component is inclined with respect to a substrate surface or a formation surface of the component. For example, a tapered shape preferably includes a region where the angle formed between the inclined side surface and the substrate surface or the formation surface (such an angle is also referred to as a taper angle) is greater than 0° and less than 90°. Note that the side surface of the component, the substrate surface, and the formation surface are not necessarily completely flat and may be substantially planar with a slight curvature or slight unevenness.

In the drawings for this specification and the like, arrows indicating an X direction, a Y direction, and a Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other.

In this specification and the like, a crystal structure of a cubic crystal system is sometimes referred to as a cubic crystal, a cubic crystal structure, or the like. The same applies to the other crystal systems (e.g., a hexagonal crystal system, a trigonal crystal system, a tetragonal crystal system, an orthorhombic crystal system, a monoclinic crystal system, and a triclinic crystal system).

In this specification and the like, a high power supply potential VDD (hereinafter, also simply referred to as “VDD”) refers to a power supply potential higher than a low power supply potential VSS (hereinafter, also simply referred to as “VSS”). The low power supply potential VSS is a power supply potential lower than the high power supply potential VDD.

A potential H is a potential with which an n-channel field-effect transistor (also referred to as an “n-type transistor”) is turned on and also a potential with which a p-channel field-effect transistor (also referred to as a “p-type transistor”) is turned off. A potential L is a potential with which an n-type transistor is turned off and a p-type transistor is turned on. Thus, the potential H is higher than the potential L. The potential H may be equal to VDD, and the potential L may be equal to VSS.

### Embodiment 1

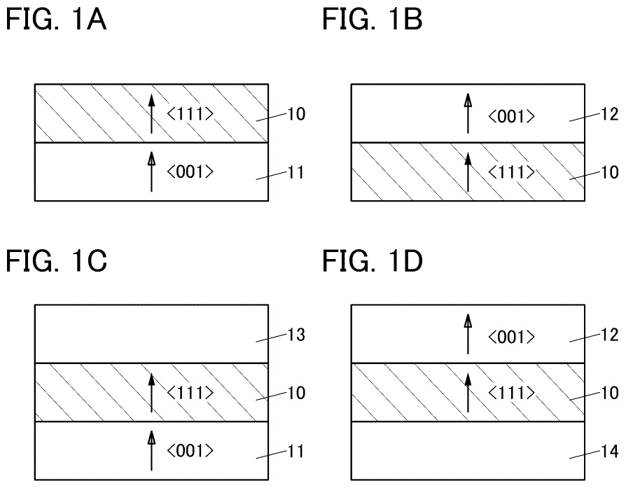

In this embodiment, a stacked-layer structure included in a transistor of one embodiment of the present invention will be described with reference to FIGS. 1A to 1D.

### [Structure Example of Stacked-Layer Structure]

FIGS. 1A to 1D are each a schematic cross-sectional view of a stacked-layer structure. The stacked-layer structure illustrated in FIG. 1A includes a first layer 11 over a substrate (not illustrated) and a semiconductor layer 10 over the first layer 11. The semiconductor layer 10 includes a channel formation region of the transistor.

A metal oxide functioning as a semiconductor (also referred to as an oxide semiconductor) is preferably used for the semiconductor layer 10. It is particularly preferable that the semiconductor layer 10 include an indium oxide film. In that case, the semiconductor layer 10 contains indium and oxygen. With a higher proportion of the number of indium atoms to the total number of atoms of all the metal elements included in the metal oxide, the field-effect mobility of the transistor can be higher. Accordingly, when indium oxide is used for the semiconductor layer 10, the transistor can have a high on-state current and excellent frequency characteristics.

Furthermore, the indium oxide film preferably has crystallinity. For example, the indium oxide film preferably includes a crystal grain. Examples of the film including a crystal grain include a single crystal film, a polycrystal film, and an amorphous film including a crystal grain. A polycrystal film is regarded as being formed of two or more crystal grains, whereas a single crystal film is regarded as being formed of one crystal grain. A crystal grain boundary (also referred to as a grain boundary) is observed in a polycrystal film, whereas a crystal grain boundary is not observed in a single crystal film.

Unlike in a polycrystal film, a crystal grain boundary is not observed in a channel formation region in a single crystal film. Impurities that block the carrier flow (typically, an insulating impurity, an insulating oxide, or the like) are likely to be segregated at a crystal grain boundary. Thus, in the case where a crystal grain boundary exists in a channel formation region, a variation in transistor characteristics is large. Meanwhile, a single crystal film of one embodiment of the present invention where a crystal grain boundary is not observed in a channel formation region produces an excellent effect of inhibiting a variation in transistor characteristics due to a crystal grain boundary.

In this specification and the like, a semiconductor layer where a crystal grain boundary is not observed in a channel formation region, a semiconductor layer where a channel formation region is included in one crystal grain, or a semiconductor layer where the directions of crystal axes of at least two regions in a channel formation region are the same can be referred to as a single crystal film. Furthermore, a semiconductor layer where at least one crystal orientation faces the same direction in a channel formation region can be referred to as a single crystal film.

Note that a channel formation region refers to a region of a semiconductor layer that overlaps with (or faces) a gate electrode with a gate insulating layer therebetween and is positioned between a region in contact with a source electrode and a region in contact with a drain electrode. Note that a semiconductor layer where a crystal grain boundary is not observed in a region between a region in contact with a source electrode and a region in contact with a drain electrode, a semiconductor layer where a region between a region in contact with a source electrode and a region in contact with a drain electrode is included in one crystal grain, or a semiconductor layer where the directions of crystal axes of at least two regions, which are positioned between a region in contact with a source electrode and a region in contact with a drain electrode, are the same can also be referred to as a single crystal film. Furthermore, a semiconductor layer where at least one crystal orientation faces the same direction in a region between a region in contact with a source electrode and a region in contact with a drain electrode can be referred to as a single crystal film.

In the channel formation region, a current path is the shortest distance between a source electrode and a drain electrode. Thus, a crystal grain, a crystal grain boundary, a crystal axis, a crystal orientation, and the like in the above-described channel formation region or the region positioned between the region in contact with the source electrode and the region in contact with the drain electrode can be confirmed by observation of a cross section including the semiconductor layer, the source electrode, and the drain electrode.

The crystallinity of the semiconductor layer 10 can be analyzed with X-ray diffractometry (XRD), transmission electron microscopy (TEM), or electron diffraction (ED), for example. Alternatively, these methods may be combined to be employed for analysis.

A crystal grain can be observed in a high-resolution transmission electron microscope (TEM) image, for example. In addition, a crystal grain boundary can sometimes be observed in a high-resolution TEM image, for example. That is, a crystal grain and a crystal grain boundary of a film having crystallinity can sometimes be observed in a high-resolution TEM image. The total magnification at the time of obtaining a TEM image is preferably greater than or equal to 2000000 times, further preferably greater than or equal to 4000000 times.

The presence of a crystal grain boundary can be checked with a TEM image obtained at a total magnification at which the crystal grain boundary can be observed. For example, in the case where a crystal grain boundary is not observed in a TEM image of a film obtained at a total magnification at which the crystal grain boundary can be observed, the film can be regarded as a single crystal film or a film in which a crystal grain boundary is not observed.

The indium oxide film is further preferably a single crystal film. Since a single crystal film does not include a crystal grain boundary, carrier scattering or the like at a crystal grain boundary can be inhibited, and a transistor having high field-effect mobility can be achieved. In addition, the transistor can have high reliability.

As the first layer 11, a film capable of increasing the crystallinity of the semiconductor layer 10 is preferably used.

The first layer 11 preferably contains, for example, at least one of the metal elements contained in the semiconductor layer 10. For example, the first layer 11 preferably includes an indium oxide film. With such a structure, the semiconductor layer 10 can homoepitaxially grow with the first layer 11 used as a seed or a nucleus, so that the crystallinity of the semiconductor layer 10 can be increased. In that case, the crystal axis of a crystal included in the semiconductor layer 10 is aligned or substantially aligned with the crystal axis of a crystal included in the first layer 11.

In this specification and the like, in the case where the angle formed by the crystal axis of a first crystal and the crystal axis of a second crystal is 0°, the crystal axis of the first crystal and the crystal axis of the second crystal are regarded as being aligned with each other. In the case where the acute angle formed by the crystal axis of the first crystal and the crystal axis of the second crystal is greater than 0° and less than or equal to 5°, the crystal axis of the first crystal and the crystal axis of the second crystal are regarded as being substantially aligned with each other. The crystal axis can be evaluated with a diffraction pattern obtained by nanobeam electron diffraction (NBED) (the diffraction pattern is also referred to as a nanobeam electron diffraction pattern). The crystal axis can also be evaluated with a pattern obtained by performing fast Fourier transform (FFT) processing on a TEM image (the pattern is also referred to as an FFT pattern). The FFT pattern reflects reciprocal lattice space information like the above-mentioned diffraction pattern.

The resistivity of the first layer 11 is preferably lower than that of the semiconductor layer 10. Thus, when the first layer 11 is connected to a source electrode or a drain electrode, the contact resistance can be reduced. The amount of oxygen vacancies is preferably larger in the indium oxide film included in the first layer 11 than in the indium oxide film included in the semiconductor layer 10. In addition, the concentration of an atom that can generate carriers is preferably higher in the indium oxide film included in the first layer 11 than in the indium oxide film included in the semiconductor layer 10. Examples of the atom that can generate carriers include tin and titanium. In that case, the first layer 11 contains indium and at least one of tin and titanium.

An indium oxide crystal has a cubic crystal structure (bixbyite structure). Thus, a metal oxide including a crystal having a hexagonal or trigonal crystal structure is preferably used for the first layer 11, for example. With such a structure, the semiconductor layer 10 can heteroepitaxially grow with the first layer 11 used as a seed or a nucleus, so that the crystallinity of the semiconductor layer 10 can be increased. In that case, the <111> orientation of the crystal included in the semiconductor layer 10 is parallel or substantially parallel to the c-axis (the <001> orientation) of the crystal included in the first layer 11. In addition, the <111> orientation of the crystal included in the semiconductor layer 10 and the c-axis (the <001> orientation) of the crystal included in the first layer 11 are perpendicular or substantially perpendicular to the substrate surface. FIG. 1A illustrates a state where the <111> orientation (indicated by an arrow) of the crystal included in the semiconductor layer 10 is parallel to the <001> orientation (indicated by an arrow) of the crystal included in the first layer 11.

Specifically, it is possible to use, for the first layer 11, zinc oxide, indium gallium oxide (also referred to as In—Ga oxide), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium gallium zinc oxide (also referred to as In—Ga—Zn oxide or IGZO), indium tin zinc oxide (also referred to as In—Sn—Zn oxide), or the like. For the first layer 11, an In—Ga—Zn oxide is preferably used. Here, the first layer 11 contains indium, gallium, zinc, and oxygen. Specifically, it is preferable that the atomic ratio of the In—Ga—Zn oxide be In:Ga:Zn=1:1:1 or in the neighborhood thereof, or In:Ga:Zn=1:3:2 or in the neighborhood thereof.

An In—Ga—Zn oxide, an In—Sn—Zn oxide, and the like easily have a c-axis aligned crystalline (CAAC) structure. In the case where an oxide having a CAAC structure is used for the first layer 11, the c-axis of the crystal included in the first layer 11 is perpendicular or substantially perpendicular to the substrate plane. That is, the <001> orientation of the crystal is perpendicular or substantially perpendicular to the substrate plane or the formation surface. Thus, when an oxide that easily has a CAAC structure is used for the first layer 11, the controllability of the crystal orientation of the semiconductor layer 10 can be increased. Also in the case where a metal oxide including a crystal having a hexagonal or trigonal crystal structure is used for the first layer 11, the resistivity of the first layer 11 is preferably lower than that of the semiconductor layer 10.

Although FIG. 1A illustrates the example of the structure in which the film capable of increasing the crystallinity of the semiconductor layer 10 (the first layer 11) is provided below the semiconductor layer 10, the present invention is not limited thereto. For example, the film capable of increasing the crystallinity of the semiconductor layer 10 can be provided above the semiconductor layer 10.

The stacked-layer structure illustrated in FIG. 1B includes the semiconductor layer 10 over a substrate (not illustrated) and a second layer 12 over the semiconductor layer 10.

Any of the materials that can be used for the first layer 11 can be used for the second layer 12. For example, indium oxide can be used for the second layer 12. The semiconductor layer 10 can homoepitaxially grow with the second layer 12 used as a seed or a nucleus, so that the crystallinity of the semiconductor layer 10 can sometimes be increased. The crystal axis of the crystal included in the semiconductor layer 10 is aligned or substantially aligned with the crystal axis of a crystal included in the second layer 12.

A metal oxide including a crystal having a hexagonal or trigonal crystal structure can be used for the second layer 12, for example. At this time, the semiconductor layer 10 can heteroepitaxially grow with the second layer 12 used as a seed or a nucleus, so that the crystallinity of the semiconductor layer 10 can sometimes be increased. In that case, the <111> orientation of the crystal included in the semiconductor layer 10 is parallel or substantially parallel to the c-axis (the <001> orientation) of the crystal included in the second layer 12. In addition, the <111> orientation of the crystal included in the semiconductor layer 10 and the c-axis (the <001> orientation) of the crystal included in the second layer 12 are perpendicular or substantially perpendicular to the substrate surface. FIG. 1B illustrates a state where the <111> orientation (indicated by an arrow) of the crystal included in the semiconductor layer 10 is parallel to the <001> orientation (indicated by an arrow) of the crystal included in the second layer 12.

Although FIG. 1A illustrates the example in which the stacked-layer structure is a two-layer structure of the first layer 11 and the semiconductor layer 10, the present invention is not limited thereto. For example, a third layer can be provided over the semiconductor layer 10.

The stacked-layer structure illustrated in FIG. 1C includes the first layer 11 over a substrate (not illustrated), the semiconductor layer 10 over the first layer 11, and a third layer 13 over the semiconductor layer 10.

Any of the materials that can be used for the first layer 11 may be used for the third layer 13. In the case where the crystallinity of the semiconductor layer 10 is increased with the first layer 11 used as a seed or a nucleus and the difference in thermal expansion coefficient between the first layer 11 and the third layer 13 is large, the semiconductor layer 10 might be polycrystallized by heat treatment after the formation of the semiconductor layer 10. In view of this, any of the materials that can be used for the first layer 11, typically an In—Ga—Zn oxide, is used for the third layer 13, so that the single crystal of the semiconductor layer 10 can sometimes be maintained even after the heat treatment. Note that when an In—Ga—Zn oxide is used for the third layer 13, the c-axis (the <001>orientation) of a crystal included in the third layer 13 is sometimes perpendicular or substantially perpendicular to the substrate surface.

The material that can be used for the third layer 13 is not limited to the above, and an insulating material, a semiconductor material, or a conductive material may be used for the third layer 13. The third layer 13 may be a single crystal film, a polycrystal film, a film including microcrystals, or an amorphous film.

Although FIG. 1B illustrates the example in which the stacked-layer structure is a two-layer structure of the semiconductor layer 10 and the second layer 12, the present invention is not limited thereto. For example, a fourth layer can be provided below the semiconductor layer 10. The stacked-layer structure illustrated in FIG. 1D includes a fourth layer 14 over a substrate (not illustrated), the semiconductor layer 10 over the fourth layer 14, and the second layer 12 over the semiconductor layer 10.

In the case where the film capable of increasing the crystallinity of the semiconductor layer 10 is used as the second layer 12, a material that can be used for the fourth layer 14 is not limited to materials described later, and an insulating material, a semiconductor material, or a conductive material may be used for the fourth layer 14. The fourth layer 14 may be a single crystal film, a polycrystal film, a film including microcrystals, or an amorphous film.

For the fourth layer 14, silicon oxide or silicon nitride can be used. Silicon oxide and silicon nitride each have a lower thermal expansion coefficient than indium oxide and thus can promote the crystal growth of an indium oxide film by utilizing a difference in thermal expansion coefficient.

For the fourth layer 14, indium tin oxide containing silicon (ITSO) can be used, for example. In that case, the fourth layer 14 can function as a source electrode or a drain electrode of a transistor. In the case of using ITSO, the silicon content percentage is preferably higher than or equal to 1 atomic % and lower than or equal to 20 atomic %, further preferably higher than or equal to 3 atomic % and lower than or equal to 20 atomic %, still further preferably higher than or equal to 3 atomic % and lower than or equal to 15 atomic %, yet still further preferably higher than or equal to 5 atomic % and lower than or equal to 15 atomic %. A metal oxide with an atomic ratio of In:Sn:Si=45:5:4 or 95:5:8 or an atomic ratio in the neighborhood thereof can be typically and suitably used. When the silicon content percentage falls within the above range, the fourth layer 14 can have high conductivity and can be amorphous. Note that the silicon content percentage in ITSO is not limited to the above range. Here, the proportion of the number of silicon atoms to the total number of atoms of indium, tin, and silicon in ITSO is regarded as the silicon content percentage.

This embodiment can be combined with any of the other embodiments and examples as appropriate. In this specification, in the case where a plurality of structure examples are shown in one embodiment, the structure examples can be combined as appropriate.

### Embodiment 2

In this embodiment, a semiconductor device of one embodiment of the present invention will be described. The semiconductor device of one embodiment of the present invention includes a transistor.

### <Structure Example of Semiconductor Device>

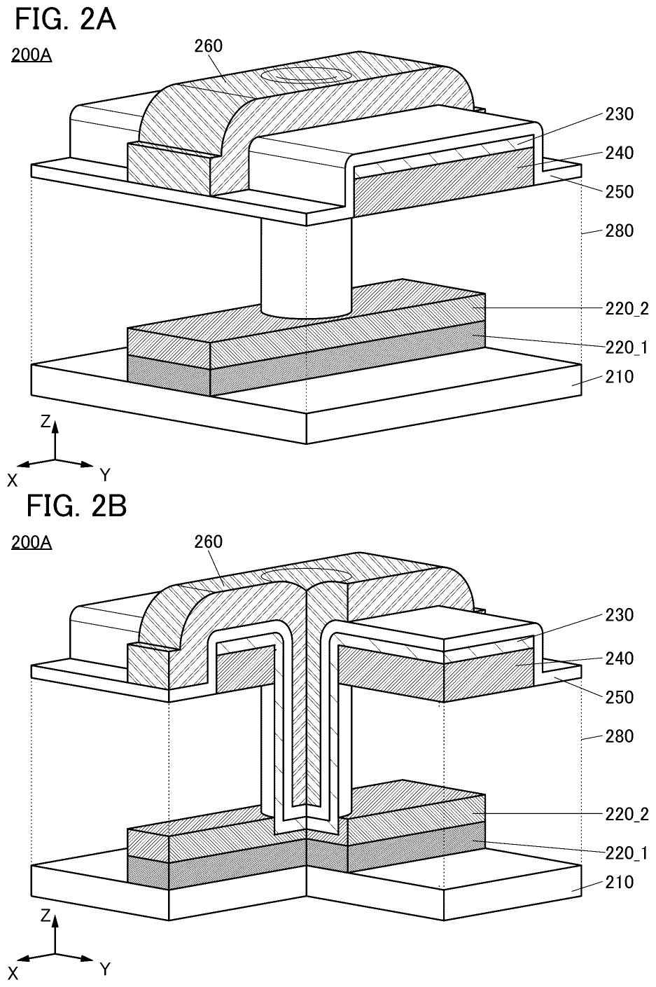

Structure examples of semiconductor devices of one embodiment of the present invention will be described with reference to FIGS. 2A and 2B to FIGS. 21A to 21D.

FIGS. 2A and 2B are schematic perspective views of a semiconductor device including a transistor 200A. FIG. 2B is a perspective view obtained by cutting part of FIG. 2A. For some components (e.g., interlayer insulating layers), FIGS. 2A and 2B show only outlines indicated by dashed lines.

In FIGS. 2A and 2B, the X direction, the Y direction, and the Z direction are indicated by arrows. The directions denoted by X, Y, and Z are consistent in FIGS. 2A and 2B but may be inconsistent among the drawings.

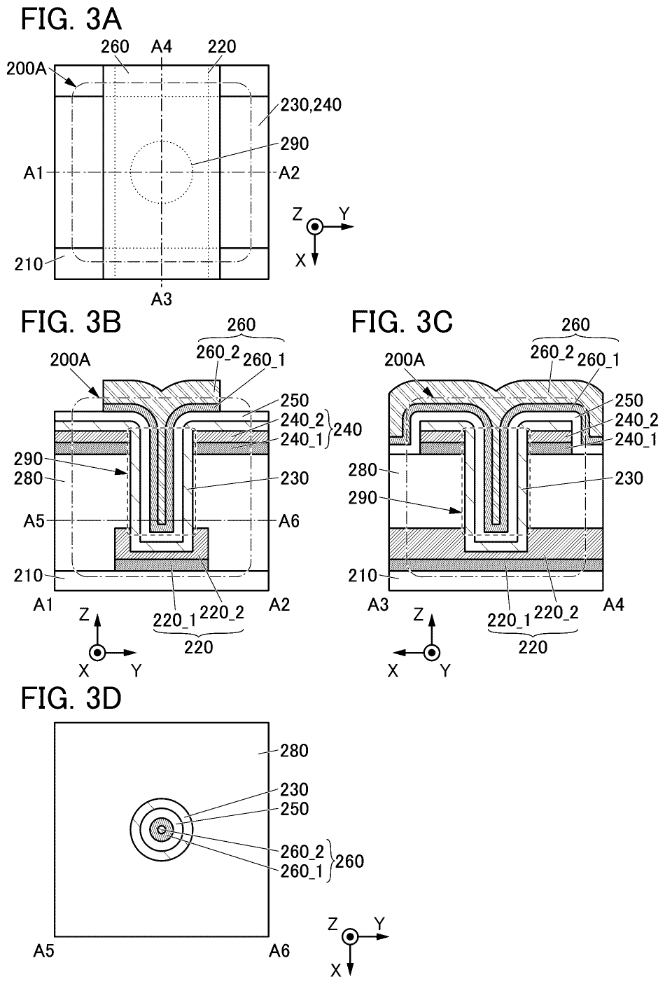

FIG. 3A is a plan view of the semiconductor device including the transistor 200A. FIG. 3B is a cross-sectional view taken along the dashed-dotted line A1-A2 in FIG. 3A. FIG. 3C is a cross-sectional view taken along the dashed-dotted line A3-A4 in FIG. 3A. FIG. 3D is a cross-sectional view taken along the dashed-dotted line A5-A6 in FIG. 3B. For simplification of the drawing, some components are not illustrated in the plan view of FIG. 3A. Some components may be omitted also in the following plan views.

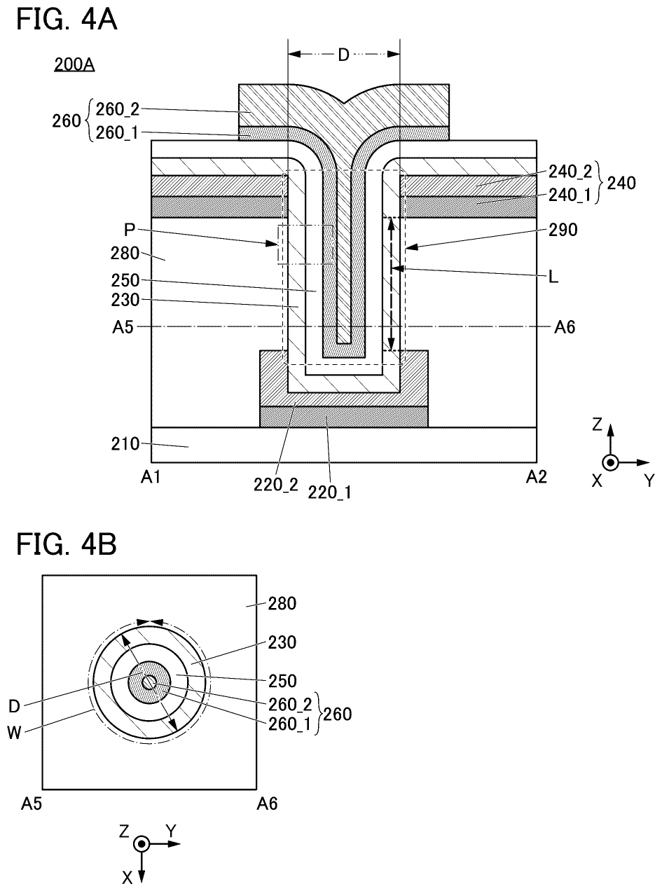

FIG. 4A is a cross-sectional view taken along the dashed-dotted line A1-A2 in FIG. 3A.

FIG. 4B is a cross-sectional view taken along the dashed-dotted line A5-A6 in FIG. 3B. FIGS. 4A and 4B correspond to examples of enlarged views of FIGS. 3B and 3D, respectively.

The semiconductor device illustrated in FIGS. 3A to 3D includes an insulating layer 210 over a substrate (not illustrated), the transistor 200A over the insulating layer 210, and an insulating layer 280 over the insulating layer 210.

### [Transistor 200A]

The transistor 200A includes a conductive layer 220 over the insulating layer 210, a conductive layer 240 over the insulating layer 280, a semiconductor layer 230, an insulating layer 250 over the semiconductor layer 230, and a conductive layer 260 over the insulating layer 250. The insulating layer 280 is positioned over the insulating layer 210 and the conductive layer 220. The insulating layer 210 and the insulating layer 280 may be regarded as components of the transistor 200A.

FIGS. 3B and 3C illustrate an example in which the conductive layer 220 has a two-layer structure of a conductive layer 220_1 and a conductive layer 220_2 over the conductive layer 220_1, the conductive layer 240 has a two-layer structure of a conductive layer 240_1 and a conductive layer 240 2 over the conductive layer 240_1, and the conductive layer 260 has a two-layer structure of a conductive layer 260_1 and a conductive layer 260_2 over the conductive layer 260_1.

In the transistor 200A, the conductive layer 260 functions as a gate electrode, the insulating layer 250 functions as a gate insulating layer, the conductive layer 220 functions as one of a source electrode and a drain electrode, and the conductive layer 240 functions as the other of the source electrode and the drain electrode. The semiconductor layer 230 includes a channel formation region. The conductive layer 260 includes a region functioning as a gate wiring.

As illustrated in FIGS. 3B and 3C, an opening portion 290 reaching the conductive layer 220 is provided in the insulating layer 280 and the conductive layer 240.

The opening portion 290 includes an opening portion of the insulating layer 280 and an opening portion of the conductive layer 240. The shape and the size of the opening portion 290 in the plan view may differ from layer to layer. When the opening portion 290 has a circular top-view shape, the opening portions of the layers may be, but not necessarily, concentrically arranged.

The semiconductor layer 230, the insulating layer 250, and the conductive layer 260 are placed in the opening portion 290 at least partly. Portions of the semiconductor layer 230, the insulating layer 250, and the conductive layer 260 which are placed in the opening portion 290 reflect the shape of the opening portion 290.

The semiconductor layer 230 is provided to cover the bottom portion and the sidewall of the opening portion 290. The semiconductor layer 230 has a depressed portion reflecting the shape of the opening portion 290. The semiconductor layer 230 includes a portion in contact with the top surface of the conductive layer 240 and a portion in contact with the top surface of the conductive layer 220 in the opening portion 290. The semiconductor layer 230 includes a portion in contact with the side surface of the insulating layer 280 in the opening portion 290.

The insulating layer 250 is provided to cover the semiconductor layer 230. The insulating layer 250 is provided over the insulating layer 280 to cover the top and side surfaces of the semiconductor layer 230 and the side surface of the conductive layer 240. The insulating layer 250 has a depressed portion reflecting the shape of the depressed portion of the semiconductor layer 230.

The conductive layer 260 is provided to fill at least part of the depressed portion of the insulating layer 250. In the opening portion 290, the conductive layer 260 includes a region overlapping with the semiconductor layer 230 with the insulating layer 250 therebetween.

The semiconductor layer 230 includes a region overlapping with the conductive layer 260 with the insulating layer 250 therebetween. At least part of the region functions as a channel formation region of the transistor 200A. One of a region of the semiconductor layer 230 which is in the vicinity of the conductive layer 220 and a region of the semiconductor layer 230 which is in the vicinity of the conductive layer 240 functions as a source region, and the other functions as a drain region. That is, the channel formation region is sandwiched between the source region and the drain region.

The semiconductor layer 230 is provided in the opening portion 290. The transistor 200A has a structure in which current flows in the vertical direction since one of the source electrode and the drain electrode (here, the conductive layer 220) is positioned on the lower side and the other of the source electrode and the drain electrode (here, the conductive layer 240) is positioned on the upper side. That is, a channel is formed along the side surface of the insulating layer 280 in the opening portion 290. Thus, the area occupied by the transistor 200A can be smaller than the area occupied by a planar transistor in which a channel formation region, a source region, and a drain region are provided separately on the XY plane. Accordingly, the semiconductor device can be highly integrated. In the case where the semiconductor device of one embodiment of the present invention is used for a memory device, the memory capacity per unit area can be increased. The channel length direction of the transistor 200A includes a height (vertical) component; thus, the transistor 200A can be referred to as a vertical field-effect transistor (VFET), a vertical transistor, a vertical-channel transistor, or the like.

As illustrated in FIG. 4A, the conductive layer 220 has a depressed portion overlapping with the opening portion 290. Specifically, the depressed portion is provided in the conductive layer 220_2 in a position overlapping with the opening portion 290. When the conductive layer 220_2 has the depressed portion, unlike in the case where the depressed portion is not provided, the levels of the bottom surfaces of the insulating layer 250 and the conductive layer 260 in the opening portion 290 can be lower than the level of the top surface of the conductive layer 220_2 which is in contact with the insulating layer 280. The levels of the surfaces can be determined using the formation surface of the transistor as a reference. Here, the top surface of the insulating layer 210 is used as the reference. The surface used as the reference is not limited to the formation surface of the transistor. For example, the top surface of the substrate where the transistor or the semiconductor device is provided may be used as the reference.

The semiconductor layer 230 is in contact with the bottom and side surfaces of the depressed portion of the conductive layer 220_2. When the conductive layer 220_2 has the depressed portion, the contact area between the semiconductor layer 230 and the conductive layer 220_2 can be increased.

Thus, the contact resistance between the semiconductor layer 230 and the conductive layer 220_2 can be reduced.

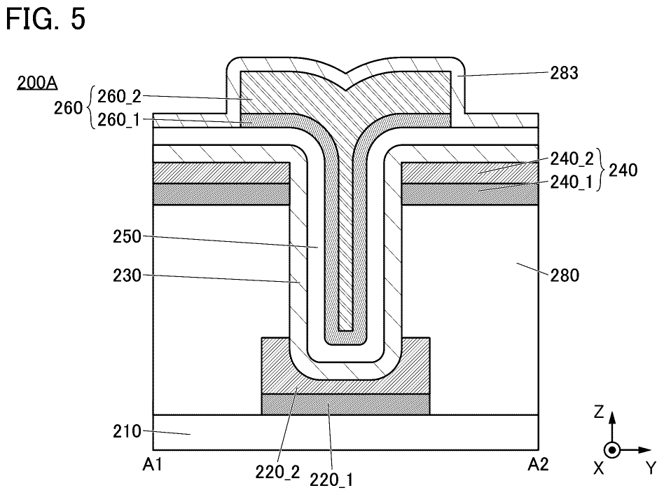

As illustrated in FIG. 5, the depressed portion of the conductive layer 220_2 can have a curved portion. When the depressed portion has the curved portion, portions of the semiconductor layer 230, the insulating layer 250, and the like that are provided over the depressed portion and in the vicinity of the depressed portion each have a curved portion in some cases. In other words, the portions each have a curved surface or a concave surface in the cross-sectional view in some cases. The portions each do not have an angle portion (a right angle or an acute angle) in the cross-sectional view in some cases. Thus, electric field concentration on the insulating layer 250 in the vicinity of the depressed portion is relieved, so that the withstand voltage of the transistor 200A can be increased and the electrostatic breakdown of the transistor 200A can be inhibited. Accordingly, the reliability of the semiconductor device can be improved.

FIG. 3C illustrates a structure in which the end portion of the conductive layer 240 and the end portion of the semiconductor layer 230 are aligned or substantially aligned with each other outside the opening portion 290. The conductive layer 240 and the semiconductor layer 230 can be formed by being processed using the same mask. This is preferable because the number of masks required for fabricating the semiconductor device can be reduced. Note that the present invention is not limited thereto. For example, in the X direction or the Y direction, any one of the end portion of the semiconductor layer 230, the end portion of the conductive layer 240_1, and the end portion of the conductive layer 240_2 may be positioned inward or outward from the others.

As illustrated in FIG. 3A, the transistor 200A is provided at an intersection of the conductive layer 260 extending in the X direction and the conductive layer 240 extending in the Y direction. As illustrated in FIG. 3A, the diameter of the opening portion 290 can be smaller than the width of the short side of the conductive layer 240 and the width of the short side of the conductive layer 260. Thus, it can be said that the transistor 200A can be highly integrated and scaled down.

As illustrated in FIG. 4B, when the opening portion 290 is formed to be circular in the plan view, the semiconductor layer 230, the insulating layer 250, and the conductive layer 260 are formed concentrically. Thus, the side surface of the conductive layer 260 provided at the center of the opening portion 290 faces the side surface of the semiconductor layer 230 with the insulating layer 250 therebetween. That is, in the plan view, the entire perimeter of the semiconductor layer 230 serves as the channel formation region. In that case, for example, the channel width of the transistor 200A is determined by the length of the outer perimeter or the inner perimeter of the semiconductor layer 230. That is, the channel width of the transistor 200A is determined by the width of the opening portion 290 (the diameter in the case where the opening portion 290 is circular in the plan view). FIGS. 4A and 4B illustrate a width D of the opening portion 290, and FIG. 4B illustrates a channel width W of the transistor 200A.

When the semiconductor layer 230, the insulating layer 250, and the conductive layer 260 are formed concentrically, the distance between the conductive layer 260 and the semiconductor layer 230 is substantially uniform; thus, a gate electric field can be substantially uniformly applied to the semiconductor layer 230.

By increasing the width D of the opening portion 290, the channel width per unit area can be increased and the on-state current can be increased. Meanwhile, the area occupied by the transistor 200A, e.g., the area of the transistor 200A in the plan view, is roughly determined by the width of the opening portion 290. By reducing the width D of the opening portion 290, the area occupied by the transistor 200A can be reduced and the semiconductor device can be highly integrated.

The width D of the opening portion 290 sometimes varies in the depth direction. Here, the shortest distance between two side surfaces of the conductive layer 240 on the opening portion side in a cross-sectional view is particularly used as the width D. In other words, the minimum width of the opening portion in the conductive layer 240 is used as the width D of the opening portion 290. The width of the opening portion at the highest position, the width of the opening portion at the lowest position, or the width of the opening portion at the midpoint therebetween in the conductive layer 240, or the average value of these three widths may be used as the width D. Although an example in which the width D of the opening portion 290 is determined by the width of the opening portion of the conductive layer 240 is described here, there is no particular limitation on the method for determining the width D. For example, the shortest distance between two side surfaces of the insulating layer 280 on the opening portion side can be used as the width D. The width of the opening portion at the highest position, the width of the opening portion at the lowest position, or the width of the opening portion at the midpoint therebetween in the insulating layer 280, or the average value of these three widths may be used as the width D of the opening portion 290.

The width D of the opening portion 290 is determined by the thicknesses of the semiconductor layer 230, the insulating layer 250, and the conductive layer 260 provided in the opening portion 290. The width D of the opening portion 290 is preferably greater than or equal to 5 nm and less than or equal to 120 nm, further preferably greater than or equal to 5 nm and less than or equal to 100 nm, still further preferably greater than or equal to 10 nm and less than or equal to 60 nm, yet further preferably greater than or equal to 20 nm and less than or equal to 50 nm, yet still further preferably greater than or equal to 20 nm and less than or equal to 40 nm, yet still further preferably greater than or equal to 20 nm and less than or equal to 30 nm, for example. In the case where the opening portion 290 is circular in the plan view, the width D of the opening portion 290 corresponds to the diameter of the opening portion 290, and the channel width W can be calculated to be “D×π”.

This embodiment describes the example in which the opening portion 290 is circular in the plan view. When the opening portion is circular, the processing accuracy in forming the opening portion can be increased; thus, the opening portion can be formed to have a minute size. Note that the present invention is not limited thereto. The opening portion 290 in the plan view can have a circular shape, a substantially circular shape such as an elliptical shape, a polygonal shape such as a triangular shape, a quadrangular shape (including a rectangular shape, a rhombic shape, and a square), a pentagonal shape, or a star polygonal shape, or any of these polygonal shapes whose corners are rounded, for example. Note that the circular shape is not necessarily a perfect circular shape. The polygonal shape may be a concave polygonal shape (a polygonal shape at least one of the interior angles of which is greater than) 180° or a convex polygonal shape (a polygonal shape all the interior angles of which are less than or equal to) 180°.

The channel length of the transistor 200A is a distance between the source region and the drain region. That is, the channel length of the transistor 200A is determined by the thickness of the insulating layer 280 over the conductive layer 220. Thus, the channel length of the transistor 200A does not affect the area occupied by the transistor 200A, e.g., the area of the transistor 200A in the plan view. In FIG. 4A, a channel length L of the transistor 200A is indicated by a dashed double-headed arrow. The channel length L can be regarded as a distance between the end portion of a region where the semiconductor layer 230 and the conductive layer 220 are in contact with each other and the end portion of a region where the semiconductor layer 230 and the conductive layer 240 are in contact with each other in the cross-sectional view. In that case, the channel length L corresponds to the length of the side surface of the insulating layer 280 on the opening portion 290 side in the cross-sectional view.

The channel length of the transistor 200A can be, for example, less than or equal to 500 nm, less than or equal to 300 nm, less than or equal to 100 nm, less than or equal to 60 nm, less than or equal to 50 nm, less than or equal to 40 nm, less than or equal to 30 nm, less than or equal to 20 nm, or less than or equal to 10 nm and greater than or equal to 0.1 nm, greater than or equal to 1 nm, or greater than or equal to 5 nm. The channel length of the transistor 200A can be typically greater than or equal to 1 nm and less than or equal to 300 nm, preferably greater than or equal to 5 nm and less than or equal to 100 nm. In that case, the productivity, yield, and the like can be improved in formation of the insulating layer 280 and formation of the opening portion 290 in the insulating layer 280, for example. In addition, the transistor 200A can have a higher on-state current and higher frequency characteristics.

The channel length L of the transistor 200A is preferably smaller than at least the channel width W of the transistor 200A. The channel length L of the transistor 200A is preferably greater than or equal to 0.1 times and less than or equal to 0.99 times, further preferably greater than or equal to 0.5 times and less than or equal to 0.8 times the channel width W of the transistor 200A. This structure enables the transistor to have excellent electrical characteristics and high reliability.

In the transistor of one embodiment of the present invention, the semiconductor layer 230 including the channel formation region includes a metal oxide functioning as a semiconductor (such a metal oxide is also referred to as an oxide semiconductor). That is, the transistor can be regarded as an OS transistor. In this specification and the like, a semiconductor layer including an oxide semiconductor can be referred to as an oxide semiconductor layer. Since the semiconductor layer 230 includes a metal oxide, the semiconductor layer 230 can be referred to as a metal oxide layer.

When oxygen vacancies (Vₒ) and impurities are in the channel formation region of the oxide semiconductor in an OS transistor, the electrical characteristics of the OS transistor easily vary and the reliability thereof may worsen in some cases. Therefore, the oxygen vacancies and the impurities are preferably reduced as much as possible in the channel formation region of the oxide semiconductor. In other words, the oxide semiconductor preferably includes an i-type (intrinsic) or substantially i-type channel formation region with a low carrier concentration.

When an excess amount of oxygen is supplied to the semiconductor layer 230, an electron trap due to the oxygen is formed in the insulating layer 250. Accordingly, the OS transistor is likely to suffer from positive drift degradation in a gate bias-temperature (+GBT) stress test. In other words, the amount of positive drift degradation in the +GBT stress test increases.

Thus, in the semiconductor device of one embodiment of the present invention, the impurity concentration in the semiconductor layer 230 is preferably low. An appropriate amount of oxygen is preferably supplied to the semiconductor layer 230. Furthermore, the amount of excess oxygen in the semiconductor layer 230 is preferably reduced.

The semiconductor layer 230 corresponds to the semiconductor layer 10 described in Embodiment 1. Thus, for the structure, material, and the like of the semiconductor layer 230, the structure, material, and the like of the semiconductor layer 10 described in Embodiment 1 can be referred to.

Note that an indium oxide film may be a polycrystal film or an amorphous film with crystal grains. In that case, it is preferable that a crystal grain boundary not be observed or the number of grain boundary components be small in the channel formation region. For example, when one crystal grain is positioned in a channel formation region, a structure in which a crystal grain boundary is not observed in the channel formation region can be obtained. Such a structure can also produce an effect similar to that of the structure in which the indium oxide film is a single crystal film.

Two or more crystal grains can be positioned in the channel formation region. For example, in the case where a first crystal grain and a second crystal grain are positioned in the channel formation region, it is preferable that the crystal orientation of the first crystal grain be aligned or substantially aligned with the crystal orientation of the second crystal grain. In the case where the crystal orientation of the first crystal grain is aligned or substantially aligned with the crystal orientation of the second crystal grain, a crystal grain boundary is sometimes not observed at the boundary between the first crystal grain and the second crystal grain. When the crystal orientation of the first crystal grain is aligned or substantially aligned with the crystal orientation of the second crystal grain, the formation of the crystal grain boundary between the first crystal grain and the second crystal grain can be inhibited. Thus, such a structure can also produce an effect similar to that of the structure in which the indium oxide film is a single crystal film. Note that a state where the crystal orientation of the first crystal grain is aligned or substantially aligned with the crystal orientation of the second crystal grain can sometimes be observed in a high-resolution TEM image, for example. Specifically, this state can be observed in a high-resolution TEM image showing continuous connection between the lattice fringes of the first crystal grain and the lattice fringes of the second crystal grain at the boundary between the first crystal grain and the second crystal grain.

In this specification and the like, a crystal grain boundary refers to a boundary between adjacent crystal grains with different crystal orientations, for example. Thus, in this specification and the like, a crystal grain boundary does not include a boundary between adjacent crystal grains with the same crystal orientation. For example, in the case where a boundary is observed between two crystal grains in a high-resolution TEM image but the crystal orientations of the two crystal grains are aligned or substantially aligned with each other, the boundary is not referred to as a crystal grain boundary in some cases.

The crystal orientation can also be evaluated with a nanobeam electron diffraction pattern, an FFT pattern, or the like.

For example, in the case where the difference in the angle of the FFT pattern between the FFT pattern of the first crystal grain and the FFT pattern of the second crystal grain is greater than or equal to −5° and less than or equal to 5°, preferably greater than or equal to −3° and less than or equal to 3°, further preferably greater than or equal to −2° and less than or equal to 2°, it can be said that the crystal orientation of the first crystal grain and the crystal orientation of the second crystal grain are aligned or substantially aligned with each other. Note that the angle of the FFT pattern in the orientation refers to, for example, an acute angle formed by an approximate straight line between one or both of a spot derived from the (222) plane and a spot derived from the (−2-2-2) plane and a spot at the center and a reference line (e.g., a vertically extending straight line).

The degree of the polycrystallinity of an indium oxide film can be evaluated from a crystal grain size. The crystal grain size can be calculated, for example, as the diameter of a perfect circle assumed to have an area equivalent to the calculated area of the crystal grain. The diameter here is sometimes referred to as an equivalent circular area diameter or the like.

The degree of the polycrystallinity of an indium oxide film can also be evaluated from the extension length of a grain boundary. The extension length of a grain boundary can be calculated as, for example, the total length of crystal grain boundaries observed in a field of view of a specific area extracted from a TEM image of a film obtained at a total magnification at which the crystal grain boundaries can be observed. An indium oxide film in which the extension length of a grain boundary is 0 nm can be regarded as a single crystal film. As the extension length of a grain boundary is longer, the number of grain boundary components is larger.

The extension length of a grain boundary in an indium oxide film is preferably longer than or equal to 0 nm and shorter than or equal to 1500 nm, further preferably longer than or equal to 0 nm and shorter than or equal to 1000 nm, still further preferably longer than or equal to 0 nm and shorter than or equal to 800 nm. When the semiconductor layer 230 includes an indium oxide film in which the extension length of a grain boundary falls within the above-described range, a structure in which a crystal grain boundary is not observed or the number of grain boundary components is small in a channel formation region can be achieved. In this specification and the like, the area of a field of view used to calculate the extension length of a grain boundary is 90 nm square, unless otherwise specified.

The thickness of the semiconductor layer 230 is preferably greater than or equal to 2 nm and less than or equal to 50 nm, further preferably greater than or equal to 2.5 nm and less than or equal to 30 nm, still further preferably greater than or equal to 2.5 nm and less than or equal to 20 nm, yet further preferably greater than or equal to 5 nm and less than or equal to 20 nm, yet still further preferably greater than or equal to 5 nm and less than or equal to 10 nm. Note that the semiconductor layer 230 at least partly includes a region with the above-described thickness. For example, the channel formation region in the semiconductor layer 230 includes a region with the above-described thickness. When the thickness of the semiconductor layer 230 is increased, the on-state current of the transistor can be increased. Meanwhile, when the thickness of the semiconductor layer 230 is too large, the extension length of the grain boundary is increased, which might cause the on-state current of the transistor to be lowered owing to the influence of carrier scattering at the crystal grain boundary. When the thickness of the semiconductor layer 230 is reduced, a reduction in threshold voltage can be inhibited, so that the transistor can be normally-off. Meanwhile, when the thickness of the semiconductor layer 230 is too small, the crystallinity of the semiconductor layer 230 might vary in the substrate plane and the electrical characteristics of the transistor might vary. Thus, when the thickness of the semiconductor layer 230 is within the above-described range, the crystallinity of the semiconductor layer 230 can be increased. Increasing the crystallinity of the semiconductor layer 230 enables the semiconductor layer 230 to include a crystal grain.

In the case where a metal oxide contains indium and zinc, the metal oxide sometimes has a CAAC structure. The CAAC structure has fewer crystal grain boundaries in the a-b plane than a polycrystalline structure. Examples of the metal oxide containing indium and zinc include indium zinc oxide (also referred to as In—Zn oxide or IZO (registered trademark)) and IGZO.

In an oxide semiconductor layer having crystallinity, one or both of hydrogen and oxygen move more easily in an indium oxide film than in an IGZO film, for example. Thus, it can be said that one or both of hydrogen and oxygen are more likely to be supplied to and released from an indium oxide film than to/from an IGZO film, for example. Note that an indium oxide film can be regarded as having a higher property of transmitting one or both of hydrogen and oxygen than an IGZO film, for example. In other words, an indium oxide film can be regarded as having a lower barrier property against one or both of hydrogen and oxygen than an IGZO film, for example.

The indium oxide film preferably has a property of transmitting oxygen in a range greater than or equal to 1×10²⁰ atoms and less than or equal to 2×10²¹ atoms per cubic centimeter, further preferably greater than or equal to 2×10²⁰ atoms and less than or equal to 1×10²¹ atoms per cubic centimeter, for example, in heat treatment at a heating temperature of 400° C. for a treatment time of 8 hours. The indium oxide film preferably has a property of diffusing oxygen through a crystal grain in a range greater than or equal to 1×10²⁰ atoms and less than or equal to 2×10²¹ atoms per cubic centimeter, further preferably greater than or equal to 2×10²⁰ atoms and less than or equal to 1×10²¹ atoms per cubic centimeter, for example, by heat treatment at a heating temperature of 400° C. for a treatment time of 8 hours.

When oxygen in the indium oxide film diffuses through a crystal grain and a crystal grain boundary, Vₒ present in the crystal grain or the crystal grain boundary can be reduced. Accordingly, the electric characteristics and reliability of the transistor can be improved.

The properties of transmitting oxygen and hydrogen in the film can be evaluated by calculation using a nudged elastic band (NEB) method, for example. Specifically, the properties can be evaluated using migration barriers against an oxygen atom and a hydrogen atom obtained by the calculation using the NEB method. As the value of the migration barrier is smaller, the corresponding atom moves (is transmitted) more easily.

Table 1 shows examples of calculation results. In Table 1, In₂O₃ is a crystal model of indium oxide and IGZO is a crystal model of In—Ga—Zn oxide. The term “excess oxygen” in Table 1 refers to oxygen that is not positioned in an oxygen site of a crystal lattice or oxygen that is positioned between lattices.

TABLE 1

| | In₂O₃ | IGZO |
|---|---|---|
| Migration barrier against oxygen | 0.85 eV | 1.88 eV |
| Migration barrier against hydrogen | 0.34 eV | 1.39 eV |
| Migration barrier against excess oxygen | 1.25 eV | 1.43 eV |

According to Table 1, the migration barriers against oxygen, hydrogen, and excess oxygen in the crystal model of indium oxide are lower than those in the crystal model of In—Ga—Zn oxide. This indicates that oxygen and hydrogen move (are transmitted) more easily in the indium oxide than in the In—Ga—Zn oxide. It is also indicated that the indium oxide film has higher properties of transmitting an oxygen atom and a hydrogen atom than the In—Ga—Zn oxide film. It is thus presumed that hydrogen and oxygen are easily supplied to and released from the indium oxide film. Furthermore, an effect of filling Vₒ generated in the +GBT test with oxygen will be produced, probably achieving a highly reliable transistor.

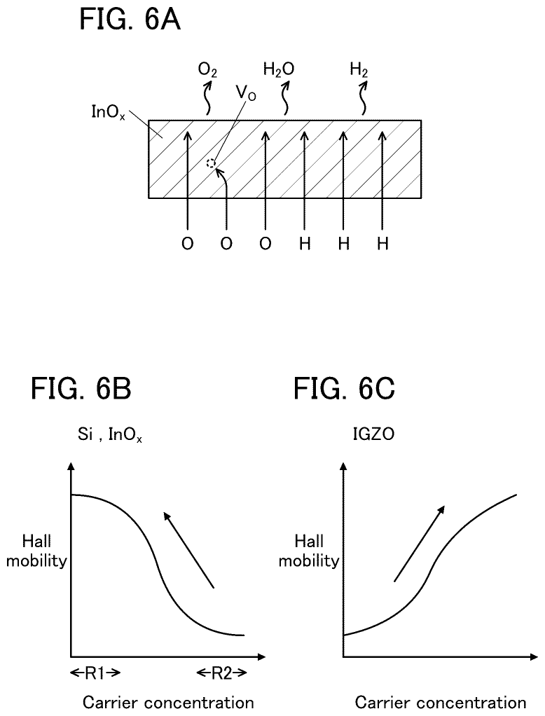

Thus, as shown in FIG. 6A, oxygen (O) diffusing in an indium oxide film (denoted as InOx) is transmitted through the indium oxide film and released as an oxygen molecule (O₂). When reacting with hydrogen contained in the film, oxygen is released as a water molecule (H₂O) in some cases. In the case where the film includes oxygen vacancies (Vₒ), the oxygen vacancies are filled with diffusing oxygen atoms. Since oxygen easily diffuses in the indium oxide film, oxygen vacancies in the indium oxide film are filled with oxygen more easily than those in an IGZO film. As described above, the oxygen vacancies in the indium oxide film are reduced more easily than those in the IGZO film; thus, a transistor including such an indium oxide film can have extremely high reliability. As shown in FIG. 6A, hydrogen diffuses in the indium oxide film. Hydrogen diffusing into the indium oxide film from the outside is transmitted through the indium oxide film and is released as a hydrogen molecule (H₂). When reacting with oxygen contained in the film as described above, hydrogen is released as a water molecule.

The content percentage of a first element in the semiconductor layer 230 is preferably low. In addition, the concentration of the first element in the semiconductor layer 230 is preferably low. In particular, the concentration of the first element in the channel formation region is preferably low. Here, the first element is at least one of boron, carbon, aluminum, silicon, zinc, and gallium. That is, in the semiconductor layer 230, the concentration of any one of boron, carbon, aluminum, silicon, zinc, and gallium is preferably low, the concentrations of two elements selected from boron, carbon, aluminum, silicon, zinc, and gallium are further preferably low, and the concentrations of all of boron, carbon, aluminum, silicon, zinc, and gallium are still further preferably low. The concentration of the first element in the semiconductor layer 230 is preferably lower than or equal to 1 atomic %, further preferably lower than or equal to 0.1 atomic %, still further preferably lower than or equal to 0.01 atomic % (100 ppm), for example. Note that the preferable concentration of the first element in the semiconductor layer 230 can be rephrased as a preferable concentration of the first element in the channel formation region.

As described later, the concentration of the first element in the semiconductor layer 230 can be lower than or equal to 0.01 atomic % (100 ppm), lower than or equal to 0.0001% (1 ppm), lower than or equal to 0.00001% (0.1 ppm or 100 ppb), or lower than or equal to 0.0000001% (0.001 ppm or 1 ppb) by using a precursor which has been subjected to distillation at least once. That is, the content percentage (purity) of indium excluding oxygen in the semiconductor layer 230 can be higher than or equal to 99.99 atomic % (4N), higher than or equal to 99.9999 atomic % (6N), higher than or equal to 99.99999 atomic % (7N), or higher than or equal to 99.9999999 atomic % (9N), which may enable the semiconductor layer 230 to have a purity substantially the same as the purity of silicon (10N) used for the semiconductor layer.

When the concentrations of boron, carbon, aluminum, and silicon in the semiconductor layer 230 are reduced, the crystallinity of the semiconductor layer 230 can be improved.

In the case where the semiconductor layer 230 contains a gallium atom, the gallium atom is bonded to an excess oxygen atom to form a Ga—O structure. The Ga—O structure functions as an acceptor that traps electrons. Thus, in the transistor including the semiconductor layer 230 containing a gallium atom and an excess oxygen atom, the amount of threshold voltage change in a positive bias temperature stress (PBTS) test is large. Reducing the concentration of gallium in the semiconductor layer 230 can reduce the amount of threshold voltage change in the PBTS test. Accordingly, the transistor can be highly reliable against positive bias application. A phenomenon similar to that in the case where the semiconductor layer 230 contains a gallium atom occurs also in the case where the semiconductor layer 230 contains a zinc atom.

Furthermore, an aluminum atom, a gallium atom, and a zinc atom have higher bonding strength with an oxygen atom than an indium atom does. Therefore, lowering the concentrations of aluminum, gallium, and zinc in the indium oxide film can inhibit a reduction in the oxygen-transmitting property.

Furthermore, an impurity, such as the first element, contained in the indium oxide film can serve as a crystal nucleus. By reducing impurities in the indium oxide film as much as possible, the number of crystal nuclei can be small, and an increase in the crystal grain size can be promoted as described later.

In the case where the indium oxide film is a polycrystal film, the first element is segregated at the crystal grain boundary, so that an oxide containing the first element is formed. The oxide has an insulating property and thus might cause a decrease in the on-state current or field-effect mobility of the transistor. By reducing the first element in the indium oxide film as much as possible, the on-state current or field-effect mobility of the transistor can be increased.

Furthermore, by reducing impurities in the indium oxide film, impurity scattering can be inhibited. Thus, a transistor having high field-effect mobility can be achieved. For example, when the concentration of the first element in the semiconductor layer 230 is within the above-described preferable range, the field-effect mobility of the transistor can be higher than or equal to 50 cm²/(V·s), preferably higher than or equal to 100 cm²/(V·s), further preferably higher than or equal to 150 cm²/(V·s), still further preferably higher than or equal to 200 cm²/(V·s), yet still further preferably higher than or equal to 250 cm²/(V·s).

Here, the dependence of the Hall mobility on the carrier concentration of indium oxide, silicon, and IGZO will be described. FIG. 6B is a schematic view showing the dependence of the Hall mobility on the carrier concentration of silicon (Si) and indium oxide (InOx), and FIG. 6C is a schematic view showing the dependence of the Hall mobility on the carrier concentration of IGZO.

As indicated by an arrow in FIG. 6C, IGZO has a tendency in which the Hall mobility is higher as the carrier concentration is higher. By contrast, as indicated by an arrow in FIG. 6B, indium oxide has a tendency in which the Hall mobility is higher as the carrier concentration is lower (see Non-Patent Document 2). This tendency is similar to that of silicon; as the concentration of a dopant (impurity) in a material is lower, impurity scattering is inhibited more and thus the Hall mobility is higher. That is, indium oxide having higher purity and being more intrinsic has higher Hall mobility. Consequently, the physical properties of indium oxide are different from those of IGZO and similar to those of silicon. Note that the characteristics of indium oxide in FIG. 6B are based on the assumption of single crystal indium oxide; thus, the characteristics of non-single-crystal (e.g., polycrystal) indium oxide are sometimes different from those in FIG. 6B.

In FIG. 6B, the Hall mobility is extremely high in a range RI with a low carrier concentration; thus, the range R1 can be regarded as a carrier concentration range suitable for a channel formation region of a transistor, for example. In the case of indium oxide, for example, the range R1 is a range including a carrier concentration of 1×10¹⁵ cm⁻³, e.g., a range with a carrier concentration higher than or equal to 1×10¹⁴ cm⁻³ and lower than or equal to 1×10¹⁸ cm⁻³. The adequately lowered carrier concentration will increase the Hall mobility to approximately 270 cm²/(V·s).

A region of indium oxide where the carrier concentration falls within the range R1 can include an element that reduces the carrier concentration. Examples of the element that reduces the carrier concentration include magnesium, calcium, cadmium, and copper. When indium is replaced with any of these elements, the carrier concentration can be reduced. Other examples of the element that reduces the carrier concentration include nitrogen, phosphorus, arsenic, and antimony. For example, when oxygen is replaced with nitrogen, phosphorus, arsenic, or antimony, the carrier concentration can be reduced.

A range R2 with a high carrier concentration has low electric resistance and is a carrier concentration range suitable for a source region and a drain region of a transistor, a resistor, or a transparent conductive film, for example. The range R2 is a range including a carrier concentration of 1×10²⁰ cm⁻³, e.g., a range with a carrier concentration higher than or equal to 1×10¹⁹ cm⁻³ and lower than or equal to 1×10²² cm⁻³. The adequately increased carrier concentration will decrease the resistivity to 1×10⁻⁴ Ω·cm or lower.

A region of indium oxide where the carrier concentration falls within the range R2 can include an element that increases the carrier concentration. For example, the region preferably includes the same element as a source electrode and a drain electrode of a transistor. Examples of the element that increases the carrier concentration include titanium, zirconium, hafnium, tantalum, tungsten, molybdenum, tin, silicon, germanium, and boron. It is particularly preferable that an oxide of the element have conductivity or semiconductor properties. As a method for supplying the element that increases the carrier concentration, a method in which a film containing the element is formed to diffuse the element, an ion implantation method, an ion doping method, a plasma immersion ion implantation method, or plasma treatment can be employed. In this specification and the like, whether or not mass separation is performed is not limited, unless otherwise specified. In this specification and the like, a method by which mass-separated ions are supplied is referred to as an ion implantation method, and a method by which non-mass-separated ions are supplied is referred to as an ion doping method, for example.

In this manner, the region with a low carrier concentration and the region with a high carrier concentration of indium oxide are used as a channel formation region and source and drain regions, respectively, of a transistor. That is, indium oxide can be regarded as an oxide whose valence electron can be controlled. As for IGZO, distortion due to stress of an electrode in contact with IGZO is formed in a source region and a drain region and n-type regions are formed in some cases. Since a valence electron can be controlled in indium oxide unlike in IGZO, formation of distortion can be inhibited in a film of indium oxide. The film with less distortion will have higher reliability. For example, when the region where the carrier concentration falls within the range R1 and the region where the carrier concentration falls within the range R2, which are shown in FIG. 6B, are separately formed in an indium oxide film, what is called an n-i-n junction (a junction between an n-type region, an i-type region, and an n-type region) can be formed. Although valence electron control in a transistor containing silicon is generally known, valence electron control in a transistor containing indium oxide is a novel technical idea that cannot be conceived usually.

With the use of the above technical idea, a transistor containing indium oxide in this specification and the like has two or more, preferably three or more, further preferably four or more, and most preferably all of the following features (1) to (5): (1) high on-state current (i.e., high mobility); (2) low off-state current; (3) normally-off characteristics; (4) high reliability; and (5) high cutoff frequency (fT). For example, the transistor containing indium oxide in this specification and the like has high mobility, low off-state current, and normally-off characteristics. This transistor is different from a normally-on transistor having high mobility.

An indium oxide film in this specification and the like has high film density. The film density of the indium oxide film (here, In₂O₃) applicable to one embodiment of the present invention is shown in Table 2.

TABLE 2
Film density of In₂O₃

| | | | | Film |
|---|---|---|---|---|
| | Condi- | Condi- | Condi- | density |
| | tion 1 | tion 2 | tion 3 | [g/cm³] |
| Sample 1 | Glass | SP | As-depo | 6.72 |
| Sample 2 | Glass | SP | Baking at 350° C., CDA | 6.75 |
| Sample 3 | Glass | SP | Baking at 650° C., CDA | 6.74 |
| Sample 4 | SiOx | ALD | As-depo | 6.97 |
| Sample 5 | YSZ | ALD | As-depo | 7.05 |
| Sample 6 | YSZ | ALD | Baking at 250° C., | 7.08 |
| | | | vacuum | |

As shown in Table 2, the film density of the indium oxide film is evaluated using six samples, Samples 1 to 6. In Table 2, Condition 1 refers to the conditions of a base film of the indium oxide film; glass is used for Samples 1 to 3, a SiOx film formed by a sputtering method is used for Sample 4, and yttria-stabilized zirconia (YSZ) is used for Samples 5 and 6. Condition 2 refers to the film formation conditions of the indium oxide film; Samples 1 to 3 are formed by a sputtering (SP) method and Samples 4 to 6 are formed by an atomic layer deposition (ALD) method. Condition 3 refers to the conditions of heat treatment performed after the formation of the indium oxide film; Samples 1, 4, and 5 are not subjected to the heat treatment (as-depo), Sample 2 is subjected to baking at 350° C. in a CDA atmosphere, Sample 3 is subjected to baking at 650° C. in a CDA atmosphere, and Sample 6 is subjected to baking at 250° C. in a vacuum atmosphere.

In Table 2, CDA means clean dry air. Note that the contents of hydrogen, water, and the like in the atmosphere of the heat treatment performed after the formation of the indium oxide film (corresponding to Condition 3) are preferably as low as possible. As the atmosphere, a high-purity gas with a dew point of −60° C. or lower, preferably −100° C. or lower is preferably used.

As shown in Table 2, the indium oxide film subjected to the heat treatment tends to have higher film density than the indium oxide film not subjected to the heat treatment (Sample 1, 4, or 5). This is due to an increase in the purity of the indium oxide film caused by release of an impurity element (e.g., carbon, nitrogen, hydrogen, or argon) from the film by the heat treatment. As in Samples 5 and 6, the film density of the indium oxide film over the YSZ is higher than 7.00 g/cm³. The theoretical film density of the indium oxide film is 7.18 g/cm³. The film density of the indium oxide film in this specification and the like ranges from 6.70 g/cm³ to 7.18 g/cm³, preferably from 6.90 g/cm³ to 7.18 g/cm³, further preferably from 7.00 g/cm³ to 7.18 g/cm³.

The film density can be evaluated by Rutherford backscattering spectrometry (RBS) or X-ray reflection (XRR), for example. A difference in film density can be evaluated using a cross-sectional TEM image in some cases. In TEM observation, a transmission electron (TE) image is dark-colored (dark) when the film density is high, and a TE image is pale (bright) when the film density is low.

When an atom that can be a cation with a valence of 4 or more is added to indium oxide, for example, the atom is replaced with an indium atom, one or more electrons are in excess, and no level is formed in the forbidden band; thus, an n-type region can be formed. Examples of the atom include tin, antimony, germanium, and titanium. That is, when the atom is added to indium oxide, a region to which the atom is added has an increased carrier concentration and thus can be used as a source region or a drain region.

The concentration of the first element can be evaluated by, for example, inductively coupled plasma-mass spectrometry (ICP-MS), X-ray photoelectron spectroscopy (XPS), secondary ion mass spectrometry (SIMS), time-of-flight secondary ion mass spectrometry (ToF-SIMS), auger electron spectroscopy (AES), energy dispersive X-ray spectroscopy (EDX), inductively coupled plasma-atomic emission spectroscopy (ICP-AES), or the like.

Hydrogen contained in an oxide semiconductor reacts with oxygen bonded to a metal atom to produce water, and thus causes an oxygen vacancy in some cases. Accordingly, the electrical characteristics easily vary, and the reliability is degraded in some cases. Meanwhile, hydrogen at a crystal grain boundary sometimes terminates a dangling bond at the crystal grain boundary to improve the electrical characteristics and reliability of the transistor. Thus, the hydrogen concentration in the indium oxide film is preferably reduced, but may be higher than the concentration of the first element. The band gap of indium oxide is greater than or equal to 2.5 eV and less than or equal to 3.7 eV. The use of indium oxide having a wider band gap than silicon for the semiconductor layer 230 leads to a low off-state current of the transistor, so that the power consumption of the semiconductor device can be sufficiently reduced.

A transistor including an indium oxide film is an accumulation-type transistor in which electrons are majority carriers. Assuming that the relaxation time of carriers is constant, the electron mobility is higher as the effective mass of electrons (carriers) is smaller. That is, a transistor containing indium oxide with a small effective mass of electrons can have a high on-state current or high field-effect mobility.

Table 3 shows the effective mass in each of single crystal indium oxide (here, In₂O3), single crystal In—Ga—Zn oxide (here, IGZO), and single crystal silicon (Si). The effective mass of electrons (me) and the effective mass of holes (m*h) shown in Table 3 are calculated by the first-principles electron state calculation.

For the first-principles electron state calculation, a first-principles electron state calculation package, Quantum ESPRESSO, is used. The package is based on density functional theory (DFT) using a plane wave basis and a pseudopotential. As the exchange-correlation functional, generalized-gradient-approximation/Perdew-Burke-Ernzerhof (GGA/PBE) is used. An ultrasoft type pseudopotential is used as the pseudopotential. The cutoff energy of the wave function is 100 Ry, and the cutoff energy of the electron density is 900 Ry. Spin polarization is not applied.

First, calculation for optimizing a structure (also referred to as structural optimization calculation) is performed, self-consistent field (SCF) calculation is performed, and then band calculation is performed. By the band calculation, an E-k dispersion curve can be obtained. Next, the band edges in the E-k dispersion curve are fitted with a quadratic function to calculate the effective mass of electrons and the effective mass of holes.

TABLE 3

| | In₂O₃ | IGZO | Si |
|---|---|---|---|
| m*ₑ | 0.17 | 0.21 | 0.26 |
| m*ₕ | 3.56 | 4.89 | 0.17 |
| m*ₕ/m*ₑ | 20.9 | 23.3 | 0.65 |
| Eg | 2.94 eV | 3.028 eV | 1.11 eV |
| | | 3.14 eV | |
| I_{off} | 1.29 × 10⁻²⁰ | 1.01 × 10⁻²⁰ | 3.56 × 10⁻¹⁰ |
| | A/FET @85° C. | A/FET @85° C. | A/FET @85° C. |

As shown in Table 3, the effective mass of electrons in indium oxide is small. Thus, the use of indium oxide with a small effective mass of electrons for the semiconductor layer 230 enables a transistor to have a high on-state current, high field-effect mobility, or high frequency characteristics (also referred to as f characteristics). In addition, the effective mass of electrons in indium oxide hardly depends on the crystal orientation. The effective mass of electrons in indium oxide is smaller than that in silicon, for example. Hence, in terms of the effective mass of electrons, the f characteristics of a transistor containing indium oxide in its channel formation region are higher than those of a Si transistor.

As shown in Table 3, the effective mass of holes in indium oxide is large. Thus, the use of indium oxide with a large effective mass of holes for the semiconductor layer 230 enables a transistor to have an extremely low off-state current. The effective mass of holes in indium oxide is larger than that in silicon, for example. Specifically, the effective mass of holes in indium oxide is approximately 20 times larger than that in silicon, for example. Hence, in terms of the effective mass of holes, the off-state current of a transistor containing indium oxide in its channel formation region is sufficiently lower than that of a Si transistor. As shown in Table 3, the off-state current Ioff of the transistor containing indium oxide in its channel formation region is lower than that of the Si transistor by ten orders of magnitude. Table 3 also shows typical values of the band gaps (Eg) of the materials. Note that 3.028 eV and 3.14 eV in Table 3 respectively represent typical Eg of an In—Ga—Zn oxide film formed by an ALD method and an In—Ga—Zn oxide film formed by a sputtering method.

The off-state current per micrometer of channel width of the transistor in which indium oxide is used for the semiconductor layer 230 at room temperature (25° C.) can be lower than or equal to 1×10⁻¹⁷ A/μm, preferably lower than or equal to 1×10⁻¹⁸ A/μm, further preferably lower than or equal to 1×10⁻¹⁹ A/μm. The off-state current per micrometer of channel width at 85° C. can be lower than or equal to 1×10⁻¹⁶ A/μm, preferably lower than or equal to 1×10⁻¹⁷ A/μm, further preferably lower than or equal to 1×10⁻¹⁸ A/μm.

Scaling down of an OS transistor can improve the high-frequency characteristics of the transistor. For example, the cutoff frequency (fT) of the transistor can be improved. Specifically, the cutoff frequency of the transistor can be higher than or equal to 50 GHz, preferably higher than or equal to 100 GHz, further preferably higher than or equal to 150 GHz at room temperature (25° C.).

A reduction in crystal grain boundaries in indium oxide can inhibit carrier scattering or the like at the crystal grain boundaries, so that a gate electric field of the conductive layer 260 can be easily applied. A reduction in crystal grain boundaries in indium oxide can also inhibit entry of impurities into the indium oxide through the crystal grain boundaries, so that the amount of impurities in the indium oxide film can be reduced. Accordingly, the on-state current of a transistor can be improved and the subthreshold swing value (the S value) of the transistor can be reduced. Specifically, the S value of the transistor can be greater than or equal to 60 mV/dec. and less than or equal to 120 mV/dec., preferably greater than or equal to 60 mV/dec. and less than or equal to 100 m V/dec., further preferably greater than or equal to 60 mV/dec. and less than or equal to 80 mV/dec. Note that the S value means the amount of change in gate voltage in a subthreshold region when drain voltage is constant and drain current is changed by one order of magnitude.

The semiconductor layer 230 is preferably formed by an ALD method. With the use of an ALD method in which deposition is performed at an atomic level, generation of a crystal nucleus in a film can be inhibited as compared with the case of using a sputtering method in which particles are made to collide with the formation surface. For example, the semiconductor layer 230 can be formed using a first precursor and a first oxidizer. The first precursor preferably contains indium. In that case, an indium oxide film is formed as the semiconductor layer 230. In the case where the first precursor contains indium, a thermal ALD method can be used as the ALD method.

As the precursor containing indium, it is possible to use trimethylindium, triethylindium, ethyldimethylindium, tris(1-methylethyl) indium, tris(2,2,6,6-tetramethyl-3,5-heptanedionato) indium, cyclopentadienylindium, indium (III) acetylacetonate, (3-(dimethylamino) propyl)dimethylindium, (diethylphosphino)dimethylindium, chlorodimethylindium, bromodimethylindium, dimethyl (2-propanolato) indium, or the like.

As the precursor containing indium, an inorganic precursor not containing hydrocarbon may be used. As the inorganic precursor containing indium, it is possible to use a halogen-based indium compound such as trifluoroindium (indium (III) fluoride), indium trichloride (indium (III) chloride), indium tribromide (indium (III) bromide), or indium triiodide (indium (III) iodide). The decomposition temperature of indium trichloride is approximately higher than or equal to 500° C. and lower than or equal to 700° C. Thus, with the use of indium trichloride, film formation can be performed by an ALD method while a substrate is being heated at approximately higher than or equal to 400° C. and lower than or equal to 600° C., e.g., at 500° C.

In the method for forming the semiconductor layer 230, it is preferable to use a precursor with a low impurity concentration, i.e., a high-purity precursor. For example, the use of a precursor having a purity higher than or equal to 3N (99.9%), preferably higher than or equal to 4N (99.99%), further preferably higher than or equal to 5N (99.999%), still further preferably higher than or equal to 6N (99.9999%) can reduce impurities in the semiconductor layer 230.

The gallium content and the aluminum content in the precursor containing indium are each preferably less than or equal to 1000 ppm, further preferably less than or equal to 500 ppm, still further preferably less than or equal to 100 ppm, yet further preferably less than or equal to 50 ppm, yet still further preferably less than or equal to 10 ppm, yet still further preferably less than or equal to 1 ppm. With the use of a precursor having a low gallium content, the concentration of gallium in the semiconductor layer 230 can be reduced and the reliability of the transistor can be increased. Furthermore, with the use of a precursor having a low aluminum content, the concentration of aluminum in the semiconductor layer 230 can be reduced and the crystallinity of the semiconductor layer 230 can be improved.

As the precursor used in this embodiment, a precursor purified by two or more times of distillation (also referred to as “rectification” or “precision distillation”) is preferably used. The use of such a precursor is preferable to facilitate formation of a metal oxide containing few impurities.

Distillation is preferably performed a plurality of times to further inhibit impurities due to a starting material used to produce the precursor from remaining in the precursor. Note that the present invention is not limited to the above, and a precursor subjected to distillation once, i.e., single distillation, may be used. The single distillation is preferable in terms of a reduction in manufacturing cost. By performing one or more times of distillation, the aluminum content in the precursor containing indium can be lower than or equal to 100 ppm, lower than or equal to 1 ppm, or lower than or equal to 1 ppb (0.001 ppm).

Ozone (O₃), oxygen (O2), water (H₂O), hydrogen peroxide (H₂O₂), or the like can be used as the first oxidizer. The first oxidizer preferably contains at least one of ozone and oxygen. When ozone, oxygen, or the like not containing hydrogen is used as the first oxidizer, the amount of hydrogen mixed into the semiconductor layer 230 can be reduced.

In this specification and the like, unless otherwise specified, ozone, oxygen, and water that can be used as an oxidizer include not only those in gas or molecular states but also those in plasma, radical, and ion states.

The pulse time for introducing the first oxidizer is preferably longer than or equal to 0.1 seconds and shorter than or equal to 30 seconds, further preferably longer than or equal to 0.3 seconds and shorter than or equal to 15 seconds, still further preferably longer than or equal to 0.3 seconds and shorter than or equal to 10 seconds. The pulse time for introducing the first oxidizer is shortened to reduce the amount of introduced first oxidizer, so that a larger amount of hydrogen contained in the first precursor remains in the film. When a larger amount of hydrogen remains in the film, generation of crystal nuclei can be inhibited and some crystal nuclei in the film can be eliminated; accordingly, the number of crystal nuclei in the film can be reduced.

Here, the substrate heating temperature at the time of introducing the first precursor into a reaction chamber is preferably a temperature corresponding to the decomposition temperature of the first precursor. In the case of a thermal ALD method in which triethylindium is used as the precursor containing indium, the substrate heating temperature can be higher than or equal to 100° C. and lower than or equal to 350° C., preferably higher than or equal to 150° C. and lower than or equal to 300° C., for example. Note that in the case where an oxide layer 229 described later is provided, the substrate heating temperature can be higher than or equal to room temperature (25° C.) and lower than or equal to 300° C., preferably higher than or equal to room temperature and lower than or equal to 200° C., further preferably higher than or equal to room temperature and lower than or equal to 150° C.

When the semiconductor layer 230 is formed by an ALD method after the oxide layer 229 described later is provided, the semiconductor layer 230 having crystallinity can sometimes be formed in the process of forming the semiconductor layer 230. For example, when the substrate heating temperature in the film formation by an ALD method is higher than or equal to 100° C. and lower than or equal to 300° C., or higher than or equal to 150° C. and lower than or equal to 250° C., the semiconductor layer 230 having crystallinity can be formed at the time of the film formation.

Note that the semiconductor layer 230 can also be formed by a sputtering method, a chemical vapor deposition (CVD) method, a molecular beam epitaxy (MBE) method, or a pulsed laser deposition (PLD) method.

In order to increase the crystallinity of the semiconductor layer 230, an oxide layer is preferably provided over the conductive layer 240 and/or the conductive layer 220. The oxide layer functions as a seed or a nucleus for increasing the crystallinity of the semiconductor layer 230. Thus, the oxide layer can be referred to as a seed layer, a seed crystal, a crystal nucleus, or the like. Providing the oxide layer enables the semiconductor layer 230 having high crystallinity to be formed at a given position (e.g., on the top surface or the side surface of the insulating layer 280).

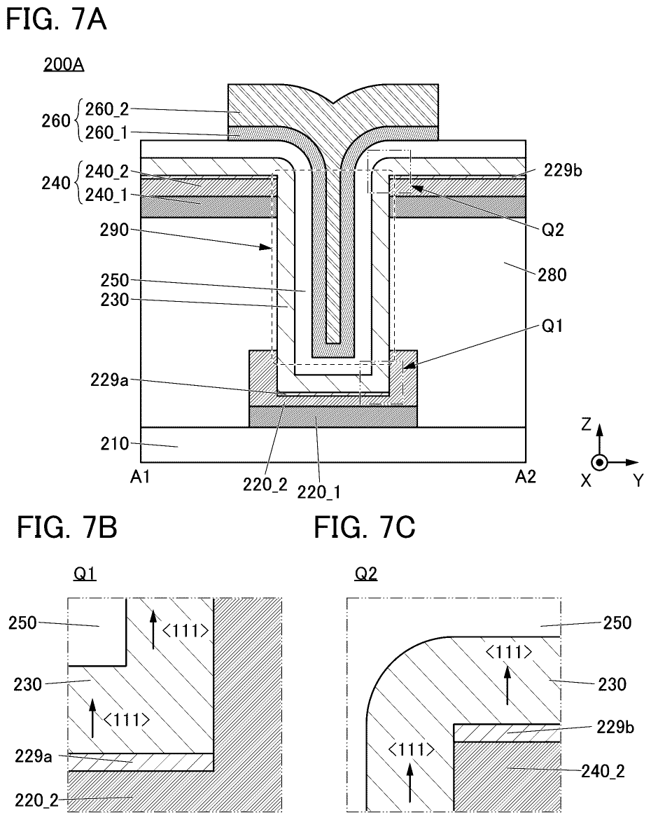

In FIG. 7A, as the oxide layer, an oxide layer 229a positioned between the conductive layer 220 and the semiconductor layer 230 and an oxide layer 229b positioned between the conductive layer 240 and the semiconductor layer 230 are provided. Hereinafter, the oxide layer 229a and the oxide layer 229b are sometimes collectively referred to as the oxide layer 229.

In order to increase the crystallinity of the semiconductor layer 230, indium oxide is preferably used for the oxide layer 229. When indium oxide is used for the oxide layer 229 and the semiconductor layer 230, the semiconductor layer 230 can homoepitaxially grow with the oxide layer 229 used as a seed or a nucleus, so that the crystallinity of the semiconductor layer 230 can be increased. In that case, the orientation of a first crystal included in the oxide layer 229 is aligned or substantially aligned with the orientation of a second crystal included in the semiconductor layer 230.

An indium oxide crystal has a cubic crystal structure (bixbyite structure). Thus, an oxide layer including the first crystal having a hexagonal or trigonal crystal structure can be used as the oxide layer 229. In that case, the oxide layer 229 is formed such that the <001> orientation of the first crystal is perpendicular or substantially perpendicular to the substrate plane or the formation surface, so that the semiconductor layer 230 including the second crystal whose <111> orientation is parallel or substantially parallel to the <001> orientation of the first crystal can be formed.

FIG. 7B is an enlarged view of a region Q1 surrounded by a dashed-dotted line in FIG. 7A, and FIG. 7C is an enlarged view of a region Q2 surrounded by another dashed-dotted line in FIG. 7A. When the oxide layer 229a is provided to include the first crystal which has a hexagonal or trigonal crystal structure and whose <001> orientation is perpendicular or substantially perpendicular to the substrate plane or the formation surface, the <111> orientation of a crystal positioned between the oxide layer 229a and the insulating layer 250 is aligned or substantially aligned with the <111>orientation of a crystal positioned between the insulating layer 250 and the side surface of the depressed portion of the conductive layer 220_2 (see FIG. 7B). Similarly, when the oxide layer 229b is provided to include the first crystal which has a hexagonal or trigonal crystal structure and whose <001> orientation is perpendicular or substantially perpendicular to the substrate plane or the formation surface, the <111> orientation of a crystal positioned over the oxide layer 229b is aligned or substantially aligned with the <111> orientation of a crystal positioned between the insulating layer 250 and the side surface of the conductive layer 240_2 in the opening portion 290 (see FIG. 7C). That is, the <111> orientation of the crystal of the semiconductor layer 230 that is included in the opening portion 290 can be regarded as being parallel or substantially parallel to the depth direction of the opening portion 290.

In this specification and the like, a space group is represented using the short symbol of the international notation (or the Hermann-Mauguin notation). In addition, the Miller index is used for the expression of crystal planes and crystal orientations. In the crystallography, a bar is placed over a number in the expression of space groups, crystal planes, and crystal orientations; in this specification and the like, because of format limitations, space groups, crystal planes, and crystal orientations are sometimes expressed by placing a minus sign (−) in front of a number instead of placing a bar over the number. Furthermore, an individual direction that shows an orientation in crystal is expressed with “[ ]”, a set direction that shows all of the equivalent orientations is expressed with “< >”, an individual plane that shows a crystal plane is expressed with “( ), and a set plane having equivalent symmetry is expressed with “{ }”.

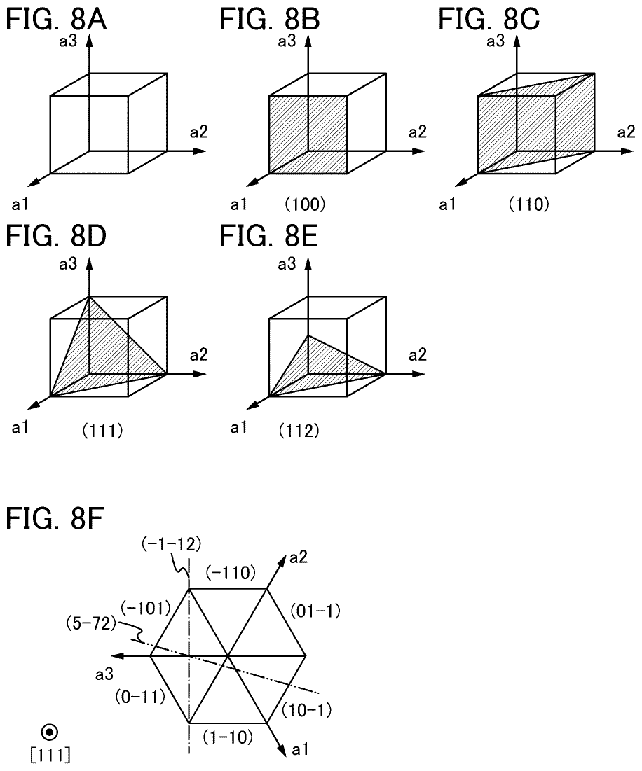

FIGS. 8A to 8E each illustrate a unit lattice and its principal axes (an a1-axis, an a2-axis, and an a3-axis). FIGS. 8A to 8E each illustrate the unit lattice of a cubic crystal system. That is, the a1-axis, the a2-axis, and the a3-axis are orthogonal to one another, and the length of the lattice in the a1-axis direction, the length of the lattice in the a2-axis direction, and the length of the lattice in the a3-axis direction are equal to one another. For example, the (hkl) plane refers to a plane including three points defined by 1/h in the a1-axis direction, 1/k in the a2-axis direction, and 1/l in the a3-axis direction. As examples of crystal planes, the (100) plane, the (110) plane, the (111) plane, and the (112) plane are illustrated with oblique lines in FIGS. 8B, 8C, 8D, and 8E, respectively. The [hkl] orientation refers to the normal of the (hkl) plane.

In a cubic crystal system, the (100) plane, the (010) plane, the (001) plane, the (−100) plane, the (0-10) plane, and the (00-1) plane are equivalent in terms of symmetry; thus, these planes can be

collectively referred to as the {100} plane. In a cubic crystal system, the orientation, the orientation, the orientation, the [-100] orientation, the [0-10] orientation, and the [00-1] orientation are equivalent in terms of symmetry; thus, these orientations can be collectively referred to as the <100> orientation.

The above crystal planes and crystal orientations are applicable to the unit lattices of crystal systems other than a cubic crystal system (e.g., a triclinic crystal system, a monoclinic crystal system, a tetragonal crystal system, an orthorhombic crystal system, a rhombohedral crystal system (a crystal system having symmetry of one 3-fold rotation axis or symmetry of one 3-fold rotary inversion axis, also referred to as a trigonal crystal system), and a hexagonal crystal system). The Miller-Bravais index (hkil) can also be used for representing the unit lattice of a hexagonal crystal system, in which case the number of indices for representing the crystal plane and the crystal orientation is four. Note that i is −(h+k).

In this specification and the like, a crystal orientation of a crystal refers to an orientation with respect to a surface of a substrate, unless otherwise specified. Note that a crystal orientation of a crystal may be an orientation with respect to a surface where a film or a layer that includes the crystal is formed.

The oxide layer 229 corresponds to the first layer 11 described in Embodiment 1. Thus, for the structure, material, and the like of the oxide layer 229, the structure, material, and the like of the first layer 11 described in Embodiment 1 can be referred to.

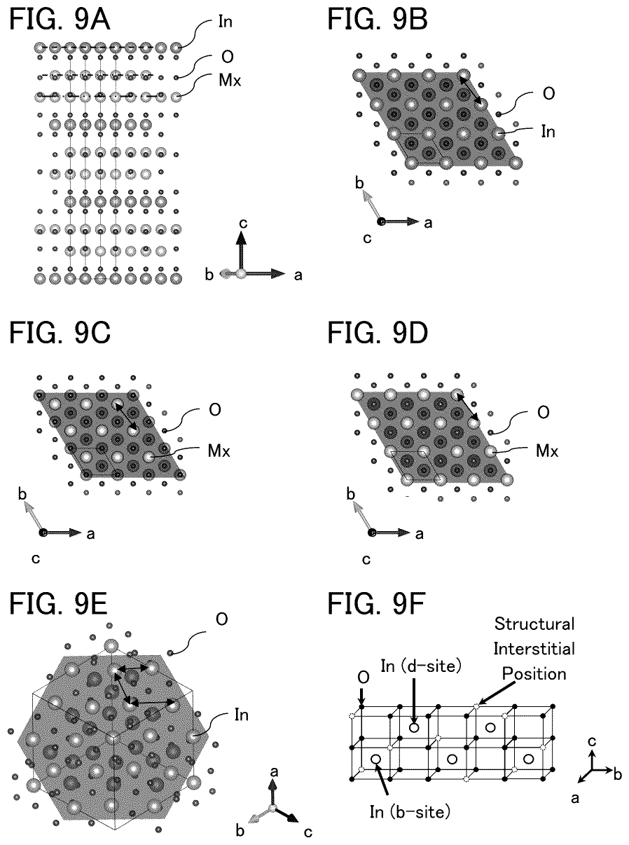

Here, crystal structures of a metal oxide are shown in FIGS. 9A to 9F. FIG. 9A shows a crystal structure of an In—Ga—Zn oxide with an atomic ratio of In:Ga:Zn=1:1:1 seen from the direction perpendicular to the c-axis. FIG. 9B shows a plane indicated by a dashed line in FIG. 9A, seen from the c-axis direction. FIG. 9C shows a plane indicated by a dashed-dotted line in FIG. 9A, seen from the c-axis direction. FIG. 9D shows a plane indicated by a dashed double-dotted line in

FIG. 9A, seen from the c-axis direction. Mx shown in FIGS. 9A, 9C, and 9D represents a Ga atom or a Zn atom. Note that in FIG. 9A, the plane indicated by the dashed line, the plane indicated by the dashed-dotted line, and the plane indicated by the dashed double-dotted line are collectively referred to as a c-plane in some cases. FIG. 9E shows the crystal structure of indium oxide seen from the direction perpendicular to the (111) plane.

The distance between metal atoms on the c-plane (a double-headed arrow in each of FIGS. 9B to 9D) is said to be 0.330 nm. The distances between In atoms on the (111) plane (double-headed arrows in FIG. 9E) are said to be 0.334 nm and 0.385 nm. That is, the arrangement of metal atoms seems to be similar between the c-plane of the CAAC structure and the (111) plane of indium oxide. Thus, an oxide that tends to have a CAAC structure can be suitably used for the oxide layer 229.

FIG. 9F is a schematic view of a crystal structure of indium oxide taken along the (100) plane. In FIG. 9F, lattice distortion is ignored. In addition, two kinds of sites (a d-site and a b-site) of indium (In) are distinguished from each other. Structural interstitial positions near In in the d-site are positioned face-diagonally. An octahedron formed of In in the d-site at the center and six oxygen (O) atoms around In has distortion. Structural interstitial positions near In in the b-site are positioned body-diagonally. An octahedron formed of In in the b-site at the center and six oxygen atoms around In does not have distortion. As illustrated in FIG. 9F, an indium oxide crystal includes structural interstitial positions.

A difference in the lattice constant or the length of a unit lattice vector between the first crystal and the second crystal (also referred to as a lattice mismatch) is preferably small. The use of an oxide that makes a lattice mismatch small for the oxide layer 229 can increase the crystallinity of the semiconductor layer 230.

One of methods for evaluating the degree of a lattice mismatch is a method using a value of a lattice mismatch degree described below. A lattice mismatch degree Aa [%] of a crystal included in a formed film (here, the indium oxide film) with respect to a crystal included in a film on which the film is formed is calculated by Formula (1) below. Hereinafter, the lattice mismatch degree Aa of the crystal included in the formed film with respect to the crystal included in the film on which the film is formed may be simply referred to as the lattice mismatch degree Aa of the formed film with respect to the film on which the film is formed.

$$\begin{matrix}[ Formula 1 ] & \\ Δ a = ( \frac{{L}_{1}}{{L}_{2}} - 1 ) \times 100 & ( 1 )\end{matrix}$$

In Formula (1), L1 is the lattice constant or the length of the unit lattice vector of the crystal included in the formed film, and L2 is the lattice constant or the length of the unit lattice vector of the crystal included in the film on which the film is formed.

The lattice mismatch degree Aa of the second crystal with respect to the first crystal is preferably higher than or equal to −10% and lower than or equal to 10%, further preferably higher than or equal to −5% and lower than or equal to 5%, still further preferably higher than or equal to −3% and lower than or equal to 3%. When a material that makes the lattice mismatch degree with respect to the semiconductor layer 230 low is used for the oxide layer 229, the crystallinity of the semiconductor layer 230 can be increased.

An oxide including the first crystal having a cubic crystal structure can also be used for the oxide layer 229. When the first crystal has the same crystal structure as the second crystal, the semiconductor layer 230 can epitaxially grow with the oxide layer 229 used as a seed or a nucleus, so that the crystallinity of the semiconductor layer 230 can be increased. Note that a crystal of an oxide containing a Group 3 element in the periodic table is likely to have a cubic crystal system. The Group 3 element in the crystal mainly exists as trivalent cations. Thus, the oxide layer 229 preferably contains at least one of elements that can be trivalent cations. As the element that can be a trivalent cation contained in the oxide layer 229, scandium, yttrium, cerium, gadolinium, erbium, ytterbium, or the like is preferably used.

As the oxide layer 229, an oxide containing one or both of yttrium and zirconium, erbium oxide, or the like can be used, for example. Examples of the oxide containing one or both of yttrium and zirconium include yttrium oxide, zirconium oxide, and yttrium zirconium oxide.

The thickness of the oxide layer 229 is preferably small. For example, the thickness of the oxide layer 229 is preferably smaller than that of the semiconductor layer 230. Specifically, the oxide layer 229 preferably includes a region with a thickness greater than or equal to 0.1 nm and less than 2 nm, further preferably includes a region with a thickness greater than or equal to 0.5 nm and less than 2 nm. When the thickness of the oxide layer 229 is small, a step generated between the oxide layer 229 and the insulating layer 280 is reduced. Thus, the coverage with the semiconductor layer 230 can be improved and the number of defects such as voids can be reduced. In addition, the crystal growth of the semiconductor layer 230 can be promoted. Even when the oxide layer 229 has an insulating property, the semiconductor layer 230 can be in contact with the conductive layer 220 or the conductive layer 240, so that an increase in contact resistance can be inhibited.

There is no particular limitation on the method for forming the oxide layer 229. For example, a film to be the oxide layer 229 is formed and then processed, whereby the oxide layer 229 can be formed. The film can be formed by a sputtering method, a CVD method, a vacuum evaporation method, a PLD method, an ALD method, or the like.

The oxide layer 229 is preferably formed by a sputtering method. The above film is formed by a sputtering method after the opening portion 290 is formed, so that the oxide layers 229a and 229b illustrated in FIG. 7A can be formed. Thus, the number of fabrication steps of the semiconductor device can be smaller than that in the case where the film is processed. The use of a sputtering method can increase the crystallinity of the oxide layer 229.

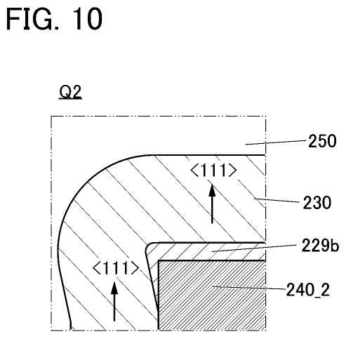

As illustrated in FIG. 10, the oxide layer 229b sometimes has a portion in contact with part of the sidewall of the opening portion 290 (part of the side surface of the conductive layer 240_2 in the opening portion 290). In that case, the contact area between the oxide layer 229b and the semiconductor layer 230 is increased, so that the crystallinity of the semiconductor layer 230 can sometimes be increased.

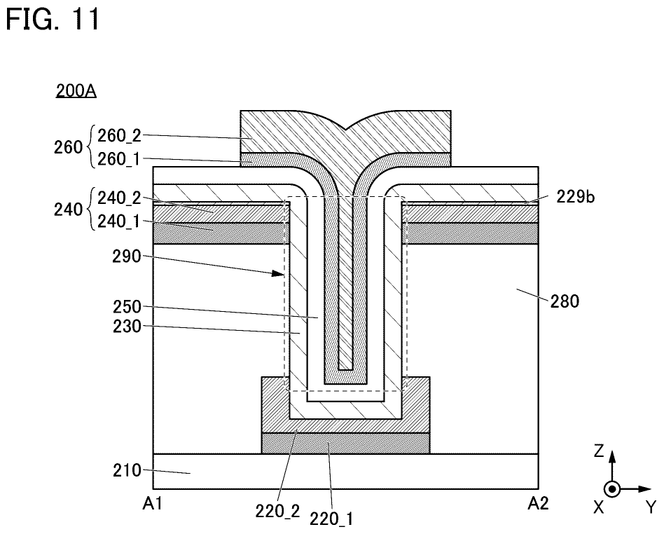

As illustrated in FIG. 11, the oxide layer 229a is not formed in some cases depending on the width, shape, or the like of the opening portion 290. In other words, only the oxide layer 229b is formed in some cases depending on the width, shape, or the like of the opening portion 290. Only the oxide layer 229b can be formed in the following manner: an oxide film to be the oxide layer 229 is formed, and then the opening portion 290 reaching the conductive layer 220 is formed in the oxide film, a conductive film to be the conductive layer 240, and the insulating layer 280. With such a structure, the number of oxide layers 229 functioning as seeds or nuclei can be smaller than that in the case where the oxide layer 229a is provided; thus, the crystallinity of the semiconductor layer 230 can be increased.

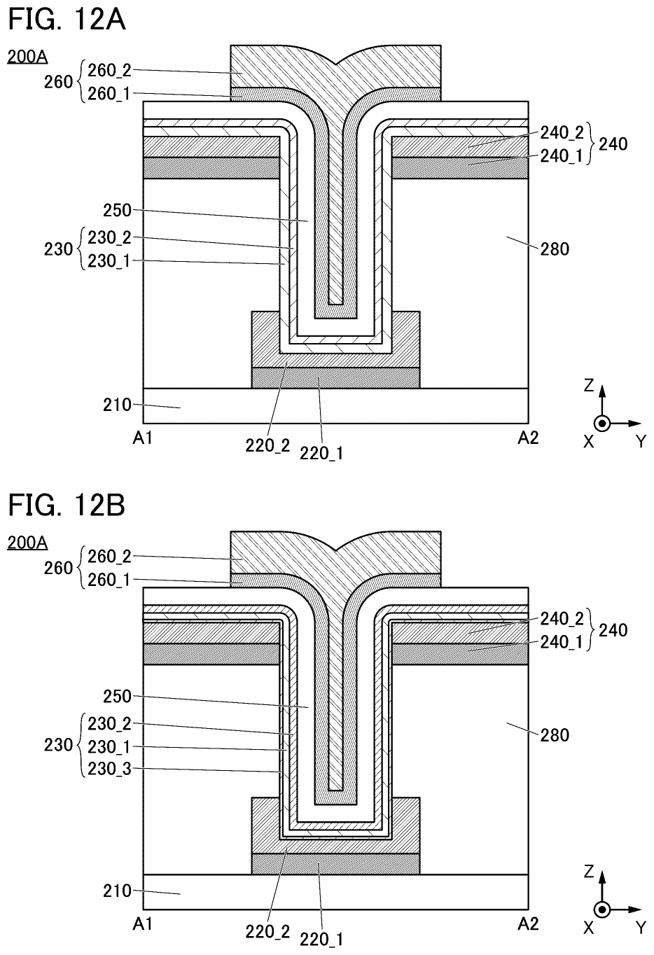

FIG. 4A illustrates an example in which the semiconductor layer 230 has a single-layer structure. The semiconductor layer 230 can have a stacked-layer structure of two or more layers. For example, as illustrated in FIG. 12A, the semiconductor layer 230 can have a two-layer structure of a semiconductor layer 230_1 and a semiconductor layer 230_2 over the semiconductor layer 230_1. In that case, it is preferable that the metal oxide that can be used for the semiconductor layer 230 (typically, indium oxide) be used for the semiconductor layer 230_1, and a metal oxide whose conduction band minimum is closer to the vacuum level than the conduction band minimum of the semiconductor layer 230_1 is be used for the semiconductor layer 230_2. Here, the semiconductor layer 230_1 can function mainly as a current path (channel). That is, the semiconductor layer 230_1 includes a channel formation region on its surface on the semiconductor layer 230_2 side and in the vicinity thereof.

The above structure can reduce the number of carriers trapped at the interface between the semiconductor layer 230_1 and the semiconductor layer 230_2 and its vicinity. Moreover, the channel can be distanced from the surface of the insulating layer 250, so that the influence of surface scattering can be reduced. Thus, the field-effect mobility of the transistor can be increased.

Examples of the metal oxide that can be used for the semiconductor layer 230_2 include In—Ga oxide, In—Zn oxide, indium tin oxide (also referred to as In—Sn oxide or ITO), indium titanium oxide (also referred to as In—Ti oxide), In—Al—Zn oxide, In—Ga—Zn oxide, In—Sn—Zn oxide, indium titanium zinc oxide (also referred to as In—Ti—Zn oxide), and indium tin oxide containing silicon oxide (also referred to as ITSO). Alternatively, zinc oxide, aluminum zinc oxide (also referred to as A1-Zn oxide or AZO), aluminum tin oxide (also referred to as A1-Sn oxide), or the like can be used.

Specifically, the In—Zn oxide used for the semiconductor layer 230_2 can have an atomic ratio of In:Zn=1:1 or the neighborhood thereof, In:Zn=2:1 or the neighborhood thereof, or In:Zn=4:1 or the neighborhood thereof. Furthermore, specifically, IGZO used for the semiconductor layer 230_2 can have an atomic ratio of In:Ga:Zn=1:1:1 or the neighborhood thereof, In:Ga:Zn=1:3:2 or the neighborhood thereof, or In:Ga:Zn=1:3:4 or the neighborhood thereof. Note that the neighborhood of the atomic ratio includes +30% of an intended atomic ratio.

The semiconductor layer 230_2 may correspond to the third layer 13 described in Embodiment 1. In that case, the structure, material, and the like of the third layer 13 described in Embodiment 1 may be referred to for the structure, material, and the like of the semiconductor layer 230_2. Alternatively, the semiconductor layer 230_2 may correspond to the second layer 12 described in Embodiment 1. In that case, the structure, material, and the like of the second layer 12 described in Embodiment 1 may be referred to for the structure, material, and the like of the semiconductor layer 230_2.

There is no particular limitation on the crystallinity of the metal oxide included in the semiconductor layer 230_2. The semiconductor layer 230_2 sometimes includes, for example, at least one of an amorphous semiconductor (a semiconductor having an amorphous structure), a single crystal semiconductor (a semiconductor having a single crystal structure), and a semiconductor having crystallinity other than single crystal (a microcrystalline semiconductor, a polycrystalline semiconductor, or a semiconductor partly including crystal regions).

As illustrated in FIG. 12B, a semiconductor layer 230_3 can be provided below the semiconductor layer 230_1. In that case, the semiconductor layer 230 has a three-layer structure. The resistivity of the semiconductor layer 230_3 is preferably higher than that of the semiconductor layer 230_1. Providing the semiconductor layer 230_3 having high resistivity between the semiconductor layer 230_1 and the conductive layer 220 or the conductive layer 240 can inhibit a negative shift of the threshold voltage or an increase in off-state current. Accordingly, the threshold voltage of the transistor 200A shifts positively, so that the transistor 200A can have normally-off characteristics. In this manner, the electrical characteristics and reliability of the transistor 200A can be improved.

The thickness of the semiconductor layer 230_3 is preferably smaller than that of the semiconductor layer 230_1. Specifically, the semiconductor layer 230_3 preferably includes a region with a thickness greater than or equal to 0.1 nm and less than or equal to 3 nm, further preferably includes a region with a thickness greater than or equal to 0.1 nm and less than or equal to 2 nm. Alternatively, the semiconductor layer 230_3 preferably includes a region with a thickness greater than or equal to 0.5 nm and less than or equal to 3 nm, further preferably includes a region with a thickness greater than or equal to 0.5 nm and less than or equal to 2 nm. Such a structure can inhibit an increase in contact resistance between the semiconductor layer 230_1 and the conductive layer 220 or the conductive layer 240.

Specifically, gallium oxide, zinc oxide, In—Ga oxide, Ga—Zn oxide, A1-Zn oxide, In—Ga—Zn oxide, or the like can be used for the semiconductor layer 230_3.

In the case where the semiconductor layer 230 has a stacked-layer structure, the semiconductor layer 230 can also be formed by a sputtering method and an ALD method, for example. In the case where the semiconductor layer 230 has the two-layer structure of the semiconductor layer 230 1 and the semiconductor layer 230_2 as illustrated in FIG. 12A, for example, the semiconductor layer 230_1 can be formed by an ALD method and the semiconductor layer 230_2 can be formed by a sputtering method. Since an ALD method is a film formation method that provides better coverage than a sputtering method, forming the semiconductor layer 230_1 by an ALD method can improve the coverage with the semiconductor layer 230. Furthermore, damage to a base (here, the conductive layer 220 or the conductive layer 240) can be reduced and formation of a mixed layer at the interface between the base and the semiconductor layer 230 can be inhibited, so that higher crystallinity can be achieved. When the semiconductor layer 230_2 is formed by a sputtering method, the productivity can be increased.

Alternatively, the semiconductor layer 230_1 may be formed by a sputtering method and the semiconductor layer 230_2 may be formed by an ALD method. Even when a pinhole, disconnection, or the like is generated in the semiconductor layer 230_1 formed by a sputtering method, such a portion can be filled with the semiconductor layer 230_2 formed by an ALD method that provides excellent coverage.

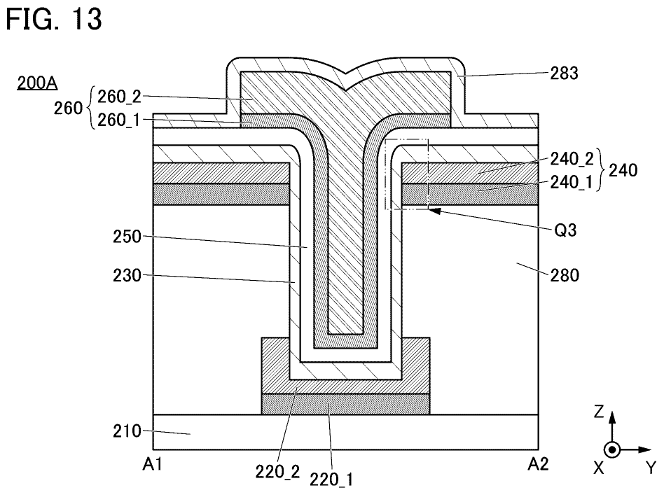

As illustrated in FIG. 13, a ratio between the thickness of a portion of the semiconductor layer 230 that is formed over the top surface of the conductive layer 240 or the conductive layer 220 (hereinafter, the thickness is referred to as a first thickness) and the thickness of a portion of the semiconductor layer 230 that is formed over the sidewall of the opening portion 290 (hereinafter, the thickness is referred to as a second thickness) sometimes varies. In the case where part of the semiconductor layer 230 is formed by a sputtering method, for example, the ratio between the first thickness and the second thickness of the semiconductor layer 230 sometimes varies. For example, as illustrated in FIG. 13, the ratio of the second thickness to the first thickness is lower than 1, lower than 0.8, or lower than 0.5 in some cases. In particular, as an angle θ280 described later is closer to 90°, the ratio of the second thickness to the first thickness of the semiconductor layer 230 tends to be lower.

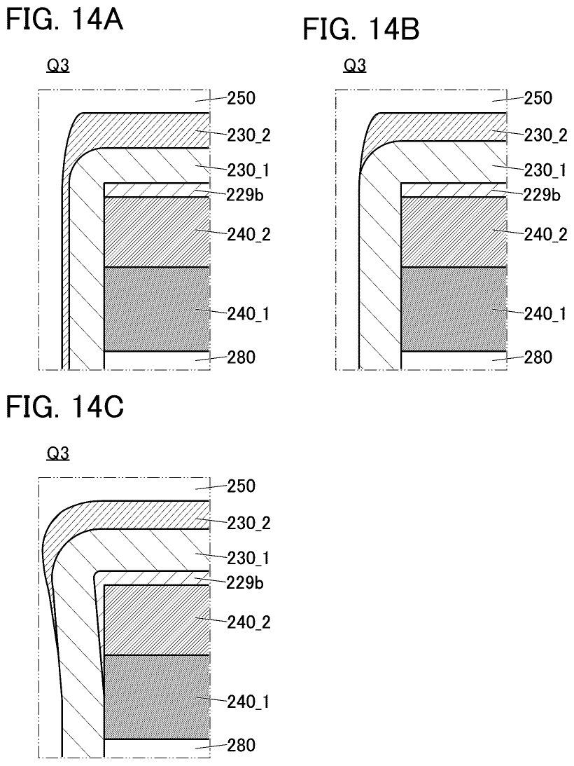

FIGS. 14A to 14C are enlarged views of a region Q3 surrounded by a dashed-dotted line in FIG. 13. In the case where the semiconductor layer 230_2 is formed by a sputtering method, for example, the semiconductor layer 230_2 is formed in contact with the top surface of the semiconductor layer 230_1 and the side surface of the semiconductor layer 230_1 in the opening portion 290 (see FIG. 14A). In that case, the thickness of the semiconductor layer 230_2 formed on the top surface of the semiconductor layer 230_1 is larger than that of the semiconductor layer 230_2 formed on the side surface of the semiconductor layer 230_1 in the opening portion 290; thus, the first thickness is larger than the second thickness as illustrated in FIG. 13.

Depending on the thickness of the semiconductor layer 230_2, the semiconductor layer 230_2 is formed on the top surface of the semiconductor layer 230_1 but is not formed on the side surface of the semiconductor layer 230_1 in the opening portion 290 in some cases (see FIG. 14B). In that case, the distance between the channel formation region of the semiconductor layer 230_1 and the conductive layer 260 is small, so that a gate electric field can be effectively applied to the semiconductor layer 230. Moreover, above the conductive layer 240, the physical distance between the conductive layer 260 and the conductive layer 240 can be increased by the thickness of the semiconductor layer 230_2, so that parasitic capacitance generated between the conductive layer 260 and the conductive layer 240 can be reduced. Note that the semiconductor layer 230_2 sometimes has a portion in contact with the top surface of the semiconductor layer 230_1 and part of the side surface of the semiconductor layer 230_1 in the opening portion 290 as illustrated in FIG. 14C.

The insulating layer 210 functions as an interlayer film and thus is preferably formed using a material with a low dielectric constant. In the case where a material with a low dielectric constant is used for an interlayer film, the parasitic capacitance generated between wirings can be reduced.

The insulating layer 210 preferably has a barrier property against hydrogen. When the insulating layer 210 provided below the semiconductor layer 230 has a barrier property against hydrogen, diffusion of hydrogen into the semiconductor layer 230 from below the transistor 200A can be inhibited.

The insulating layer 210 preferably has a function of capturing or fixing hydrogen. When the insulating layer 210 has a function of capturing or fixing hydrogen, hydrogen in the semiconductor layer 230 can diffuse into the insulating layer 210 through the conductive layer 220 and the hydrogen can be captured or fixed. Thus, the hydrogen concentration in the semiconductor layer 230 can be reduced.

The concentration of impurities such as water and hydrogen in the insulating layer 210 is preferably reduced. This can inhibit entry of impurities such as water and hydrogen into the channel formation region in the semiconductor layer 230.

In the example illustrated in FIG. 4A, the insulating layer 210 has a single-layer structure. Note that the insulating layer 210 can have a stacked-layer structure of two or more layers. For example, the insulating layer 210 can have a two-layer structure of a first insulating layer and a second insulating layer over the first insulating layer. In that case, it is preferable that the first insulating layer have a barrier property against hydrogen and the second insulating layer have a function of capturing or fixing hydrogen, for example. Specifically, it is preferable that silicon nitride be used for the first insulating layer and aluminum oxide, hafnium oxide, hafnium zirconium oxide, or hafnium silicate be used for the second insulating layer.

The insulating layer 280 functions as an interlayer film and thus is preferably formed using a material with a low dielectric constant. In the case where a material with a low dielectric constant is used for an interlayer film, the parasitic capacitance generated between wirings can be reduced. Silicon oxide or silicon oxynitride can be used for the insulating layer 280, for example.

When silicon oxide with a low thermal expansion coefficient is used for the insulating layer 280 provided before the formation of the semiconductor layer 230, the crystal growth of indium oxide formed by an ALD method in the opening portion of the insulating layer 280 can be promoted.

The concentration of impurities such as water and hydrogen in the insulating layer 280 is preferably reduced. This can inhibit entry of impurities such as water and hydrogen into the channel formation region in the semiconductor layer 230.

The insulating layer 250 preferably has a function of supplying oxygen to the semiconductor layer 230. The insulating layer 250 preferably includes a region containing oxygen that is released by heating (hereinafter, sometimes referred to as excess oxygen), for example. When the insulating layer including the region containing excess oxygen is in contact with the semiconductor layer 230, oxygen can be supplied to the semiconductor layer 230. Oxygen supplied to the semiconductor layer 230 fills oxygen vacancies, so that the amount of oxygen vacancies in the semiconductor layer 230 can be reduced. Examples of an insulating material that easily forms the region containing excess oxygen include silicon oxide, silicon oxynitride, and porous silicon oxide.

The insulating layer 250 preferably has a function of capturing or fixing (also referred to as gettering) oxygen. As described above, oxygen easily moves in the indium oxide film. Thus, when the insulating layer 250 has a function of capturing or fixing oxygen, excess oxygen in the semiconductor layer 230 can diffuse into the insulating layer 250 and the oxygen can be captured or fixed. Accordingly, the positive drift degradation of the OS transistor in the +GBT stress test due to the oxygen can be inhibited. Examples of an insulating material having a function of capturing or fixing oxygen include aluminum oxide, hafnium oxide, hafnium zirconium oxide, and an oxide containing hafnium and silicon (hafnium silicate).

Aluminum oxide, hafnium oxide, hafnium zirconium oxide, and hafnium silicate each have a function of capturing or fixing hydrogen. As described above, hydrogen easily moves in the indium oxide film. Thus, when the insulating layer 250 has a function of capturing or fixing hydrogen, hydrogen in the semiconductor layer 230 can diffuse into the insulating layer 250 and the hydrogen can be captured or fixed. Hence, the hydrogen concentration in the semiconductor layer 230 (in particular, the hydrogen concentration in the channel formation region) can be reduced.

In the example illustrated in FIG. 4A, the insulating layer 250 has a single-layer structure. Note that the insulating layer 250 can have a stacked-layer structure of two or more layers. In that case, the insulating layer 250 is preferably formed of two or more kinds of films. When the insulating layer 250 is formed of two or more kinds of films, the insulating layer 250 can have a plurality of functions. Examples of the functions of the insulating layer 250 include a function of extracting excess oxygen from the semiconductor layer 230, a function of extracting hydrogen from the semiconductor layer 230, and a function of inhibiting diffusion of hydrogen into the semiconductor layer 230.

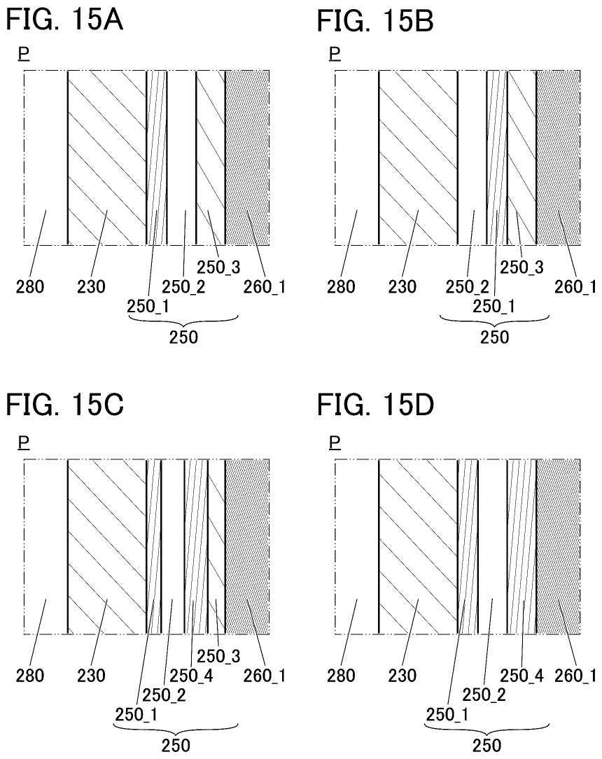

FIGS. 15A to 15D are enlarged views of the insulating layer 250 and its vicinity. FIGS. 15A to 15D are also enlarged views of a region P surrounded by a dashed-dotted line in FIG. 4A.

FIG. 15A illustrates an example in which the insulating layer 250 has a three-layer structure of an insulating layer 250_1, an insulating layer 250_2 over the insulating layer 250_1, and an insulating layer 250_3 over the insulating layer 250_2. In that case, the insulating layer 250_1 is in contact with the semiconductor layer 230.

Any of the above-described materials that can be used for the insulating layer 250 can be used for the insulating layer 250_1. For example, when the insulating layer 250_1 includes an insulating layer having a function of capturing or fixing oxygen, the amount of excess oxygen in the semiconductor layer 230 can be reduced. The insulating layer having a function of capturing or fixing oxygen sometimes has a function of capturing or fixing hydrogen; thus, the hydrogen concentration in the semiconductor layer 230 can sometimes be reduced. Accordingly, the transistor can have high reliability.

The insulating layer 250_1 can be formed using a material with a high dielectric constant (a high-k material). An example of the high-k material is an oxide containing one or both of aluminum and hafnium. With the use of the high-k material for the insulating layer 250_1, gate voltage applied during the operation of the transistor can be reduced while the physical thickness of a gate insulator is maintained. Furthermore, the equivalent oxide thickness (EOT) of the insulator functioning as the gate insulator can be reduced.

As described above, for the insulating layer 250_1, it is preferable to use an oxide containing one or both of aluminum and hafnium and it is further preferable to use an oxide containing one or both of aluminum and hafnium and having an amorphous structure. Since aluminum oxide can be formed as an amorphous film relatively easily by an ALD method, the use of aluminum oxide having an amorphous structure is preferable. Aluminum oxide is suitable for the insulating layer 250_1 because of having a function of capturing or fixing oxygen and hydrogen. Alternatively, hafnium oxide is suitable for the insulating layer 250_1 because of having a high capability of capturing or fixing oxygen and hydrogen.

The insulating layer 250_2 is preferably formed using a material with a low dielectric constant, for example. The insulating layer 250_2 preferably includes a silicon oxide film or a silicon oxynitride film, for example.

Silicon oxide or silicon nitride is an insulating material having a high withstand voltage. Thus, leakage current of the transistor can be reduced. A silicon oxide film or a silicon oxynitride film has a high hydrogen-transmitting property. Hence, as illustrated in FIG. 15B, the insulating layer 250 may have a three-layer structure of the insulating layer 250_2, the insulating layer 250_1 over the insulating layer 250_2, and the insulating layer 250_3 over the insulating layer 250_1. With such a structure, hydrogen in the semiconductor layer 230 can diffuse into the insulating layer 250_1 through the insulating layer 250_2, and the hydrogen can be captured or fixed. Accordingly, the hydrogen concentration in the semiconductor layer 230 can be reduced.

The insulating layer 250_3 preferably has a barrier property against hydrogen. Such a structure can inhibit diffusion of hydrogen into the semiconductor layer 230. The insulating layer 250_3 preferably also has a barrier property against oxygen. The insulating layer 250_3 is provided between the channel formation region in the semiconductor layer 230 and the conductive layer 260.

Such a structure can inhibit oxygen contained in the channel formation region in the semiconductor layer 230 from diffusing into the conductive layer 260 and thus can inhibit formation of oxygen vacancies in the channel formation region in the semiconductor layer 230. Oxygen contained in the semiconductor layer 230 can be inhibited from diffusing into the conductive layer 260 and oxidizing the conductive layer 260. The insulating layer 250_3 preferably has a lower oxygen-transmitting property than at least the insulating layer 250_2. The insulating layer 250_3 preferably has a function of inhibiting diffusion of hydrogen. This can prevent diffusion of impurities such as hydrogen contained in the conductive layer 260 into the semiconductor layer 230. Silicon nitride is preferably used for the insulating layer 250_3, for example.

As illustrated in FIG. 15C, an insulating layer 250_4 may be provided over the insulating layer 250_2. The insulating layer 250_4 can be formed using any of the insulating materials that can be used for the insulating layer 250_1. When the insulating layer 250_4 having a function of capturing or fixing hydrogen is provided between the insulating layer 250_3 and the insulating layer 250_2, for example, hydrogen contained in the insulating layer 250_2 and the like can be captured or fixed.

Specifically, the insulating layer 250 preferably has a four-layer structure in which an aluminum oxide film, a silicon oxide film, a hafnium oxide film, and a silicon nitride film are stacked in this order from the semiconductor layer 230 side. With such a structure, hydrogen in the semiconductor layer 230 can diffuse into the insulating layer 250_1 or the insulating layer 250_4, and the hydrogen can be captured or fixed. Accordingly, the hydrogen concentration in the semiconductor layer 230 can be reduced.

The insulating layer 250 is preferably thin. For example, when the thickness of the insulating layer 250 is greater than or equal to 1 nm and less than or equal to 20 nm, preferably greater than or equal to 3 nm and less than or equal to 10 nm, the S value of the transistor can be reduced.

The thickness of each layer included in the insulating layer 250 is preferably greater than or equal to 0.1 nm and less than or equal to 20 nm, preferably greater than or equal to 0.1 nm and less than or equal to 10 nm, further preferably greater than or equal to 0.1 nm and less than or equal to 5.0 nm, still further preferably greater than or equal to 0.5 nm and less than or equal to 5.0 nm, yet further preferably greater than or equal to 1.0 nm and less than 5.0 nm, yet still further preferably greater than or equal to 1.0 nm and less than or equal to 3.0 nm. Note that each layer included in the insulating layer 250 at least partly includes a region with the above-described thickness.

Typically, the thicknesses of the insulating layer 250_1, the insulating layer 250_2, the insulating layer 250_4, and the insulating layer 250_3 are 1 nm, 2 nm, 2 nm, and 1 nm, respectively. Such a structure enables the transistor to have excellent electrical characteristics even when the transistor is scaled down or highly integrated.

The insulating layer 250_3 in the insulating layer 250 having the four-layer structure is not necessarily provided (see FIG. 15D). For example, an insulating layer having a function of capturing or fixing oxygen can be used as the insulating layer 250_1, an insulating layer containing a material with a low dielectric constant can be used as the insulating layer 250_2, and an insulating layer having a function of capturing or fixing hydrogen can be used as the insulating layer 250_4. Specifically, the insulating layer 250 can have a three-layer structure in which an aluminum oxide film, a silicon oxide film, and a hafnium oxide film are stacked in this order from the semiconductor layer 230 side.

The insulating layer 250 can have a three-layer structure in which a hafnium oxide film, a silicon oxide film, and a silicon nitride film are stacked in this order from the semiconductor layer 230 side. The thicknesses of the hafnium oxide film, the silicon oxide film, and the silicon nitride film are 2 nm, 2 nm, and 1 nm, respectively. With such a structure, excess oxygen in the semiconductor layer 230 can be released to the insulating layer 250, so that the amount of excess oxygen in the semiconductor layer 230 can be reduced. Furthermore, hydrogen in the semiconductor layer 230 can be captured or fixed. Thus, the electrical characteristics and reliability of the transistor 200A can be improved.

In order that the insulating layers 250_1 to 250_4 have small thicknesses as described above, an ALD method is preferably employed. In order that the insulating layers 250_1 to 250_4 with good coverage are formed in the opening portion 290, an ALD method is preferably employed.

Note that in formation of the insulating layer 250 having a stacked-layer structure of a plurality of insulating films, an ALD process is preferably performed twice or more. For example, two or more kinds of the insulating films in the insulating layer 250 are preferably formed through an ALD process. When at least two kinds of insulating films are formed through an ALD process, the coverage with the insulating layer 250 and the thickness uniformity of the insulating layer 250 can be improved. When two or more kinds of insulating films are successively formed through an ALD process, for example, the productivity can be increased.

Although the insulating layer 250 has the three-layer structure or the four-layer structure in the above description, the present invention is not limited thereto. The insulating layer 250 can have a structure including at least one of the insulating layers 250_1 to 250_4. When the insulating layer 250 is formed of one, two, or three of the insulating layers 250_1 to 250_4, the fabrication process of the semiconductor device can be simplified and the productivity can be improved.

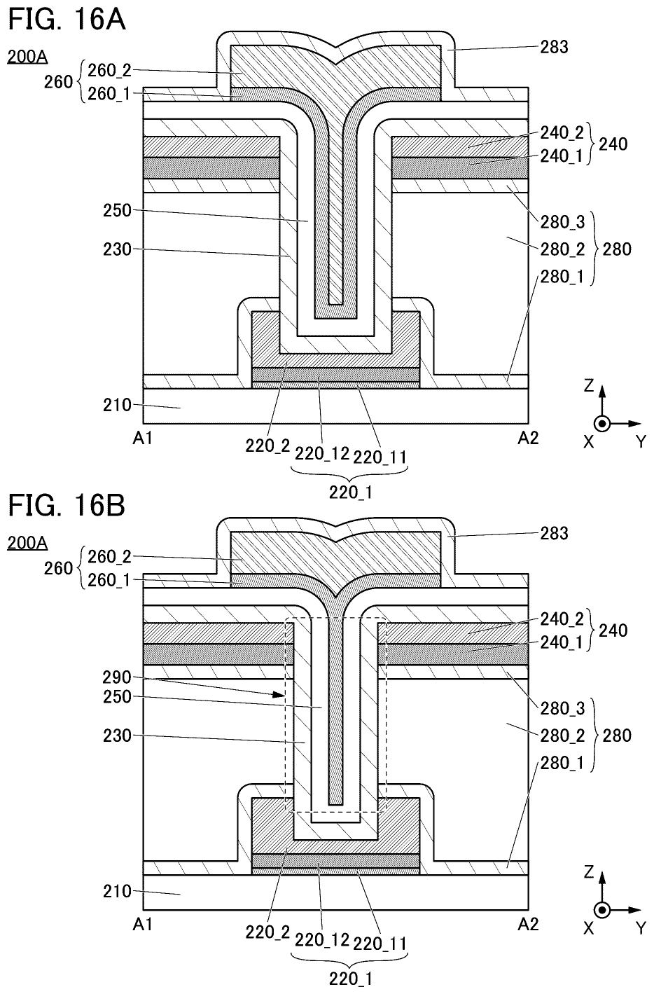

In the example illustrated in FIG. 4A, the insulating layer 280 has a single-layer structure. Note that the insulating layer 280 can have a stacked-layer structure of two or more layers. For example, as illustrated in FIG. 16A, the insulating layer 280 can have a three-layer structure of an insulating layer 280_1, an insulating layer 280_2 over the insulating layer 280_1, and an insulating layer 280_3 over the insulating layer 280_2. In that case, it is preferable that the material with a low dielectric constant be used for the insulating layer 280_2 and a barrier insulating layer against oxygen be used as each of the insulating layers 280_1 and 280_3. Thus, the conductive layer 220 and the conductive layer 240 can be inhibited from being oxidized and having an increased resistance.

It is preferable that silicon nitride or aluminum oxide be used for each of the insulating layers 280_1 and 280_3 and silicon oxide be used for the insulating layer 280_2, for example. Note that each of the insulating layers 280_1 and 280_3 may have a stacked-layer structure of two or more layers.

Each of the conductive layers 220 and 240 is in contact with the semiconductor layer 230, and thus is preferably formed using a conductive material that is not easily oxidized, a conductive material that maintains its low electric resistance even after being oxidized, a metal oxide that has conductivity (also referred to as an oxide conductor), or a conductive material that has a function of inhibiting diffusion of oxygen. Examples of the conductive material include a conductive material containing nitrogen and a conductive material containing oxygen. Thus, a decrease in conductivity of each of the conductive layers 220 and 240 can be inhibited.

When a conductive material containing oxygen is used for the conductive layers 220 and 240, the conductive layers 220 and 240 can maintain their conductivity even after absorbing oxygen. This is preferable because the conductive layer 220 can maintain its conductivity even when an insulator containing oxygen, such as hafnium oxide, is used for the insulating layer 210. For each of the conductive layers 220 and 240, ITO, ITSO, In—Zn oxide, or the like is preferably used, for example.

In the case where the conductive layers 220 and 240 each have a stacked-layer structure, a conductive material containing oxygen is used for a layer having the largest contact area with the semiconductor layer 230 in the stacked-layer structure, in which case the contact resistance between the conductive layer 220 and the semiconductor layer 230 and the contact resistance between the conductive layer 240 and the semiconductor layer 230 can be reduced.

FIG. 16A illustrates an example in which the conductive layer 220_1 has a two-layer structure of a conductive layer 220_11 and a conductive layer 220_12 over the conductive layer 220 11. In other words, the conductive layer 220 illustrated in FIG. 16A has a three-layer structure of the conductive layer 220_11, the conductive layer 220_12 over the conductive layer 220_11, and the conductive layer 220_2 over the conductive layer 220_12. In that case, for example, it is preferable that a conductive material that is not easily oxidized or a conductive material that has a function of inhibiting diffusion of oxygen be used for the conductive layer 220_11, a material that has high conductivity be used for the conductive layer 220_12, and a conductive material that contains oxygen (further preferably an oxide conductor) be used for the conductive layer 220_2. Specifically, it is preferable that titanium nitride be used for the conductive layer 220_11, tungsten be used for the conductive layer 220_12, and an oxide conductor (e.g., ITO, ITSO, or In—Zn oxide) be used for the conductive layer 220_2. In that case, a titanium nitride film is in contact with the insulating layer 210, and an oxide conductive film is in contact with the semiconductor layer 230. In addition, an oxide conductor is used for a layer closest to the channel formation region in the semiconductor layer 230. Since the oxide conductor has a lower contact resistance with the semiconductor layer 230 than tungsten, the current path between the source and the drain can be shortened and the on-state current of the transistor 200A can be increased. Such a structure enables the conductive layer 220 to maintain its conductivity even when the conductive layer 220 is in contact with the semiconductor layer 230. In the case of using an oxide insulating layer as the insulating layer 210, such a structure can inhibit the conductive layer 220 from being excessively oxidized by the insulating layer 210. When a metal material (here, tungsten) having higher conductivity than the oxide conductor and titanium nitride is used for the conductive layer 220_12, the conductivity of the conductive layer 220 can be increased.

The conductive layer 240 illustrated in FIG. 4A has the two-layer structure of the conductive layer 240_1 and the conductive layer 240_2 over the conductive layer 240_1. In that case, for example, it is preferable that a conductive material containing oxygen be used for the conductive layer 240_2, and a material having higher conductivity than the material for the conductive layer 240_2 be used for the conductive layer 240_1. Specifically, it is preferable that an oxide conductor (e.g., ITO, ITSO, or In—Zn oxide) be used for the conductive layer 240_2 and tungsten be used for the conductive layer 240_1. For the conductive layer 240_1, ruthenium, titanium nitride, tantalum nitride, or the like may be used. When an oxide conductor is used for the conductive layer 240_2 mainly in contact with the semiconductor layer 230, the contact resistance with the semiconductor layer 230 can be reduced. When a material having higher conductivity than an oxide conductor is used for a layer included in the conductive layer 240, the conductivity of the conductive layer 240 can be increased.

Note that a conductive material containing oxygen can be used for the conductive layer 240 1, and a material having higher conductivity than the material for the conductive layer 240_1 can be used for the conductive layer 240_2. In that case, an oxide conductor is used for the layer of the conductive layer 240 which is closest to the channel formation region in the semiconductor layer 230. Thus, the current path between the source and the drain can be shortened and the on-state current of the transistor 200A can be increased in some cases.

In the case where the oxide layer 229 is not provided, one or both of the conductive layer 220 and the conductive layer 240 may function as the first layer 11 described in Embodiment 1. In that case, the crystallinity of the semiconductor layer 230 can be increased with one or both of the conductive layer 220 and the conductive layer 240 used as a seed or a nucleus. In the case where the oxide layer 229 is not provided, one or both of the conductive layer 220 and the conductive layer 240 may correspond to the fourth layer 14 described in Embodiment 1. In that case, the structure, material, and the like of the fourth layer 14 described in Embodiment 1 may be referred to for the structure, material, and the like of one or both of the conductive layer 220 and the conductive layer 240.

The conductive layer 260 illustrated in FIG. 4A has the two-layer structure of the conductive layer 260_1 and the conductive layer 260_2 over the conductive layer 260_1. In that case, for example, it is preferable that titanium nitride be used for the conductive layer 260_1, and tungsten be used for the conductive layer 260_2. Alternatively, it is preferable that tantalum nitride be used for the conductive layer 260_1, and copper be used for the conductive layer 260_2. Such a structure can increase the conductivity of the conductive layer 260.

Alternatively, the conductive layer 260 may have a stacked-layer structure of three or more layers. For example, the conductive layer 260 may have a three-layer structure of a tantalum nitride film, a titanium nitride film over the tantalum nitride film, and a tungsten film over the titanium nitride film.

As illustrated in FIG. 16A, an insulating layer 283 may be provided over the transistor 200A. Specifically, the insulating layer 283 may be provided over the conductive layer 260 and the insulating layer 250.

As the insulating layer 283, a barrier insulating layer against hydrogen is preferably used. Such a structure can inhibit diffusion of hydrogen from above the transistor 200A into the semiconductor layer 230.

In the transistor 200A illustrated in FIG. 4A, both the conductive layer 260_1 and the conductive layer 260_2 are positioned in the opening portion 290. Depending on the width of the opening portion 290, the thicknesses of the semiconductor layer 230, the insulating layer 250, and the conductive layer 260_1, and the like, the conductive layer 260_1 is provided in the opening portion 290 and the conductive layer 260_2 is provided outside the opening portion 290 in some cases (see FIG. 16B).

It is preferable that, in the opening portion 290, the side surface of the conductive layer 240 and the side surface of the insulating layer 280 be aligned or substantially aligned with each other. With such a structure, the opening portion 290 can be formed in the conductive layer 240 and the insulating layer 280 at a time. Moreover, the thickness distribution of the semiconductor layer 230 and the like provided in the opening portion 290 can be uniform. In addition, the semiconductor layer 230 and the like can be inhibited from being divided by a step or the like between the conductive layer 240 and the insulating layer 280.

Note that the present invention is not limited to the above structure. For example, the side surface of the conductive layer 240 and the side surface of the insulating layer 280 may be discontinuous in the opening portion 290. The inclination of the side surface of the conductive layer 240 and the inclination of the side surface of the insulating layer 280 may be different from each other in the opening portion 290. At this time, part of the sidewall of the opening portion 290 has a tapered shape.

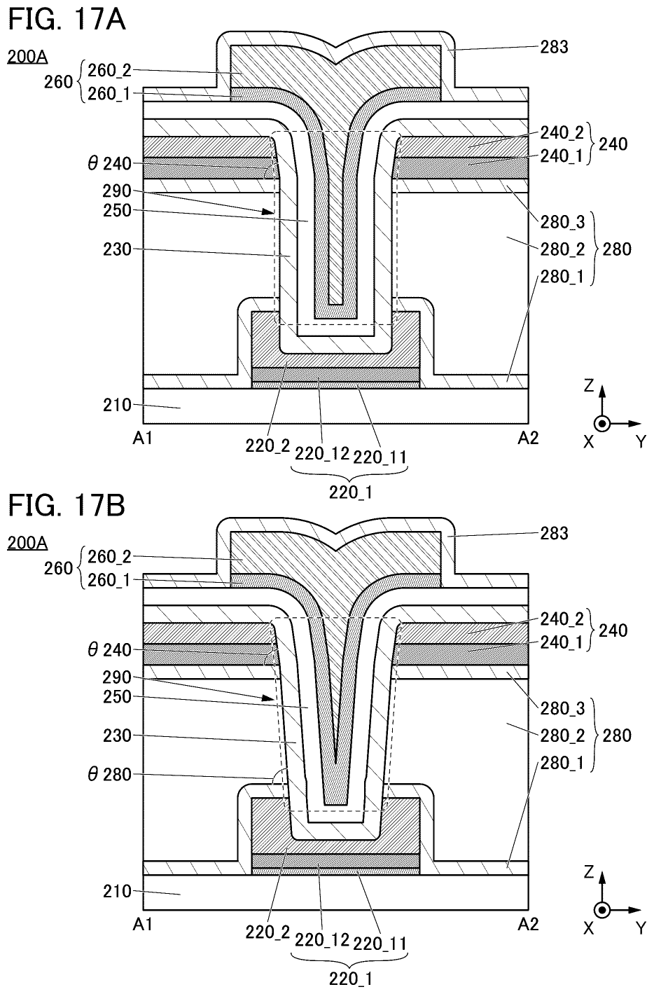

FIG. 17A illustrates an example in which the side surface of the conductive layer 240 in the opening portion 290 has a tapered shape, and FIG. 17B illustrates an example in which the side surfaces of the conductive layer 240 and the insulating layer 280 in the opening portion 290 each have a tapered shape.

When the sidewall of the opening portion 290 has a tapered shape, the coverage with the semiconductor layer 230, the insulating layer 250, and the like can be improved, so that defects such as voids can be reduced. In the case where the sidewall of the opening portion 290 has a tapered shape, for example, a taper angle (an angle θ240) of the side surface of the conductive layer 240 in the opening portion 290 and a taper angle (the angle θ280) of the side surface of the insulating layer 280 in the opening portion 290 are each preferably greater than or equal to 45° and less than 90°. Specifically, the taper angles are each preferably greater than or equal to 80° and less than 90°, in which case the semiconductor device can be scaled down or highly integrated. Alternatively, the taper angles are each preferably greater than or equal to 45° and less than 80°, or greater than or equal to 50° and less than or equal to 75°, in which case the coverage with a film to be formed in the opening portion 290 is improved.

For example, the angle θ240 is preferably smaller than the angle θ280. With such a structure, the coverage of the side surface of the conductive layer 240 in the opening portion 290 with the semiconductor layer 230 or the like is improved, so that defects such as voids can be reduced. In the case where the insulating layer 280 has a stacked-layer structure, the inclinations of the side surfaces of the layers in the opening portion 290 may be different from each other. Similarly, in the case where the conductive layer 240 has a stacked-layer structure, the inclinations of the side surfaces of the layers in the opening portion 290 may be different from each other.

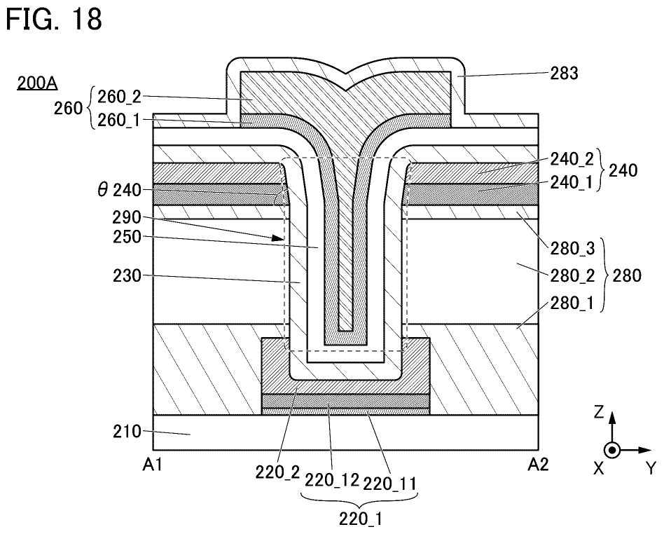

Although FIG. 17A and the like illustrate an example in which the top surface of the insulating layer 280_2 is flat, the present invention is not limited thereto. The top surface of at least one of the insulating layers 280_1 to 280_3 is preferably flat. FIG. 18 illustrates a semiconductor device in which the top surface of the insulating layer 280_1 is flat.

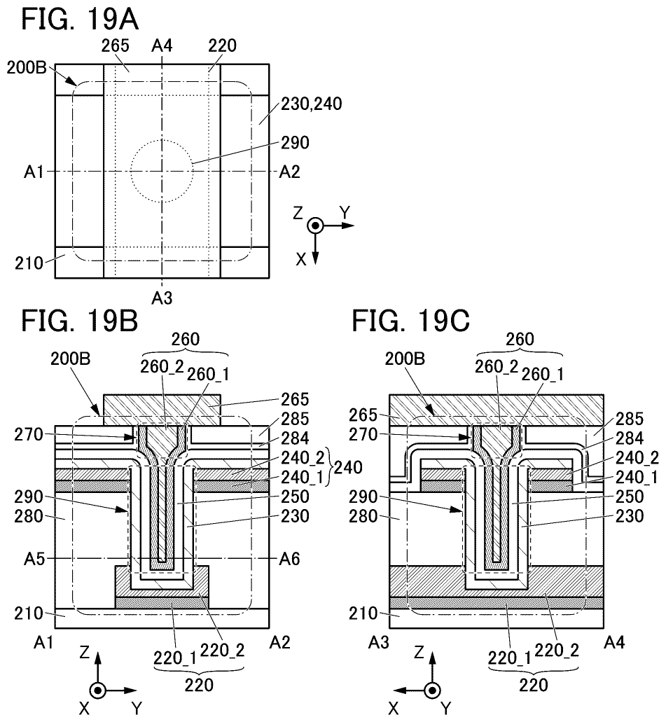

Structure examples of transistors whose structures are partly different from that of the transistor 200A will be described below with reference to FIGS. 19A to 19C, FIGS. 20A and 20B, and FIGS. 21A to 21D. Note that description of the portions already described is omitted and only different portions are described in detail. Even when positions or shapes of components are different from those in the above example, the same reference numerals are used as long as the components have the same functions as those in the above example, and description thereof is omitted in some cases.

### [Transistor 200B]

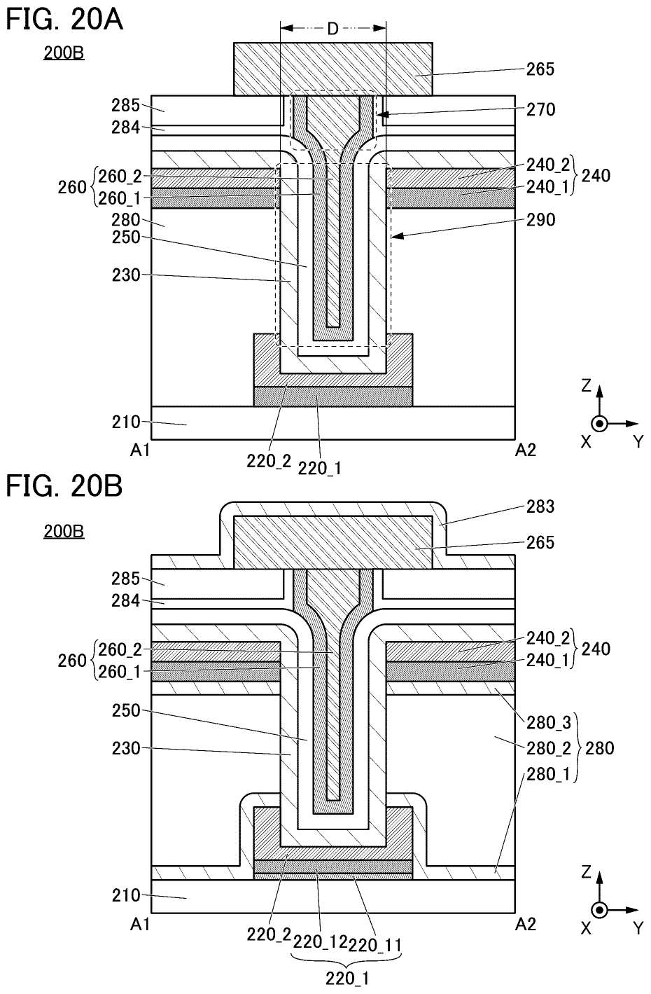

FIG. 19A is a plan view of a semiconductor device including a transistor 200B. FIG. 19B is a cross-sectional view taken along the dashed-dotted line A1-A2 in FIG. 19A. FIG. 19C is a cross-sectional view taken along the dashed-dotted line A3-A4 in FIG. 19A. FIG. 3D can be referred to for a cross-sectional view along the dashed-dotted line A5-A6 in FIG. 19B. FIG. 20A is an enlarged view of FIG. 19B.

The semiconductor device illustrated in FIGS. 19A to 19C is different from the semiconductor device illustrated in FIGS. 3A to 3D in including a conductive layer 265, an insulating layer 284, and an insulating layer 285.

Since the stacked-layer structure from the conductive layer 220 to the insulating layer 250 in the transistor 200B is similar to that in the transistor 200A, the details thereof are not described.

As illustrated in FIGS. 19B and 19C, the insulating layer 284 is positioned over the insulating layer 250. The insulating layer 284 is provided with an opening portion 270 reaching the insulating layer 250 at a position overlapping with the opening portion 290.

The conductive layer 260 is provided to fill the opening portion 290 and the opening portion 270. The conductive layer 260 is provided over the insulating layer 250 and is in contact with the insulating layer 250 in the opening portion 290. The conductive layer 260 includes a portion facing the semiconductor layer 230 with the insulating layer 250 therebetween in the opening portion 290 and a portion positioned in the opening portion 270.

FIGS. 19B and 19C illustrate an example in which both the conductive layer 260_1 and the conductive layer 260_2 are provided in the opening portion 290. In the case where the widths of the opening portions 290 and 270 are small, only the conductive layer 260_1 is provided in the opening portion 290 and the conductive layers 260_1 and 260_2 are provided in the opening portion 270 in some cases. Alternatively, only the conductive layer 260_1 is provided in the opening portion 270 in some cases.

FIG. 20A illustrates an example in which the width of the opening portion 270 is smaller than the width D of the opening portion 290. The width of the opening portion 270 is preferably as small as possible, in which case the physical distance between the conductive layer 240 and the conductive layer 260 can be increased and thus the parasitic capacitance generated therebetween can be reduced. For example, the width of the opening portion 270 is preferably smaller than or equal to that of the opening portion 290.

The conductive layer 265 is provided over the conductive layer 260 and is in contact with the top surface of the conductive layer 260. It can be said that the conductive layer 260 and the conductive layer 265 are connected to each other. The conductive layer 265 may be regarded as a component of the transistor 200B. The top surface of the conductive layer 260 and the top surface of the insulating layer 285 are level or substantially level with each other.

The conductive layer 265 functions as a gate wiring. For the conductive layer 265, any of the materials that can be used for the conductive layer 260 can be used. For example, a high-melting-point material that has both heat resistance and conductivity, such as tungsten or molybdenum, can be used for the conductive layer 265. Alternatively, a low-resistance conductive material such as aluminum or copper can be used. The use of a low-resistance conductive material can reduce wiring resistance.

A portion of the conductive layer 265 that does not overlap with the opening portion 290 is mainly positioned over the insulating layer 285. Thus, the conductive layer 265 mainly overlaps with the conductive layer 240 with the insulating layers 284 and 285 therebetween. This can increase the physical distance between the conductive layers 265 and 240, and reduce the parasitic capacitance generated therebetween. Note that the conductive layers 240 and 265 may include a portion where they overlap with each other without the insulating layer 285 therebetween.

The transistor 200B has a structure in which the parasitic capacitance generated between the other of the source and drain electrodes and the gate wiring is reduced. Accordingly, the frequency characteristics of a circuit including the transistor can be improved.

Although this embodiment describes the example in which the opening portion 270 has a circular shape in the plan view, the present invention is not limited thereto. Any of the above-described shapes that can be employed for the opening portion 290 can be employed as the shape of the opening portion 270.

The width of the opening portion 270 varies in the depth direction in some cases. Here, the maximum width of the opening portion 270 provided in the insulating layer 284 in the cross-sectional view is specifically used as the width of the opening portion 270.

The insulating layer 284 preferably has a function of capturing or fixing hydrogen. With such a structure, diffusion of hydrogen from above the insulating layer 284 into the semiconductor layer 230 can be inhibited, and hydrogen contained in the semiconductor layer 230 can be captured or fixed. Thus, the hydrogen concentration in the semiconductor layer 230 can be reduced. For the insulating layer 284, aluminum oxide, hafnium oxide, hafnium zirconium oxide, hafnium silicate, or the like can be used.

The insulating layer 284 can be a barrier insulating layer against hydrogen. In that case, diffusion of hydrogen from above the insulating layer 284 into the semiconductor layer 230 can be inhibited. Silicon nitride and silicon nitride oxide can be suitably used for the insulating layer 284 because they are less likely to transmit oxygen and hydrogen.

In the case where the insulating layer 284 includes a silicon nitride film, the silicon nitride film is preferably formed by a sputtering method. A film formation gas in a sputtering method need not include molecules containing hydrogen; thus, the hydrogen concentration in the insulating layer 284 can be reduced. When the insulating layer 284 is formed by a sputtering method, a high-density silicon nitride film can be obtained.

The insulating layer 284 may have a stacked-layer structure of an insulating layer having a function of capturing or fixing hydrogen and a barrier insulating layer against hydrogen. For example, the insulating layer 284 may include a stack of an aluminum oxide film and a silicon nitride film over the aluminum oxide film.

The insulating layer 285 functions as an interlayer film and thus is preferably formed using any of the above-described materials with a low dielectric constant. For example, the insulating layer 285 preferably includes a silicon oxide film.

Note that the transistor 200B can have a structure similar to that of the transistor 200A. FIG. 20B illustrates an example in which the structure illustrated in FIG. 16A is employed for the semiconductor device illustrated in FIG. 20A. In FIG. 20B, the insulating layer 283 is provided over the insulating layer 285 and the conductive layer 265.

### [Transistor 200C]

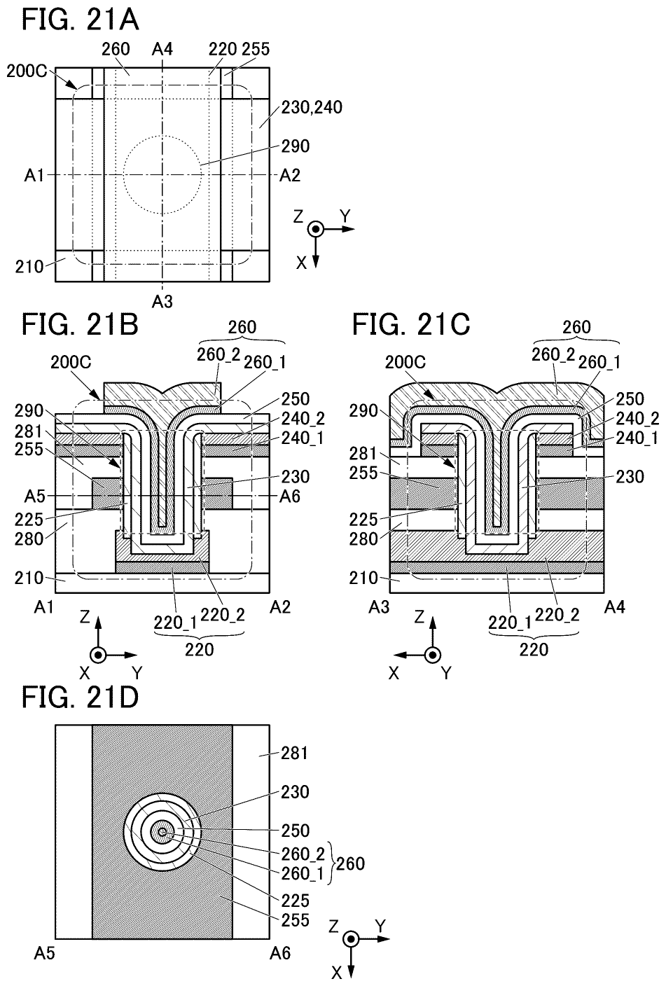

FIG. 21A is a plan view of a semiconductor device including a transistor 200C. FIG. 21B is a cross-sectional view taken along the dashed-dotted line A1-A2 in FIG. 21A. FIG. 21C is a cross-sectional view taken along the dashed-dotted line A3-A4 in FIG. 21A. FIG. 21D is a cross-sectional view taken along the dashed-dotted line A5-A6 in FIG. 21B.

The semiconductor device illustrated in FIGS. 21A to 21D is different from the semiconductor device illustrated in FIGS. 3A to 3D mainly in including an insulating layer 225, a conductive layer 255, and an insulating layer 281.

As illustrated in FIG. 21B, the conductive layer 255 is positioned over the insulating layer 280, and the insulating layer 281 is positioned over the conductive layer 255 and the insulating layer 280. The conductive layer 240_1 is positioned over the insulating layer 281. The opening portion 290 reaching the conductive layer 220 is provided in the insulating layer 280, the conductive layer 255, the insulating layer 281, and the conductive layer 240. The insulating layer 225 is positioned between the insulating layer 280 and the semiconductor layer 230.

As illustrated in FIG. 21B and the like, the conductive layer 220 has a first depressed portion and a second depressed portion whose end portion is positioned outward from that of the first depressed portion. The depth of the first depressed portion is greater than that of the second depressed portion. In other words, the bottom surface of the first depressed portion is positioned below the bottom surface of the second depressed portion (on the insulating layer 210 side). The side surface of the second depressed portion is aligned or substantially aligned with the side surface of the insulating layer 280 in the opening portion 290, and the side surface of the first depressed portion is aligned or substantially aligned with the surface of the insulating layer 225 on the semiconductor layer 230 side. Hereinafter, the first depressed portion and the second depressed portion are collectively referred to as a depressed portion in some cases.

In FIG. 21B and the like, the insulating layer 225 is in contact with the bottom and side surfaces of the second depressed portion of the conductive layer 220, and is in contact with the side surfaces of the insulating layer 280, the conductive layer 255, the insulating layer 281, and the conductive layer 240 in the opening portion 290. The semiconductor layer 230 is in contact with the bottom and side surfaces of the first depressed portion of the conductive layer 220, the top surface of the insulating layer 225, and the top surface of the conductive layer 240. The insulating layer 250 is positioned inward from the semiconductor layer 230 in the opening portion 290, and the conductive layer 260 is positioned inward from the insulating layer 250 in the opening portion 290.

The transistor 200C may have a structure in which the insulating layer 225 does not cover at least part of the side surface of the conductive layer 240. In that case, the side surface of the conductive layer 240 that is not covered with the insulating layer 225 is in contact with the semiconductor layer 230. Thus, the contact resistance between the semiconductor layer 230 and the conductive layer 240 can be reduced.

FIG. 21B illustrates an example in which the insulating layer 225 has a single-layer structure. The insulating layer 225 can have a stacked-layer structure of two or more layers. For example, the insulating layer 225 can have a two-layer structure of a first insulating layer and a second insulating layer. The first insulating layer is in contact with the side surface of the insulating layer 280 in the opening portion 290, and the second insulating layer is positioned between the first insulating layer and the semiconductor layer 230.

For the first insulating layer and the second insulating layer, any of insulating materials described later in [Insulating layer] can be used. For example, a barrier insulating layer against hydrogen can be used as the first insulating layer, and an insulating layer including a region containing excess oxygen can be used as the second insulating layer. Such a structure can reduce one or both of oxygen vacancies and hydrogen in the semiconductor layer 230. Thus, the electrical characteristics and reliability of the transistor can be improved. For example, it is preferable that silicon nitride be used for the first insulating layer and silicon oxide or silicon oxynitride be used for the second insulating layer.

The semiconductor layer 230 includes a region overlapping with the conductive layer 255 with the insulating layer 225 therebetween and overlapping with the conductive layer 260 with the insulating layer 250 therebetween. At least part of the region functions as the channel formation region of the transistor 200C.

In the transistor 200C, the conductive layer 260 functions as a first gate electrode, the insulating layer 250 functions as a first gate insulating layer, the conductive layer 255 functions as a second gate electrode, and the insulating layer 225 functions as a second gate insulating layer.

In the transistor 200C, one of the conductive layers 255 and 260 can be used as a gate electrode and the other can be used as a back gate electrode. In the transistor 200C, it is particularly suitable to use the conductive layer 260 as the gate electrode and to use the conductive layer 255 as the back gate electrode in some cases. When the conductive layer 260 whose region facing the semiconductor layer 230 is larger than that of the conductive layer 255 is used as the gate electrode, a gate electric field is applied to the semiconductor layer 230 more efficiently; thus, the electrical characteristics of the transistor can be improved in some cases. In the case where the conductive layer 260 functions as the gate electrode and the conductive layer 255 functions as the back gate electrode, the insulating layer 250 functions as a gate insulating layer and the insulating layer 225 functions as a back gate insulating layer.

Since the transistor 200C includes the conductive layer functioning as the back gate electrode, the threshold voltage of the transistor 200C can be controlled by a potential supplied to the conductive layer. Thus, by controlling the threshold voltage, a normally-off transistor is easily achieved.

For the conductive layer 255, any of the conductive materials that can be used for the conductive layer 260 can be used.

The insulating layer 281 functions as an interlayer film. The insulating layer 281 can be formed using any of the insulating materials that can be used for the insulating layer 280.

Note that the transistor 200C can have a structure similar to that of at least one of the transistors 200A and 200B.

### <Materials for Semiconductor Device>

Materials that can be used for the semiconductor device of this embodiment will be described below. Note that the layers included in the semiconductor device of this embodiment may each have a single-layer structure or a stacked-layer structure. [Oxide semiconductor layer]

For an oxide semiconductor layer that can be used as the semiconductor layer of the transistor of one embodiment of the present invention, description in <Structure example of semiconductor device>can be referred to.

The carrier concentration in the channel formation region is preferably lower than 1×10¹⁹ cm⁻³, lower than 1×10¹⁸ cm⁻³, lower than 5×10¹⁷ cm⁻³, lower than 1×10¹⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. The lower limit of the carrier concentration in the channel formation region is not particularly limited and can be, for example, 1×10⁻⁷ cm⁻³.

As described above, the electrical characteristics of the OS transistor may vary easily and the reliability of the OS transistor may be decreased when oxygen vacancies (Vₒ) and impurities are present in the channel formation region in the oxide semiconductor. Accordingly, in order to obtain stable electrical characteristics of the OS transistor, reducing the impurity concentration in the oxide semiconductor is effective. In order to reduce the impurity concentration in the oxide semiconductor, it is preferable that the impurity concentration in an adjacent film be also reduced. Examples of impurities include hydrogen, carbon, and nitrogen.

When the oxide semiconductor contains nitrogen, a trap state is sometimes formed. This may make the electrical characteristics of the transistor unstable. Accordingly, the nitrogen concentration in the channel formation region in the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus an oxygen vacancy is formed in some cases. Entry of hydrogen into the oxygen vacancy generates an electron serving as a carrier in some cases. Furthermore, bonding of part of hydrogen to oxygen bonded to a metal atom generates an electron serving as a carrier in some cases. Thus, a transistor including an oxide semiconductor that contains hydrogen tends to be normally on. For this reason, hydrogen in the channel formation region in the oxide semiconductor is preferably reduced as much as possible. Specifically, the hydrogen concentration in the channel formation region in the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet further preferably lower than 1×10¹⁸ atoms/cm³, yet still further preferably lower than 1×10¹⁷ atoms/cm³. The lower limit of the hydrogen concentration in the channel formation region in the oxide semiconductor is not particularly limited and can be, for example, higher than or equal to 1×10¹⁶ atoms/cm³.

When the oxide semiconductor contains an alkali metal or an alkaline earth metal, defect states are formed and the transistor has unstable electrical characteristics in some cases. Thus, the concentration of an alkali metal or an alkaline earth metal in the channel formation region in the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for a channel formation region of a transistor, the transistor can have stable electrical characteristics. [Insulating layer]

An inorganic insulating film is preferably used as each of the insulating layers included in the semiconductor device (e.g., the insulating layers 210, 225, 250, 280, 281, 283, 284, and 285). Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film. An organic insulating film may be used for the insulating layer included in the semiconductor device.

With scaling down and high integration of a transistor, for example, a problem such as generation of leakage current may arise because of a thin gate insulating layer. When a high-k material is used for the gate insulating layer, the voltage at the time of operation of the transistor can be reduced while the physical thickness is maintained. Furthermore, the equivalent oxide thickness (EOT) of the gate insulating layer can be reduced. By contrast, when a material with a low dielectric constant is used for the insulating layer functioning as an interlayer film, the parasitic capacitance generated between wirings can be reduced. Thus, a material is preferably selected depending on the function of an insulating layer. Note that a material with a low dielectric constant is a material with high dielectric strength.

Examples of the material with a low dielectric constant include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the material with a low dielectric constant include inorganic insulating materials such as silicon oxide, silicon oxynitride, and silicon nitride oxide, and resins such as polyester, polyolefin, polyamide (e.g., nylon and aramid), polyimide, polycarbonate, and an acrylic resin. Other examples of the inorganic insulating material with a low dielectric constant include silicon oxide containing fluorine, silicon oxide containing carbon, and silicon oxide containing carbon and nitrogen. Another example is porous silicon oxide. Note that these silicon oxides can contain nitrogen.

A material that can have ferroelectricity may be used for the insulating layer included in the semiconductor device. As the material that can have ferroelectricity, an oxide containing one or both of hafnium and zirconium is preferably used. Examples of the oxide include metal oxides such as hafnium oxide, zirconium oxide, and hafnium zirconium oxide. As the material that can have ferroelectricity, a material in which an element J1 (the element J1 here is one or more selected from one of hafnium and zirconium, silicon, aluminum, gadolinium, yttrium, lanthanum, strontium, and the like) is added to a metal oxide containing the other of hafnium and zirconium may also be used.

Addition of a Group 3 element in the periodic table to an oxide containing one or both of hafnium and zirconium increases the oxygen vacancy concentration in the oxide and facilitates formation of a crystal having an orthorhombic crystal structure. This is preferable because the proportion of the crystal having an orthorhombic crystal structure is increased and the amount of remanent polarization can be increased. On the other hand, too much addition of the Group 3 element might decrease the crystallinity of the oxide and hinder the exhibition of ferroelectricity. Thus, the content percentage of the Group 3 element in the oxide containing one or both of hafnium and zirconium is preferably higher than or equal to 0.1 atomic % and lower than or equal to 10 atomic %, further preferably higher than or equal to 0.1 atomic % and lower than or equal to 5 atomic %, still further preferably higher than or equal to 0.1 atomic % and lower than or equal to 3 atomic %. Here, the content percentage of the Group 3 element refers to the proportion of the number of the Group 3 element atoms in the number of all metal element atoms contained in the layer. The Group 3 element is preferably one or more selected from scandium, lanthanum, and yttrium, further preferably one or both of lanthanum and yttrium.

Examples of the material that can have ferroelectricity also include a metal nitride containing nitrogen and at least one of an element M1 and an element M2. Here, the element M1 is one or more of aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Examples of the material that can have ferroelectricity also include the above metal nitride to which an element M3 is added. Note that the element M3 is one or more of magnesium, calcium, strontium, zinc, cadmium, and the like.

Examples of the material that can have ferroelectricity also include perovskite-type oxynitrides such as SrTaO₂N and BaTaO₂N, and GaFeO₃ with a K-alumina-type structure. As the material that can have ferroelectricity, a piezoelectric ceramic having a perovskite structure, such as lead titanate (PbTiOx), barium strontium titanate (BST), strontium titanate, lead zirconate titanate (PZT), strontium bismuth tantalate (SBT), bismuth ferrite (BFO), or barium titanate, may be used. Although metal oxides and metal nitrides are described above as examples, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can have ferroelectricity, a mixture or compound containing a plurality of materials selected from the above-listed materials can be used, for example. Alternatively, an insulating layer 130 to be described in Embodiment 3 can have a stacked-layer structure of a plurality of materials selected from the above-listed materials. Since the above-listed materials and the like may change their crystal structures (characteristics) according to a variety of processes and the like as well as film formation conditions, a material that exhibits ferroelectricity is referred to not only as a ferroelectric but also as a material that can have ferroelectricity in this specification and the like.

In this specification and the like, the material that can have ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

The ferroelectric layer preferably includes a crystal having an orthorhombic crystal structure, in which case ferroelectricity is exhibited. A crystal included in the ferroelectric layer may have one or more of crystal structures selected from tetragonal, orthorhombic, monoclinic, and hexagonal crystal structures. Alternatively, the ferroelectric layer may have an amorphous structure. In that case, the ferroelectric layer may have a composite structure including an amorphous structure and a crystal structure.

A metal oxide containing one or both of hafnium and zirconium is also an insulating material having a function of capturing or fixing hydrogen. Thus, with the use of a metal oxide containing one or both of hafnium and zirconium for at least part of the gate insulating layer, hydrogen contained in the oxide semiconductor layer can be captured or fixed and the hydrogen concentration in the oxide semiconductor layer can be reduced. The transistor including the gate insulating layer can function as a ferroelectric field-effect transistor (FeFET).

A transistor including a metal oxide can have stable electrical characteristics when surrounded by an insulating layer having a function of inhibiting transmission of impurities and oxygen. The insulating layer having a function of inhibiting transmission of impurities and oxygen can have, for example, a single-layer structure or a stacked-layer structure of an insulating layer containing one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum. Specifically, as a material for the insulating layer having a function of inhibiting transmission of impurities and oxygen, a metal oxide such as aluminum oxide, magnesium oxide, germanium oxide, yttrium oxide, zirconium oxide, lanthanum oxide, neodymium oxide, hafnium oxide, or tantalum oxide, a nitride such as aluminum nitride or silicon nitride, or a nitride oxide such as silicon nitride oxide can be used.

Specific examples of the material for the insulating layer having a function of inhibiting transmission of oxygen and impurities such as water and hydrogen include metal oxides such as aluminum oxide, magnesium oxide, germanium oxide, yttrium oxide, zirconium oxide, lanthanum oxide, neodymium oxide, hafnium oxide, tantalum oxide, and an oxide containing aluminum and hafnium (hafnium aluminate). Other examples include nitrides such as aluminum nitride, aluminum titanium nitride, and silicon nitride. Other examples include a nitride oxide such as silicon nitride oxide. Examples of the material for the insulating layer having a function of inhibiting transmission of oxygen include gallium oxide.

An insulating layer that is in contact with an oxide semiconductor layer or provided in the vicinity of the oxide semiconductor layer, such as a gate insulating layer, preferably includes a region containing excess oxygen. For example, when an insulating layer including a region containing excess oxygen is in contact with an oxide semiconductor layer or positioned in the vicinity of the oxide semiconductor layer, oxygen vacancies in the oxide semiconductor layer can be reduced. For the insulating layer in which the region containing excess oxygen is easily formed, the description in <Structure example of semiconductor device>can be referred to.

As the insulating layer that is in contact with the oxide semiconductor layer or provided in the vicinity of the oxide semiconductor layer, a barrier insulating layer against hydrogen is preferably used. When the insulating layer has a barrier property against hydrogen, diffusion of hydrogen into the oxide semiconductor layer can be inhibited. The barrier insulating layer against hydrogen can be rephrased as an insulating layer having a function of inhibiting diffusion of hydrogen.

Examples of an insulating material having a function of capturing or fixing hydrogen include metal oxides such as an oxide containing hafnium, an oxide containing magnesium, an oxide containing aluminum, an oxide containing aluminum and hafnium (hafnium aluminate), and hafnium silicate. Furthermore, these metal oxides may further contain zirconium, and an example of such a metal oxide is an oxide containing hafnium and zirconium.

The insulating layer having a function of capturing or fixing hydrogen preferably has an amorphous structure. In a metal oxide having an amorphous structure, some oxygen atoms have a dangling bond, which allows the metal oxide to have a high property of capturing or fixing hydrogen. Thus, when the insulating layer has an amorphous structure, the function of capturing or fixing hydrogen can be enhanced.

When the insulating layer has an amorphous structure, formation of a crystal grain boundary can be inhibited. Inhibiting formation of a crystal grain boundary can increase the planarity of the insulating layer. This enables the insulating layer to have uniform thickness distribution and a reduced number of extremely thin portions, so that the withstand voltage of the insulating layer can be increased. In addition, the thickness distribution of the film provided over the insulating layer can be uniform. Furthermore, inhibiting formation of a crystal grain boundary in the insulating layer can reduce leakage current due to the defect states in the crystal grain boundary. Thus, the insulating layer can function as an insulating film with a low leakage current.

Note that a function of capturing or fixing a target substance can also be referred to as a property that does not easily allow diffusion of a target substance. Thus, a function of capturing or fixing a target substance can be rephrased as a barrier property.

In this specification and the like, a barrier insulating layer refers to an insulating layer having a barrier property. In addition, the barrier property refers to a property that does not easily allow diffusion of a target substance (also referred to as a property that does not easily allow transmission of a target substance, a property with low permeability of a target substance, or a function of inhibiting diffusion of a target substance). Note that hydrogen described as a target substance refers to at least one of a hydrogen atom, a hydrogen molecule, and a substance bonded to hydrogen, such as a water molecule or OH, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), a copper atom, and the like. Oxygen described as a target substance refers to, for example, at least one of an oxygen atom, an oxygen molecule, and the like.

Examples of a material for the barrier insulating layer against hydrogen include aluminum oxide, magnesium oxide, hafnium oxide, zirconium oxide, an oxide containing aluminum and hafnium (hafnium aluminate), an oxide containing hafnium and zirconium (hafnium zirconium oxide), silicon nitride, and silicon nitride oxide.

The inorganic insulating layers given as examples of the insulating layer having a function of capturing or fixing hydrogen and the insulating layer having a function of inhibiting diffusion of hydrogen also have a barrier property against oxygen. Examples of a material for a barrier insulating layer against oxygen include an oxide containing one or both of aluminum and hafnium, magnesium oxide, gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and hafnium silicate.

### [Conductive Layer]

For each of the conductive layers included in the semiconductor device (e.g., the conductive layers 220, 240, 255, 260, and 265), it is preferable to use a metal element selected from aluminum, chromium, copper, silver, gold, platinum, zinc, tantalum, nickel, titanium, iron, cobalt, molybdenum, tungsten, hafnium, vanadium, niobium, manganese, magnesium, zirconium, beryllium, indium, ruthenium, palladium, iridium, strontium, lanthanum, and the like; an alloy containing any of the above metal elements as its component; an alloy containing a combination of the above metal elements; or the like. As an alloy containing any of the above metal elements as its component, a nitride of the alloy or an oxide of the alloy may be used. For example, tantalum nitride, titanium nitride, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. A semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting diffusion of oxygen, or a material maintaining its conductivity even after absorbing oxygen. Examples of the conductive material containing oxygen include indium oxide containing tungsten oxide, indium oxide containing titanium oxide, ITO, indium tin oxide containing titanium oxide, ITSO, In—Zn oxide, and indium zinc oxide containing tungsten oxide. In this specification and the like, a conductive film formed using the conductive material containing oxygen may be referred to as an oxide conductive film.

Conductive layers formed using any of the above materials may be stacked. For example, a stacked-layer structure combining a material containing any of the above metal elements and a conductive material containing oxygen may be employed. Alternatively, a stacked-layer structure combining a material containing any of the above metal elements and a conductive material containing nitrogen may be employed. Further alternatively, a stacked-layer structure combining a material containing any of the above metal elements, a conductive material containing oxygen, and a conductive material containing nitrogen may be employed.

In the case where a metal oxide is used for the channel formation region of the transistor, the conductive layer functioning as the gate electrode preferably employs a stacked-layer structure combining a material containing any of the above metal elements and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

### [Substrate]

As a substrate where a transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Other examples include any of the above semiconductor substrates including an insulator region, e.g., a silicon on insulator (SOI) substrate. Examples of the conductor substrate include a graphite substrate, a metal substrate, an alloy substrate, and a conductive resin substrate. Other examples include a substrate containing a nitride of a metal and a substrate containing an oxide of a metal.

Other examples include a substrate which is an insulator substrate provided with a conductor or a semiconductor, a substrate which is a semiconductor substrate provided with a conductor or an insulator, and a substrate which is a conductor substrate provided with a semiconductor or an insulator. Alternatively, these substrates provided with elements may be used. Examples of the element provided over the substrate include a capacitor, a resistor, a switching element, a light-emitting element, and a memory element.

The above is the description of materials that can be used for the semiconductor device of this embodiment.

This embodiment can be combined with any of the other embodiments and examples as appropriate. In this specification, in the case where a plurality of structure examples are shown in one embodiment, the structure examples can be combined as appropriate.

### Embodiment 3

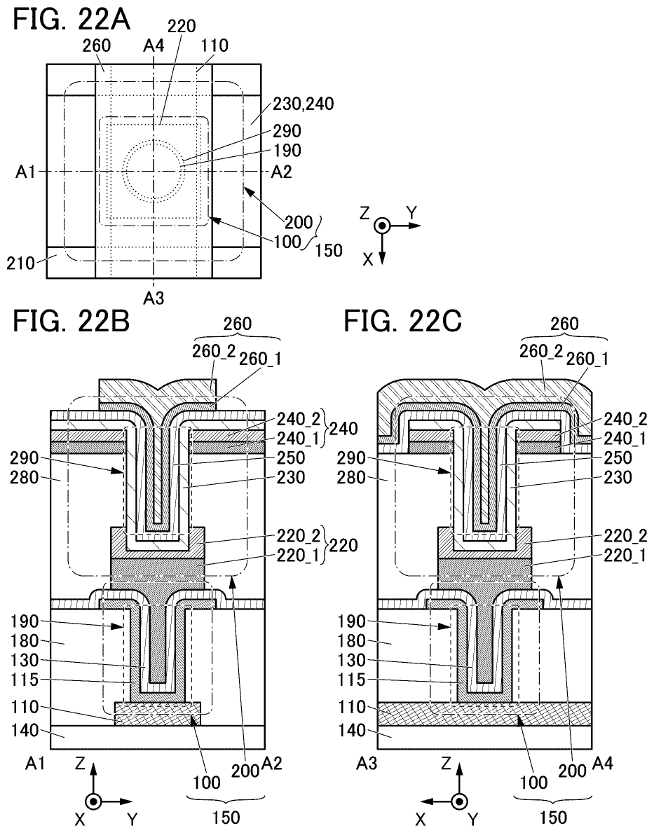

In this embodiment, memory devices of one embodiment of the present invention will be described with reference to FIGS. 22A to 22C, FIGS. 23A to 23C, FIGS. 24A to 24C, FIGS. 25A and 25B, FIGS. 26A and 26B, FIG. 27, and FIG. 28. The memory devices of one embodiment of the present invention each include a memory cell. The memory cell includes a transistor and a capacitor.

### <Structure Example 1 of Memory Device>

A structure of a memory device including a memory cell is described with reference to FIGS. 22A to 22C. FIG. 22A is a plan view of a memory device including a memory cell 150. FIG. 22B is a cross-sectional view taken along the dashed-dotted line A1-A2 in FIG. 22A. FIG. 22C is a cross-sectional view taken along the dashed-dotted line A3-A4 in FIG. 22A.

The memory device illustrated in FIGS. 22A to 22C includes an insulating layer 140 over a substrate (not illustrated), a conductive layer 110 over the insulating layer 140, the memory cell 150 over the conductive layer 110, an insulating layer 180 over the conductive layer 110, and the insulating layer 280. The insulating layers 140 and 180 function as interlayer films. The conductive layer 110 functions as a wiring.

The memory cell 150 includes a capacitor 100 over the conductive layer 110 and a transistor 200 over the capacitor 100.

The capacitor 100 includes a conductive layer 115 over the conductive layer 110, the insulating layer 130 over the conductive layer 115, and the conductive layer 220_1 over the insulating layer 130. The conductive layer 220_1 functions as one of a pair of electrodes (sometimes referred to as an upper electrode), the conductive layer 115 functions as the other of the pair of electrodes (sometimes referred to as a lower electrode), and the insulating layer 130 functions as a dielectric. That is, the capacitor 100 is a metal-insulator-metal (MIM) capacitor. Note that the conductive layer 220_2 provided over the conductive layer 220_1 can be regarded as part of the upper electrode of the capacitor 100.

As illustrated in FIGS. 22B and 22C, an opening portion 190 reaching the conductive layer 110 is provided in the insulating layer 180. At least part of the conductive layer 115 is placed in the opening portion 190. Note that the conductive layer 115 includes a region in contact with the top surface of the conductive layer 110 in the opening portion 190, a region in contact with the side surface of the insulating layer 180 in the opening portion 190, and a region in contact with at least part of the top surface of the insulating layer 180. The insulating layer 130 is placed to be positioned in the opening portion 190 at least partly. The conductive layer 220_1 is placed to be positioned in the opening portion 190 at least partly. The conductive layer 220_1 is preferably provided to fill the opening portion 190 as illustrated in FIGS. 22B and 22C. The films provided in the opening portion 190 are preferably formed by an ALD method. Thus, the coverage with the films can be improved. For example, the conductive layer 115, the insulating layer 130, and the conductive layer 220_1 are preferably formed by an ALD method.

The upper electrode and the lower electrode of the capacitor 100 face each other with the dielectric therebetween, along the side surface of the opening portion 190 as well as the bottom surface thereof; thus, the capacitance per unit area can be larger. Accordingly, the deeper the opening portion 190 is, the larger the capacitance of the capacitor 100 can be. Increasing the capacitance per unit area of the capacitor 100 in this manner allows stable reading operation of the memory device. This can also promote scaling down or high integration of the memory device.

FIGS. 22B and 22C illustrate an example in which the sidewall of the opening portion 190 is perpendicular to the top surface of the conductive layer 110 and the opening portion 190 is circular in the plan view. Such a structure enables scaling down or high integration of the memory device.

The conductive layer 115 and the insulating layer 130 are stacked along the sidewall of the opening portion 190 and the top surface of the conductive layer 110. The conductive layer 220_1 is provided over the insulating layer 130 to fill the opening portion 190. The capacitor 100 having such a structure may be referred to as a trench-type capacitor or a trench capacitor.

The conductive layer 110 functions as a wiring CAL described later and can be provided in a belt-like shape, for example. Note that a belt-like shape refers to a shape including a region extending in a certain direction (e.g., the X direction, the Y direction, or the Z direction).

The conductive layer 110 can be formed as a single layer or stacked layers using any of the conductive materials described in [Conductive layer] in Embodiment 2. For example, a conductive material with high conductivity such as tungsten can be used for the conductive layer 110. With the use of a conductive material with high conductivity, the conductivity of the conductive layer 110 can be improved and the conductive layer 110 can function adequately as the wiring CAL.

For the conductive layer 115, it is preferable to use a single layer or stacked layers of a conductive material that is not easily oxidized, a conductive material having a function of inhibiting diffusion of oxygen, or the like. For example, titanium nitride, ITSO, or the like may be used. Alternatively, a structure in which titanium nitride is stacked over tungsten may be used, for example. Alternatively, a structure in which tungsten is stacked over first titanium nitride and second titanium nitride is stacked over the tungsten may be used, for example. With such a structure, the conductive layer 115 can be inhibited from being oxidized by the insulating layer 130 even when an oxide is used for the insulating layer 130. Such a structure can also inhibit oxidation of the conductive layer 115 by the insulating layer 180 even when an oxide is used for the insulating layer 180.

The insulating layer 130 can be provided to be in contact with the top and side surfaces of the conductive layer 115. That is, the insulating layer 130 preferably covers the side end portion of the conductive layer 115. This can prevent a short circuit between the conductive layer 115 and the conductive layer 220_1.

Alternatively, the side end portion of the insulating layer 130 and the side end portion of the conductive layer 115 may be aligned or substantially aligned with each other. With such a structure, the insulating layer 130 and the conductive layer 115 can be formed using the same mask, so that the fabrication process of the memory device can be simplified.

For the insulating layer 130, a high-k material is preferably used. Using a high-k material for the insulating layer 130 allows the insulating layer 130 to be thick enough to inhibit leakage current and the capacitor 100 to have a sufficiently high capacitance.

The insulating layer 130 preferably has a stacked-layer structure including an insulating layer that contains a high-k material. A stacked-layer structure containing a high-k material and a material with higher dielectric strength than the high-k material is preferably used. For example, as the insulating layer 130, an insulating film in which zirconium oxide, aluminum oxide, and zirconium oxide are stacked in this order can be used. For another example, an insulating film in which zirconium oxide, aluminum oxide, zirconium oxide, and aluminum oxide are stacked in this order can be used. For another example, an insulating film in which hafnium zirconium oxide, aluminum oxide, hafnium zirconium oxide, and aluminum oxide are stacked in this order can be used. The stacking of such an insulating layer having relatively high dielectric strength, such as aluminum oxide, can increase the dielectric strength and inhibit electrostatic breakdown of the capacitor 100.

Alternatively, a material that can have ferroelectricity may be used for the insulating layer 130. The description in Embodiment 2 can also be referred to for the details of the material that can have ferroelectricity.

A metal oxide containing one or both of hafnium and zirconium is preferable as the insulating layer 130 because the metal oxide can have ferroelectricity even when being a thin film of several nanometers. The thickness of the insulating layer 130 is preferably less than or equal to 100 nm, further preferably less than or equal to 50 nm, still further preferably less than or equal to 20 nm, yet still further preferably less than or equal to 10 nm (typically, greater than or equal to 2 nm and less than or equal to 9 nm). For example, the thickness is preferably greater than or equal to 8 nm and less than or equal to 12 nm. With the use of the ferroelectric layer that can have a small thickness, the capacitor 100 can be combined with a miniaturized semiconductor element such as a transistor to fabricate a semiconductor device.

A metal oxide containing one or both of hafnium and zirconium is preferable as the insulating layer 130 because the metal oxide can have ferroelectricity even with a minute area. For example, a ferroelectric layer can have ferroelectricity even with an area (occupation area) less than or equal to 100 μm², less than or equal to 10 μm², less than or equal to 1 μm², or less than or equal to 0.1 μm² in the plan view. Furthermore, even with an area less than or equal to 10000 nm² or less than or equal to 1000 nm², a ferroelectric layer can have ferroelectricity in some cases. With a small-area ferroelectric layer, the area occupied by the capacitor 100 can be reduced.

A ferroelectric refers to an insulator having a property of causing internal polarization by application of an electric field from the outside and maintaining the polarization even after the electric field is made zero. Thus, with the use of a capacitor that contains this material as a dielectric (hereinafter, such a capacitor is sometimes referred to as a ferroelectric capacitor), a nonvolatile memory element can be formed. A nonvolatile memory element including a ferroelectric capacitor is sometimes referred to as a ferroelectric random access memory (FeRAM), a ferroelectric memory, or the like. For example, a ferroelectric memory includes a transistor and a ferroelectric capacitor, and one of a source and a drain of the transistor is connected to one terminal of the ferroelectric capacitor. Thus, in the case of using a ferroelectric capacitor as the capacitor 100, the memory device described in this embodiment functions as a ferroelectric memory.

The conductive layer 220_1 is provided in contact with part of the top surface of the insulating layer 130. The side end portion of the conductive layer 220_1 is preferably positioned inward from the side end portion of the conductive layer 115 in both the X direction and the Y direction. In the structure in which the insulating layer 130 covers the side end portion of the conductive layer 115, the side end portion of the conductive layer 220_1 may be positioned outward from the side end portion of the conductive layer 115.

The insulating layer 180 functions as an interlayer film and thus preferably has a low dielectric constant. In the case where a material with a low dielectric constant is used for an interlayer film, parasitic capacitance generated between wirings can be reduced.

Although the insulating layer 180 has a single-layer structure in FIGS. 22B and 22C, the present invention is not limited thereto. The insulating layer 180 may have a stacked-layer structure of two or more layers.

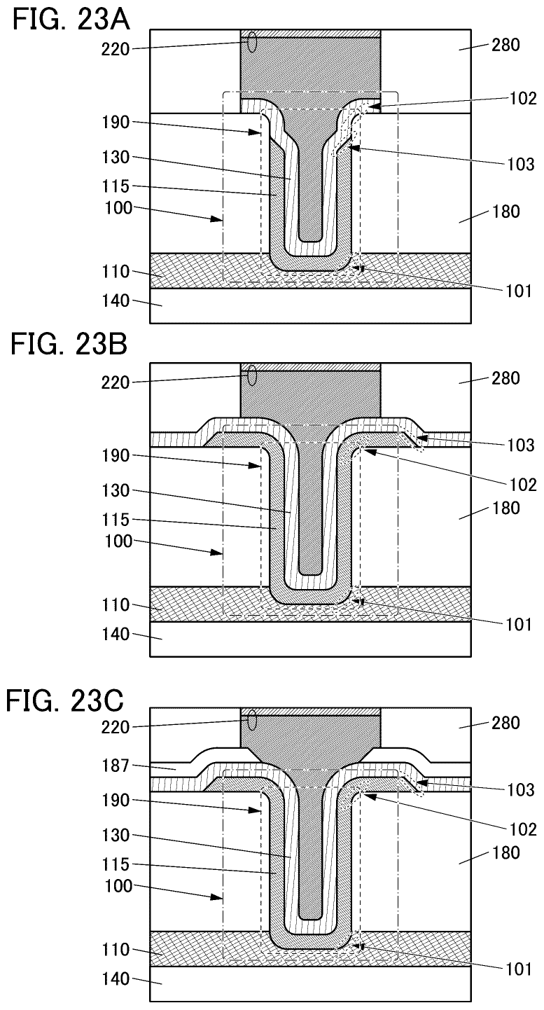

FIG. 23A illustrates an example in which the conductive layer 115 includes a region 101 with a curved corner in the depressed portion of the conductive layer 110. Thus, electric field concentration on the insulating layer 130 in the vicinity of the region 101 can be inhibited as compared with the case where the region 101 has an angular portion (a right angle or an acute angle) in the cross-sectional view, for example. An end portion 103 of the conductive layer 115 is provided at a lower level than the top surface of the insulating layer 180 with respect to a reference surface. Accordingly, electric field concentration on the insulating layer 130 in the vicinity of the end portion 103 can be inhibited as compared with the case where the end portion 103 is positioned above the insulating layer 180. When electric field concentration on the insulating layer 130 is inhibited in this manner, the dielectric breakdown of the insulating layer 130 can be inhibited, so that a highly reliable memory device can be provided.

FIG. 23B illustrates an example in which the end portion 103 illustrated in FIG. 23A is positioned over the insulating layer 180. In the example illustrated in FIG. 23B, a region 102 from the top surface of the insulating layer 180 to the side surface of the opening portion 190 has a curved portion. In the example illustrated in FIG. 23B, the end portion 103 has a tapered shape. When the region 102 has a curved portion and the end portion 103 has a tapered shape, electric field concentration on the insulating layer 130 in the vicinity of the region 102 and in the vicinity of the end portion 103 can be inhibited even when the end portion 103 is positioned over the insulating layer 180. Accordingly, the dielectric breakdown of the insulating layer 130 is inhibited, so that a highly reliable memory device can be provided.

FIG. 23C illustrates an example in which an insulating layer 187 is provided over the insulating layer 130 illustrated in FIG. 23B, for example, over a region of the insulating layer 130 that overlaps with the insulating layer 180. Providing the insulating layer 187 can suitably inhibit electric field concentration on the insulating layer 130 in some cases.

The insulating layer 280 is provided over the capacitor 100. The insulating layer 280 includes a portion positioned over the insulating layer 130 and a portion positioned over the conductive layer 220_2.

The description in Embodiment 2 (for the transistor 200A illustrated in FIG. 4A) can be referred to for the transistor 200; thus, the detailed description thereof is omitted. The transistor included in the memory cell 150 is not limited to the transistor 200A, and any of the transistors described as examples in Embodiment 2 can be used. Alternatively, a transistor with a planar structure, a gate all around (GAA) structure, or a lateral gate all around (LGAA) structure can be used.

As illustrated in FIGS. 22A to 22C, the transistor 200 is provided to overlap with the capacitor 100. The opening portion 290 where parts of the components of the transistor 200 are provided includes a region overlapping with the opening portion 190 where parts of the components of the capacitor 100 are provided. In particular, since the conductive layer 220 has a function of one of a source electrode and a drain electrode of the transistor 200 and a function of the upper electrode of the capacitor 100, the transistor 200 and the capacitor 100 share part of the structure. With such a structure, the transistor 200 and the capacitor 100 can be provided without a significant increase in the occupation area in the plan view. Thus, the area occupied by the memory cell 150 can be reduced, so that the memory cells 150 can be arranged densely and the memory capacity of the memory device can be increased. In other words, the memory device can be highly integrated. FIGS. 22B and 22C illustrate an example in which the width of the opening portion 190 is smaller than the width of the opening portion 290. There is no particular limitation on the size relationship between the width of the opening portion 190 and the width of the opening portion 290. In view of scaling down, the width of the opening portion 190 is preferably smaller than or equal to the width of the opening portion 290.

When the transistor 200 is provided above the capacitor 100, the transistor 200 is not affected by heat treatment in fabricating the capacitor 100. Thus, in the transistor 200, degradation of the electrical characteristics such as variation in threshold voltage and an increase in parasitic resistance, and an increase in variation in electrical characteristics due to the degradation of the electrical characteristics can be inhibited.

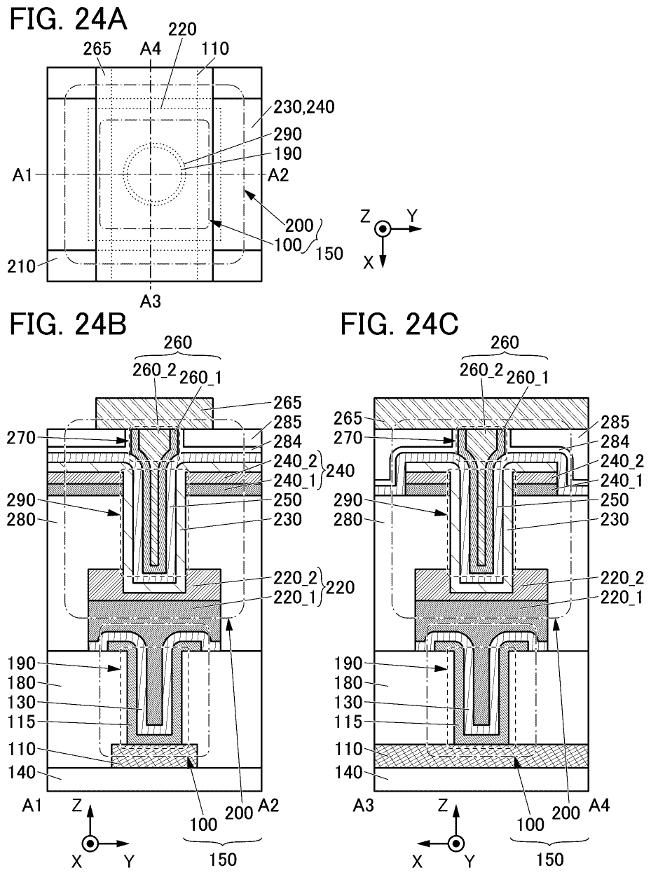

FIGS. 24A to 24C illustrate a memory device in which the transistor 200B described in Embodiment 2 is used as the transistor 200 included in the memory cell 150. FIG. 24A is a plan view of the memory device including the memory cell 150. FIG. 24B is a cross-sectional view taken along the dashed-dotted line A1-A2 in FIG. 24A. FIG. 24C is a cross-sectional view taken along the dashed-dotted line A3-A4 in FIG. 24A.

As illustrated in FIGS. 24B and 24C, the side end portion of the insulating layer 130 and the side end portion of the conductive layer 220 may be aligned or substantially aligned with each other. With such a structure, the insulating layer 130 and the conductive layer 220 can be formed using the same mask, so that the fabrication process of the memory device can be simplified.

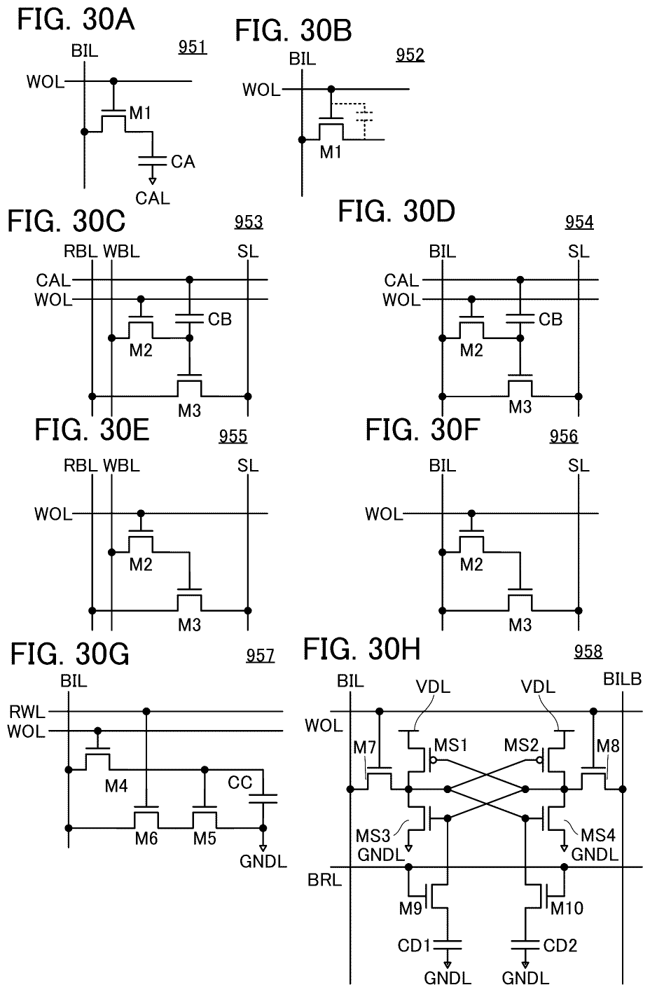

FIG. 30A is a circuit diagram of the memory device described in this embodiment. As illustrated in FIG. 30A, the structure illustrated in FIGS. 22A to 22C functions as a memory cell. A memory cell 951 includes a transistor M1 and a capacitor CA. Here, the transistor M1 corresponds to the transistor 200, and the capacitor CA corresponds to the capacitor 100.

One of a source and a drain of the transistor M1 is connected to one of a pair of electrodes of the capacitor CA. The other of the source and the drain of the transistor M1 is connected to a wiring BIL. A gate of the transistor M1 is connected to a wiring WOL. The other of the pair of electrodes of the capacitor CA is connected to the wiring CAL.

Here, the wiring BIL corresponds to the conductive layer 240, the wiring WOL corresponds to the conductive layer 260, and the wiring CAL corresponds to the conductive layer 110. As illustrated in FIGS. 22A to 22C, it is preferable that the conductive layer 260 be provided to extend in the X direction and the conductive layer 240 be provided to extend in the Y direction. With such a structure, the wiring BIL and the wiring WOL are provided to intersect with each other. The wiring CAL (the conductive layer 110) is provided parallel to the wiring WOL (the conductive layer 260) in FIG. 22A. Note that the present invention is not limited thereto. For example, the wiring CAL may be provided parallel to the wiring BIL (the conductive layer 240).

Note that the memory cell will be described in detail in a later embodiment.

### <Structure Example 2 of Memory Device>

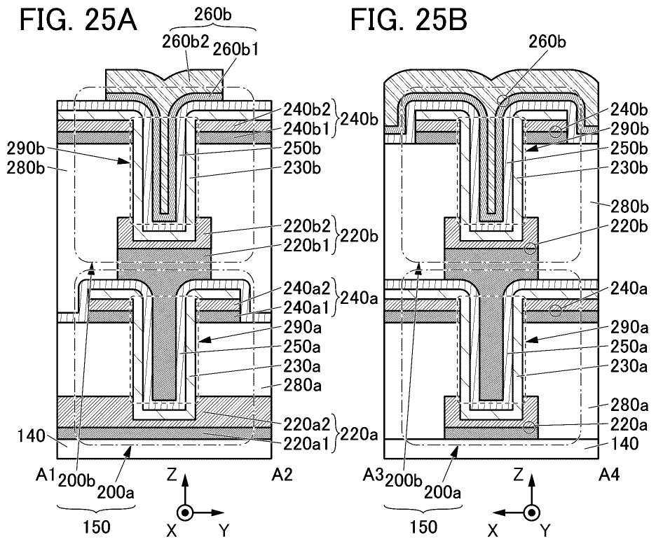

FIGS. 25A and 25B are cross-sectional views of a memory device including a transistor 200a and a transistor 200b.

The memory device illustrated in FIGS. 25A and 25B includes the insulating layer 140 over a substrate (not illustrated), the memory cell 150 over the insulating layer 140, an insulating layer 280a over the insulating layer 140, and an insulating layer 280b above the insulating layer 280a. The insulating layers 140, 280a, and 280b function as interlayer films.

The memory cell 150 includes the transistor 200a over the insulating layer 140 and the transistor 200b over the transistor 200a.

The description of the transistor 200 in Embodiment 2 (the transistor 200A illustrated in FIG. 4A) can be referred to for the transistors 200a and 200b; thus, the detailed description thereof is omitted. For example, the description with reference to FIG. 4A can be referred to for the structures of a conductive layer 220a, a semiconductor layer 230a, and the like by replacing the conductive layer 220 with the conductive layer 220a and replacing the semiconductor layer 230 with the semiconductor layer 230a. For another example, the description with reference to FIG. 4A can be referred to for the structures of a conductive layer 220b, a semiconductor layer 230b, and the like by replacing the conductive layer 220 with the conductive layer 220b and replacing the semiconductor layer 230 with the semiconductor layer 230b.

The insulating layers 280a and 280b can each have a structure similar to the structure that can be employed for the insulating layer 280.

The transistors included in the memory cell 150 are not limited to the combination of the transistors 200a and 200b, and one or more kinds of the transistors described in Embodiment 2 can be used.

In the memory cell 150 illustrated in FIGS. 25A and 25B, capacitance generated between the conductive layer 220b and a conductive layer 240a can be used; thus, data can be retained without formation of an additional capacitor.

The shortest distance from the top surface of the conductive layer 240a to the conductive layer 220b is preferably shorter than the shortest distance from the top surface of a conductive layer 240b to the gate wiring (a conductive layer 260b in FIG. 25A). Thus, the capacitance generated between the conductive layer 220b and the conductive layer 240a can be increased. In addition, the parasitic capacitance generated between the conductive layer 240b and the gate wiring can be reduced. The transistor 200b can have the structure of the transistor 200B described in Embodiment 2, for example.

As illustrated in FIGS. 25A and 25B, the transistor 200b is provided to overlap with the transistor 200a. An opening portion 290b where parts of the components of the transistor 200b are provided includes a region overlapping with an opening portion 290a where parts of the components of the transistor 200a are provided. In particular, since the conductive layer 220b has a function of one of a source electrode and a drain electrode of the transistor 200b and a function of a gate electrode of the transistor 200a, the transistor 200b and the transistor 200a share part of the structure. With such a structure, the transistor 200b and the transistor 200a can be provided without a significant increase in the occupation area in the plan view. Thus, the area occupied by the memory cell 150 can be reduced, so that the memory cells 150 can be arranged densely and the memory capacity of the memory device can be increased. In other words, the memory device can be highly integrated.

FIG. 30E is a circuit diagram of the memory device described in this embodiment. As illustrated in FIG. 30E, the structure illustrated in FIGS. 25A and 25B functions as a memory cell. A memory cell 955 includes a transistor M2 and a transistor M3. Here, the transistor M2 corresponds to the transistor 200b, and the transistor M3 corresponds to the transistor 200a.

One of a source and a drain of the transistor M2 is connected to a gate of the transistor M3. The other of the source and the drain of the transistor M2 is connected to a wiring WBL. A gate of the transistor M2 is connected to the wiring WOL. One of a source and a drain of the transistor M3 is connected to a wiring RBL. The other of the source and the drain of the transistor M3 is connected to a wiring SL.

Here, the wiring WBL corresponds to the conductive layer 240b, and the wiring WOL corresponds to the conductive layer 260b. As illustrated in FIGS. 25A and 25B, it is preferable that the conductive layer 260b be provided to extend in the X direction and the conductive layer 240b be provided to extend in the Y direction. With such a structure, the wiring WBL and the wiring WOL are provided to intersect with each other.

The transistor M2 may include a back gate. Similarly, the transistor M3 may include a back gate.

### <Structure Example 3 of Memory Device>

The memory cell 150 including the transistor 200 and the capacitor 100 described in this embodiment can be used as a memory cell of the memory device. The transistor 200 is an OS transistor. Since the transistor 200 has a low off-state current, a memory device including the transistor 200 can retain stored data for a long time. In other words, such a memory device does not require refresh operation or has an extremely low frequency of refresh operation, leading to a sufficient reduction in power consumption. The transistor 200 has high frequency characteristics and thus enables the memory device to perform reading and writing at high speed.

The memory cells 150 can be arranged in a matrix three-dimensionally to form a memory cell array.

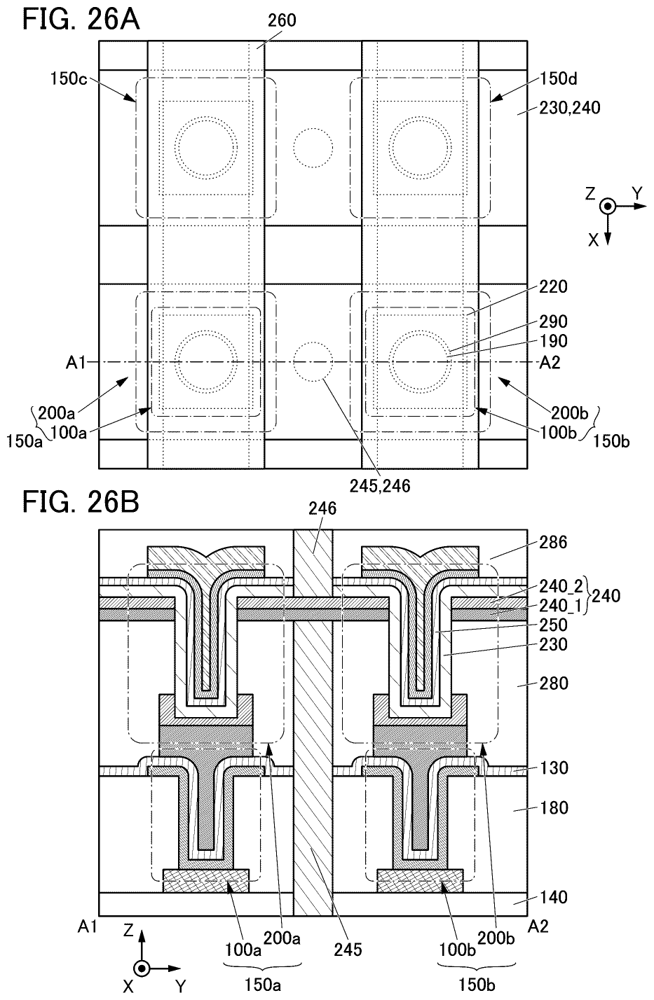

FIG. 26A is a plan view of a memory device. FIG. 26A illustrates an example in which 2×2 memory cells (memory cells 150a to 150d) are arranged in the X direction and the Y direction.

FIG. 26B is a cross-sectional view taken along the dashed-dotted line A1-A2 in FIG. 26A. In FIGS. 26A and 26B, two memory cells (the memory cells 150a and 150b in FIG. 26B) are connected to a common wiring (a conductive layer 246).

The memory cells 150a and 150b illustrated in FIGS. 26A and 26B each have a structure similar to that of the memory cell 150. The memory cell 150a includes a capacitor 100a and the transistor 200a, and the memory cell 150b includes a capacitor 100b and the transistor 200b. The memory cells 150c and 150d illustrated in FIG. 26A each have a structure similar to that of the memory cell 150. Thus, in the memory device illustrated in FIGS. 26A and 26B, components having the same functions as the components of the memory device illustrated in FIGS. 22A to 22C are denoted by the same reference numerals. The description of the memory cell 150 in <Structure example 1 of memory device>can be referred to for the details of the memory cells 150a to 150d.

As illustrated in FIGS. 26A and 26B, the conductive layer 260 functioning as the wiring WOL is provided in each of the memory cells 150a and 150b. As illustrated in FIG. 26A, one conductive layer 260 is shared by the memory cells 150a and 150c, and another conductive layer 260 is shared by the memory cells 150b and 150d. One conductive layer 240 functioning as part of the wiring BIL is shared by the memory cells 150a and 150b. That is, the conductive layer 240 is in contact with the semiconductor layer 230 of the memory cell 150a and the semiconductor layer 230 of the memory cell 150b. Another conductive layer 240 is shared by the memory cells 150c and 150d.

Here, the memory device illustrated in FIGS. 26A and 26B includes a conductive layer 245 and the conductive layer 246 functioning as plugs (also can be referred to as connection electrodes) connected to the memory cells 150a and 150b. The conductive layer 245 is placed in an opening portion formed in the insulating layers 140, 180, 130, and 280 and is in contact with the bottom surface of the conductive layer 240_1. The conductive layer 246 is placed in an opening portion formed in an insulating layer 286, the insulating layer 250, and the semiconductor layer 230 and is in contact with the top surface of the conductive layer 240_2. Note that any of the conductive materials that can be used for the conductive layer 240 can be used for the conductive layers 245 and 246, for example.

The conductive layer 246 can be in contact with the top surface of the conductive layer 240_1. Alternatively, the conductive layer 246 can be in contact with the top surface of the semiconductor layer 230. That is, the conductive layer 240_2 may have an opening portion in a position overlapping with the conductive layer 246. The semiconductor layer 230 does not necessarily have an opening portion in a position overlapping with the conductive layer 246. As a connection portion between the memory cell and the plug, a layer having a low contact resistance with the conductive layer 246 among the layers included in the conductive layer 240 and the semiconductor layer 230 is preferably in contact with the conductive layer 246.

Similarly, the conductive layer 245 can be in contact with the bottom surface of the conductive layer 240_2 or the bottom surface of the semiconductor layer 230. That is, the conductive layer 240_1 may have an opening portion in a position overlapping with the conductive layer 246. Among the layers included in the conductive layer 240 and the semiconductor layer 230, a layer having a low contact resistance with the conductive layer 245 is preferably in contact with the conductive layer 245.

Among the layers included in the conductive layer 240 and the semiconductor layer 230, a layer with a low wiring resistance is preferably in contact with the conductive layers 245 and 246.

The conductive layers 245 and 246 each function as a plug or a wiring for connecting the memory cells 150a and 150b to a wiring, an electrode, a terminal, or a circuit element such as a switch, a transistor, a capacitor, an inductor, a resistor, or a diode. For example, the conductive layer 245 can be connected to a sense amplifier (not illustrated) provided below the memory device illustrated in FIG. 26B, and the conductive layer 246 can be connected to a similar memory device (not illustrated) provided above the memory device illustrated in FIG. 26B. In that case, the conductive layers 245 and 246 function as part of the wiring BIL. When the memory device or the like is provided above or below the memory device illustrated in FIG. 26B in this manner, the memory capacity per unit area can be increased.

The memory cells 150a and 150b have a line-symmetric structure with a perpendicular bisector of the dashed-dotted line A1-A2 as the symmetric axis. Thus, the transistors 200a and 200b are also placed symmetrically with the conductive layers 245 and 246 therebetween. The conductive layer 240 has a function of the other of the source electrode and the drain electrode of the transistor 200a and a function of the other of the source electrode and the drain electrode of the transistor 200b. The transistors 200a and 200b share the conductive layers 245 and 246. With the above connection structure between the two transistors and the plugs, a memory device that can be scaled down or highly integrated can be provided.

Note that the conductive layer 110 may be provided in each of the memory cells 150a and 150b or may be provided in common to the memory cells 150a and 150b. However, as illustrated in FIG. 26B, the conductive layer 110 is provided to be apart from the conductive layer 245 so that the conductive layers 110 and 245 are not short-circuited.

The memory cell 150 illustrated in FIGS. 24A to 24C may be used as the memory cell illustrated in FIGS. 26A and 26B. When the side end portion of the insulating layer 130 and the side end portion of the conductive layer 220 are aligned with each other, the insulating layer 130 does not overlap with the conductive layer 245. This makes processing at the time of forming the opening portion in which the conductive layer 245 is provided relatively easy.

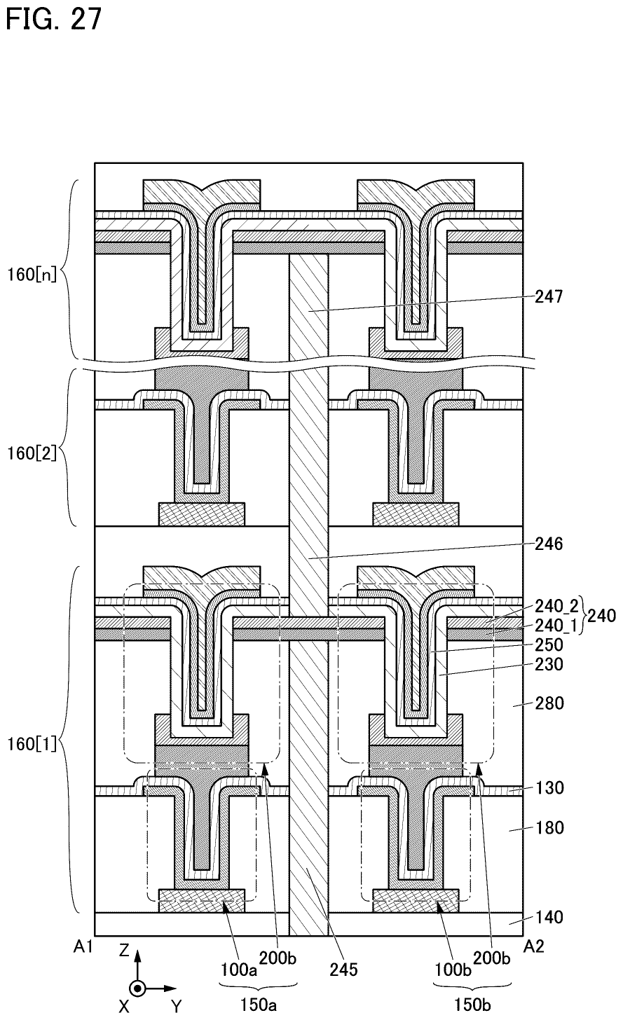

FIG. 27 illustrates an example in which n layers (n is an integer greater than or equal to 3) each including the four memory cells illustrated in FIG. 26A are stacked in the Z direction. FIG. 27 is a cross-sectional view taken along the dashed-dotted line A1-A2 in FIG. 26A.

A memory device illustrated in FIG. 27 includes n memory layers 160. Specifically, a memory layer 160 [2] is provided over a memory layer 160 [1], (n-2) memory layers are provided over the memory layer 160 [2], and a memory layer 160 [n] is provided as the uppermost layer. There is no particular limitation on the number of memory cells included in one memory layer 160, and two or more memory cells can be included. Through the conductive layer 245, the conductive layer 246, a conductive layer 247, and the like, memory cells included in the n memory layers 160 are connected to a sense amplifier (not illustrated) provided below the n memory layers 160.

FIG. 27 illustrates an example in which the conductive layer 245 is in contact with the bottom surface of the conductive layer 240 and the conductive layer 246 is in contact with the top surface of the conductive layer 240. As described above, a connection portion between the plug such as the conductive layer 245 or the conductive layer 246 and each memory cell can have any of a variety of modes and is not limited to the structure in FIG. 27.

When a plurality of memory cells are stacked as illustrated in FIG. 27, the cells can be provided in an integrated manner without increasing the area occupied by the memory cell array. That is, a 3D memory cell array can be formed.

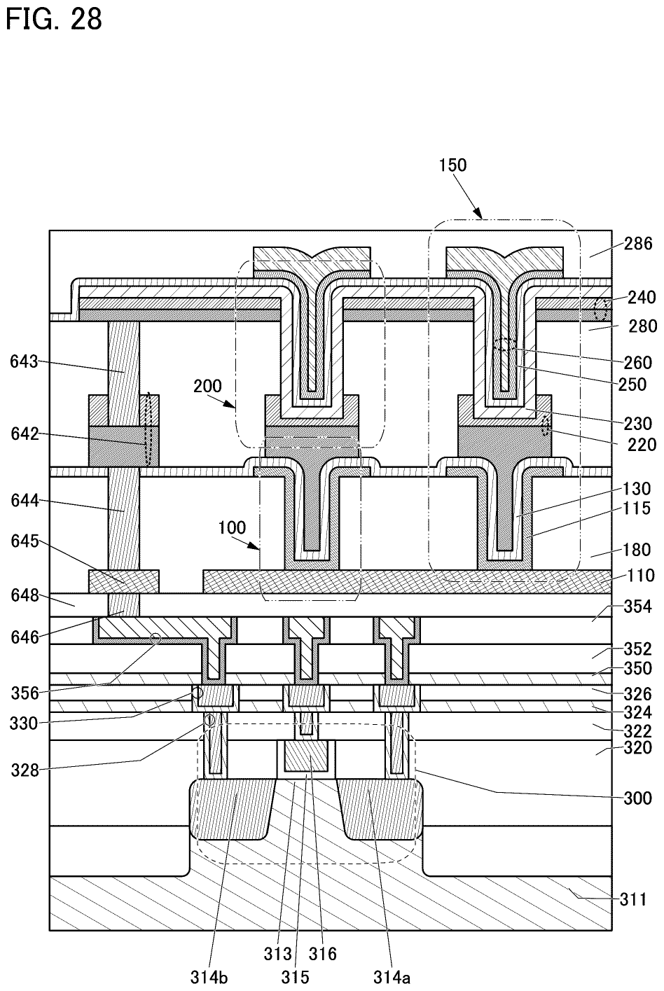

FIG. 28 illustrates a cross-sectional structure example of a memory device in which a layer including a memory cell is stacked over a layer including a driver circuit provided with a sense amplifier.

In FIG. 28, the memory cell 150 (the transistor 200 and the capacitor 100) is provided above a transistor 300.

The transistor 300 is one of the transistors included in the sense amplifier.

The description of the memory cell 150 in <Structure example 1 of memory device>can be referred to for the memory cell 150 illustrated in FIG. 28.

When the sense amplifier is provided to overlap with the memory cell 150 as illustrated in FIG. 28, the bit line can be shortened. Accordingly, the bit line capacitance can be reduced and the memory device can be driven at high speed.

The memory device illustrated in FIG. 28 can correspond to a semiconductor device 900 described in Embodiment 4. Specifically, the transistor 300 corresponds to a transistor included in a sense amplifier 927 in the semiconductor device 900. The memory cell 150 corresponds to a memory cell 950.

The transistor 300 is provided on a substrate 311 and includes a conductive layer 316 functioning as a gate, an insulating layer 315 functioning as a gate insulating layer, a semiconductor region 313 that is part of the substrate 311, and a low-resistance region 314a and a low-resistance region 314b functioning as a source region and a drain region. The transistor 300 may be either a p-channel transistor or an n-channel transistor. The substrate 311 preferably includes a silicon-based semiconductor, specifically, single crystal silicon.

As the substrate 311, a structure body in which a single crystal oxide semiconductor film (typically, indium oxide film) is provided over a stabilized zirconia substrate can also be used. As described in Embodiment 2 and the like, an indium oxide film formed over a stabilized zirconia substrate includes a single crystal. With the use of part of the indium oxide film as the semiconductor region 313, the field-effect mobility and reliability of the transistor 300 can be increased.

In the transistor 300 illustrated in FIG. 28, the semiconductor region 313 (part of the substrate 311) in which a channel is formed has a projecting shape. Furthermore, the conductive layer 316 is provided to cover the side and top surfaces of the semiconductor region 313 with the insulating layer 315 therebetween. Note that the conductive layer 316 may be formed using a material for adjusting the work function. The transistor 300 having such a structure is also referred to as a FIN transistor because the projecting portion of the semiconductor substrate is utilized. Note that an insulating layer serving as a mask for forming the projecting portion may be provided in contact with the top of the projecting portion. Although the case where the projecting portion is formed by processing part of the semiconductor substrate is described here, a semiconductor film having a projecting shape may be formed by processing an SOI substrate.

Note that the transistor 300 illustrated in FIG. 28 is just an example and is not limited to having the structure illustrated therein; an appropriate transistor can be used in accordance with a circuit configuration or a driving method. In the structure illustrated in FIG. 28, the transistor 300 can be a p-channel transistor containing silicon (PMOS), the transistor 200 can be an n-channel transistor containing indium oxide (NMOS), and a complementary metal oxide semiconductor (CMOS) circuit can be formed using both the transistor 300 and the transistor 200. A CMOS circuit configuration will be described in detail in Embodiment 5.

A wiring layer including an interlayer film, a wiring, a plug, and the like may be provided between components. A plurality of wiring layers can be provided in accordance with the design. Here, a plurality of conductive layers functioning as plugs or wirings are collectively denoted by the same reference numeral in some cases. In this specification and the like, a wiring and a plug connected to the wiring may be a single component. That is, part of a conductive layer functions as a wiring in some cases and part of a conductive layer functions as a plug in other cases.

For example, an insulating layer 320, an insulating layer 322, an insulating layer 324, and an insulating layer 326 are stacked over the transistor 300 in this order as interlayer films. A conductive layer 328 is embedded in the insulating layer 320 and the insulating layer 322, and a conductive layer 330 is embedded in the insulating layer 324 and the insulating layer 326. Note that the conductive layer 328 and the conductive layer 330 each function as a plug or a wiring.

The insulating layer functioning as an interlayer film may function as a planarization film that covers a roughness thereunder. For example, the top surface of the insulating layer 322 may be planarized by planarization treatment using a chemical mechanical polishing (CMP) method or the like to improve the planarity.

A wiring layer may be provided over the insulating layer 326 and the conductive layer 330. For example, in FIG. 28, an insulating layer 350, an insulating layer 352, and an insulating layer 354 are stacked in this order. Furthermore, a conductive layer 356 is formed in the insulating layers 350, 352, and 354. The conductive layer 356 functions as a plug or a wiring.

As the insulating layer 352, the insulating layer 354, and the like functioning as interlayer films, the above-described insulating layer that can be used for the semiconductor device or the memory device can be used.

As the conductive layer functioning as a plug or a wiring, such as the conductive layer 328, the conductive layer 330, and the conductive layer 356, any of the conductive materials that can be used for the conductive layer 240 can be used. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

The conductive layer 240 included in the transistor 200 is connected to the low-resistance region 314b functioning as the source region or the drain region of the transistor 300 through a conductive layer 643, a conductive layer 642, a conductive layer 644, a conductive layer 645, a conductive layer 646, the conductive layer 356, the conductive layer 330, and the conductive layer 328.

The conductive layer 643 is embedded in the insulating layer 280. The conductive layer 642 is provided over the insulating layer 130 and is embedded in the insulating layer 280. The conductive layers 642 and 220 can be formed using the same material in the same step. The conductive layer 644 is embedded in the insulating layers 180 and 130. The conductive layer 645 is embedded in the insulating layer 180. The conductive layers 645 and 110 can be formed using the same material in the same step. The conductive layer 646 is embedded in an insulating layer 648. The transistor 300 and the conductive layer 110 are insulated from each other by the insulating layer 648.

This embodiment can be combined with any of the other embodiments and examples as appropriate. In this specification, in the case where a plurality of structure examples are shown in one embodiment, the structure examples can be combined as appropriate.

### Embodiment 4

In this embodiment, the semiconductor device 900 of one embodiment of the present invention will be described. The semiconductor device 900 can function as a memory device.

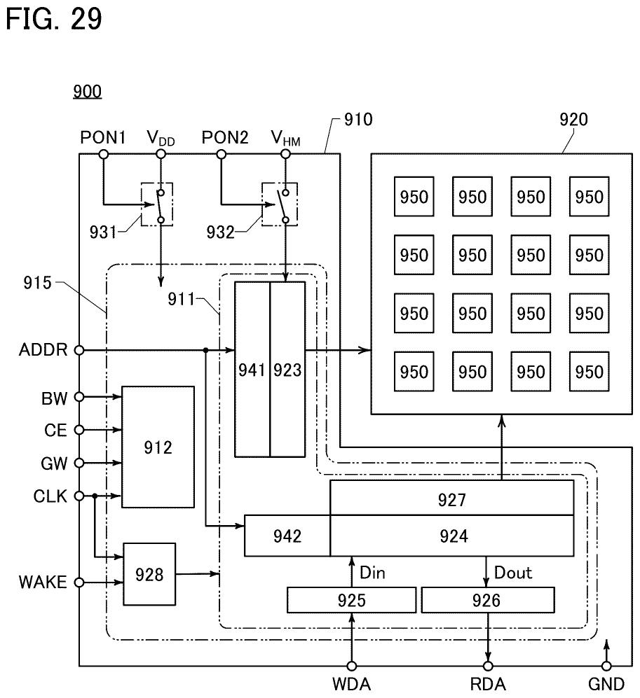

FIG. 29 is a block diagram illustrating a structure example of the semiconductor device 900. The semiconductor device 900 illustrated in FIG. 29 includes a driver circuit 910 and a memory array 920. The memory array 920 includes at least one memory cell 950. FIG. 29 illustrates an example in which the memory array 920 includes a plurality of memory cells 950 arranged in a matrix.

The memory device (e.g., the memory cell 150) described in Embodiment 3 can be used as the memory cell 950.

The driver circuit 910 includes a power switch (PSW) 931, a PSW 932, and a peripheral circuit 915. The peripheral circuit 915 includes a peripheral circuit 911, a control circuit 912, and a voltage generator circuit 928.

In the semiconductor device 900, the circuits, signals, and voltages can be appropriately selected as needed. Another circuit or another signal may be added. Signals BW, CE, GW, CLK, WAKE, ADDR, WDA, PON1, and PON2 are signals input from the outside, and a signal RDA is a signal output to the outside. The signal CLK is a clock signal.

The signals BW, CE, and GW are control signals. The signal CE is a chip enable signal. The signal GW is a global write enable signal. The signal BW is a byte write enable signal. The signal ADDR is an address signal. The signal WDA is a write data signal, and the signal RDA is a read data signal. The signals PON1 and PON2 are power gating control signals. Note that the signals PON1 and PON2 may be generated in the control circuit 912.

The control circuit 912 is a logic circuit having a function of controlling the overall operation of the semiconductor device 900. For example, the control circuit 912 performs logical operation on the signals CE, GW, and BW to determine the operating mode (e.g., writing operation or reading operation) of the semiconductor device 900. The control circuit 912 generates a control signal for the peripheral circuit 911 so that the operating mode is executed.

The voltage generator circuit 928 has a function of generating a negative voltage. The signal WAKE has a function of controlling the input of the signal CLK to the voltage generator circuit 928. For example, when an H-level signal is supplied as the signal WAKE, the signal CLK is input to the voltage generator circuit 928, and the voltage generator circuit 928 generates a negative voltage.

The peripheral circuit 911 is a circuit for writing and reading data to/from the memory cell 950. The peripheral circuit 911 includes a row decoder 941, a column decoder 942, a row driver 923, a column driver 924, an input circuit 925, an output circuit 926, and the sense amplifier 927.

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has a function of writing data to the memory cell 950, a function of reading data from the memory cell 950, and a function of retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the semiconductor device 900. The data output from the output circuit 926 is the signal RDA.

The PSW 931 has a function of controlling supply of VDD to the peripheral circuit 915. The PSW 932 has a function of controlling supply of VHM to the row driver 923. Here, in the semiconductor device 900, a high power supply potential is VDD and a low power supply potential is a ground potential (GND). In addition, VHM is a high power supply potential used for setting a word line at a high level, and is higher than VDD. The on/off state of the PSW 931 is controlled by the signal PON1, and the on/off state of the PSW 932 is controlled by the signal PON2. The number of power domains to which VDD is supplied is one in the peripheral circuit 915 in FIG. 29 but can be more than one. In that case, a power switch is provided for each power domain.

Structure examples of other memory cells each of which can be used as the memory cell 950 are described with reference to FIGS. 30A to 30H.

In the following description, the expression “two components are connected to each other” includes the case where the two components are electrically connected through a circuit element (a transistor, a switch, a diode, a resistor, or the like). The term “electrical connection” means a possibility that current flows between two components. Note that the case where two components are connected through a switch or a transistor is included as electrical connection because current can flow when the components are in an on state.

### [DOSRAM]

FIG. 30A illustrates a circuit configuration example of a memory cell for a dynamic random access memory (DRAM). In this specification and the like, a DRAM including an OS transistor is referred to as a dynamic oxide semiconductor random access memory (DOSRAM). The memory cell 951 includes the transistor M1 and the capacitor CA.

Note that the transistor M1 may include a front gate (sometimes simply referred to as a gate) and a back gate. Here, the back gate may be connected to a wiring supplied with a constant potential or a signal, and the front gate and the back gate may be connected to each other.

A first terminal of the transistor M1 is connected to a first terminal of the capacitor CA. A second terminal of the transistor M1 is connected to the wiring BIL. The gate of the transistor M1 is connected to the wiring WOL. A second terminal of the capacitor CA is connected to the wiring CAL.

The wiring BIL functions as a bit line, and the wiring WOL functions as a word line. The wiring CAL functions as a wiring for applying a predetermined potential to the second terminal of the capacitor CA. At the time of data writing and data reading, a low-level potential (sometimes referred to as a reference potential) is preferably applied to the wiring CAL.

Data writing and data reading are performed as follows: a high-level potential is applied to the wiring WOL to turn on the transistor M1 so that electrical continuity is established between the wiring BIL and the first terminal of the capacitor CA (current can flow therebetween).

The memory cell that can be used as the memory cell 950 is not limited to the memory cell 951, and the circuit configuration can be changed. For example, one wiring BIL may be provided to be shared by two or more memory cells. For another example, the configuration of a memory cell 952 illustrated in FIG. 30B may be employed. The memory cell 952 is an example including neither the capacitor CA nor the wiring CAL. The first terminal of the transistor M1 is in an electrically floating state.

In the memory cell 952, a potential written through the transistor M1 is retained in a capacitor (also referred to as parasitic capacitance) between the first terminal and the gate, which is shown by a dashed line. With such a structure, the structure of the memory cell can be greatly simplified.

Note that an OS transistor is preferably used as the transistor M1. An OS transistor has a characteristic of an extremely low off-state current. The use of an OS transistor as the transistor M1 enables an extremely low leakage current of the transistor M1. That is, with the use of the transistor M1, written data can be retained for a long time, and thus the frequency of refresh operation for the memory cell can be decreased. Alternatively, refresh operation for the memory cell can be omitted. In addition, owing to an extremely low leakage current, multilevel data or analog data can be retained in the memory cells 951 and 952.

### [NOSRAM]

FIG. 30C illustrates a circuit configuration example of a gain-cell memory cell including two transistors and one capacitor. A memory cell 953 includes the transistor M2, the transistor M3, and a capacitor CB. In this specification and the like, a memory device including a gain-cell memory cell using an OS transistor as the transistor M2 is referred to as a nonvolatile oxide semiconductor RAM (NOSRAM).

A first terminal of the transistor M2 is connected to a first terminal of the capacitor CB. A second terminal of the transistor M2 is connected to the wiring WBL. The gate of the transistor M2 is connected to the wiring WOL. A second terminal of the capacitor CB is connected to the wiring CAL. A first terminal of the transistor M3 is connected to the wiring RBL. A second terminal of the transistor M3 is connected to the wiring SL. The gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. At the time of data writing, data retention, and data reading, a low-level potential (sometimes referred to as a reference potential) is preferably applied to the wiring CAL.

Data writing is performed as follows: a high-level potential is applied to the wiring WOL to turn on the transistor M2 so that electrical continuity is established between the wiring WBL and the first terminal of the capacitor CB. Specifically, when the transistor M2 is on, a potential corresponding to data to be stored is applied to the wiring WBL, and the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. Current flowing between the source and the drain of the transistor M3 and the potential of the first terminal of the transistor M3 are determined by the potential of the gate of the transistor M3 and the potential of the second terminal of the transistor M3. Accordingly, by reading the potential of the wiring RBL connected to the first terminal of the transistor M3, a potential retained in the first terminal of the capacitor CB (or the gate of the transistor M3) can be read. That is, data written to the memory cell can be read on the basis of the potential retained in the first terminal of the capacitor CB (or the gate of the transistor M3).

For another example, one wiring BIL may be provided instead of the wiring WBL and the wiring RBL. A circuit configuration example of the memory cell is illustrated in FIG. 30D. In a memory cell 954, one wiring BIL is provided instead of the wiring WBL and the wiring RBL in the memory cell 953, and the second terminal of the transistor M2 and the first terminal of the transistor

M3 are connected to the wiring BIL. That is, one wiring BIL operates as the write bit line and the read bit line in the memory cell 954.

The memory cell 955 illustrated in FIG. 30E is an example in which the capacitor CB and the wiring CAL in the memory cell 953 are omitted. A memory cell 956 illustrated in FIG. 30F is an example in which the capacitor CB and the wiring CAL in the memory cell 954 are omitted. Such configurations enable high integration of the memory cells.

Note that an OS transistor is preferably used as at least the transistor M2. In particular, an OS transistor is preferably used as each of the transistors M2 and M3. With the use of an OS transistor as the transistor M2, written data can be retained for a long time, and thus the frequency of refresh operation for the memory cell can be decreased. Alternatively, refresh operation for the memory cell can be omitted. In addition, owing to an extremely low leakage current, multilevel data or analog data can be retained in the memory cells 953 to 956.

The memory cells 953 to 956 each using the OS transistor as the transistor M2 are embodiments of a NOSRAM.

Note that a Si transistor may be used as the transistor M3. The Si transistor can have high field-effect mobility and can be formed as a p-channel transistor, so that circuit design flexibility can be increased.

FIG. 30G illustrates a gain-cell memory cell 957 including three transistors and one capacitor. The memory cell 957 includes transistors M4 to M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL. A second terminal of the capacitor CC is connected to a first terminal of the transistor M5 and a wiring GNDL. A second terminal of the transistor M5 is connected to a first terminal of the transistor M6. A gate of the transistor M5 is connected to the first terminal of the capacitor CC. A second terminal of the transistor M6 is connected to the wiring BIL. A gate of the transistor M6 is connected to a wiring RWL.

The wiring BIL functions as a bit line. The wiring WOL functions as a write word line. The wiring RWL functions as a read word line. The wiring GNDL is a wiring for supplying a low-level potential.

Data writing is performed as follows: a high-level potential is applied to the wiring WOL to turn on the transistor M4 so that electrical continuity is established between the wiring BIL and the first terminal of the capacitor CC. Specifically, when the transistor M4 is on, a potential corresponding to data to be stored is applied to the wiring BIL, and the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed by precharging the wiring BIL with a predetermined potential, and then making the wiring BIL in an electrically floating state and applying a high-level potential to the wiring RWL. Since the wiring RWL has the high-level potential, the transistor M6 is turned on, so that electrical continuity is established between the wiring BIL and the second terminal of the transistor M5. At this time, the potential of the wiring BIL is applied to the second terminal of the transistor M5; the potential of the second terminal of the transistor M5 and the potential of the wiring BIL change depending on the potential retained in the first terminal of the capacitor CC (or the gate of the transistor M5). Here, the potential retained in the first terminal of the capacitor CC (or the gate of the transistor M5) can be read by reading the potential of the wiring BIL. That is, data written to the memory cell can be read on the basis of the potential retained in the first terminal of the capacitor CC (or the gate of the transistor M5).

Note that an OS transistor is preferably used as at least the transistor M4.

Note that Si transistors may be used as the transistors M5 and M6. As described above, a Si transistor may have higher field-effect mobility than an OS transistor depending on the crystal state of silicon used in a semiconductor layer, for example.

### [OS-SRAM]

FIG. 30H illustrates an example of a static random access memory (SRAM) including an OS transistor. In this specification and the like, an SRAM including an OS transistor is referred to as an oxide semiconductor SRAM (OS-SRAM). A memory cell 958 illustrated in FIG. 30H is a memory cell of an SRAM capable of backup operation.

The memory cell 958 includes transistors M7 to M10, transistors MS1 to MS4, a capacitor CD1, and a capacitor CD2. The transistors MS1 and MS2 are p-channel transistors, and the transistors MS3 and MS4 are n-channel transistors.

A first terminal of the transistor M7 is connected to the wiring BIL. A second terminal of the transistor M7 is connected to a first terminal of the transistor MS1, a first terminal of the transistor MS3, a gate of the transistor MS2, a gate of the transistor MS4, and a first terminal of the transistor M10. A gate of the transistor M7 is connected to the wiring WOL. A first terminal of the transistor M8 is connected to a wiring BILB. A second terminal of the transistor M8 is connected to a first terminal of the transistor MS2, a first terminal of the transistor MS4, a gate of the transistor MS1, a gate of the transistor MS3, and a first terminal of the transistor M9. A gate of the transistor M8 is connected to the wiring WOL.

A second terminal of the transistor MS1 is connected to a wiring VDL. A second terminal of the transistor MS2 is connected to the wiring VDL. A second terminal of the transistor MS3 is connected to the wiring GNDL. A second terminal of the transistor MS4 is connected to the wiring GNDL.

A second terminal of the transistor M9 is connected to a first terminal of the capacitor CD1. A gate of the transistor M9 is connected to a wiring BRL. A second terminal of the transistor M10 is connected to a first terminal of the capacitor CD2. A gate of the transistor M10 is connected to the wiring BRL.

A second terminal of the capacitor CD1 is connected to the wiring GNDL. A second terminal of the capacitor CD2 is connected to the wiring GNDL.

The wirings BIL and BILB function as bit lines. The wiring WOL functions as a word line. The wiring BRL controls the on/off states of the transistors M9 and M10.

The wiring VDL supplies a high-level potential. The wiring GNDL supplies a low-level potential.

Data writing is performed by applying a high-level potential to the wiring WOL and the wiring BRL. Specifically, when the transistor M10 is on, a potential corresponding to data to be stored is applied to the wiring BIL, and the potential is written to the second terminal side of the transistor M10.

In the memory cell 958, the transistors MS1 and MS2 form an inverter loop; hence, an inversion signal of a data signal corresponding to the potential is input to the second terminal side of the transistor M8. Since the transistor M8 is on, an inversion signal of the potential that has been applied to the wiring BIL (i.e., the signal that has been input to the wiring BIL) is output to the wiring BILB. Since the transistors M9 and M10 are on, the potential of the second terminal of the transistor M7 is retained in the first terminal of the capacitor CD2, and the potential of the second terminal of the transistor M8 is retained in the first terminal of the capacitor CD1. After that, a low-level potential is applied to the wiring WOL and the wiring BRL to turn off the transistors M7 to M10, whereby the potential of the first terminal of the capacitor CD1 and the potential of the first terminal of the capacitor CD2 are retained.

Data reading is performed as follows: the wiring BIL and the wiring BILB are precharged with a predetermined potential, and then a high-level potential is applied to the wiring WOL and the wiring BRL so that the potential of the first terminal of the capacitor CD1 is refreshed by the inverter loop in the memory cell 958 and output to the wiring BILB. Furthermore, the potential of the first terminal of the capacitor CD2 is refreshed by the inverter loop in the memory cell 958 and output to the wiring BIL. Since the potentials of the wiring BIL and the wiring BILB are changed from the precharged potentials to the potentials of the first terminal of the capacitor CD2 and the first terminal of the capacitor CD1, the potential retained in the memory cell can be read on the basis of the potentials of the wiring BIL and the wiring BILB.

Note that OS transistors are preferably used as the transistors M7 to M10. In that case, with the use of the transistors M7 to M10, written data can be retained for a long time, and thus the frequency of refresh operation for the memory cell can be decreased. Alternatively, refresh operation for the memory cell can be omitted.

Note that Si transistors may be used as the transistors MS1 to MS4.

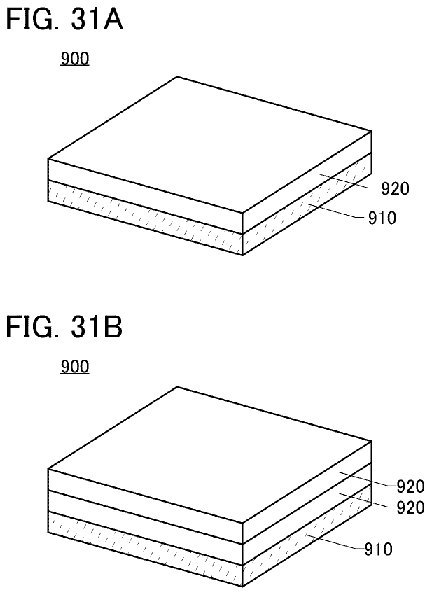

The driver circuit 910 and the memory array 920 included in the semiconductor device 900 may be provided on the same plane. Alternatively, as illustrated in FIG. 31A, the driver circuit 910 and the memory array 920 may be provided to overlap with each other. Providing the driver circuit 910 and the memory array 920 to overlap with each other can shorten a signal propagation distance. As illustrated in FIG. 31B, a plurality of memory arrays 920 may be stacked over the driver circuit 910.

Next, description is made on an example of an arithmetic processing device that can include the semiconductor device such as the memory device described above.

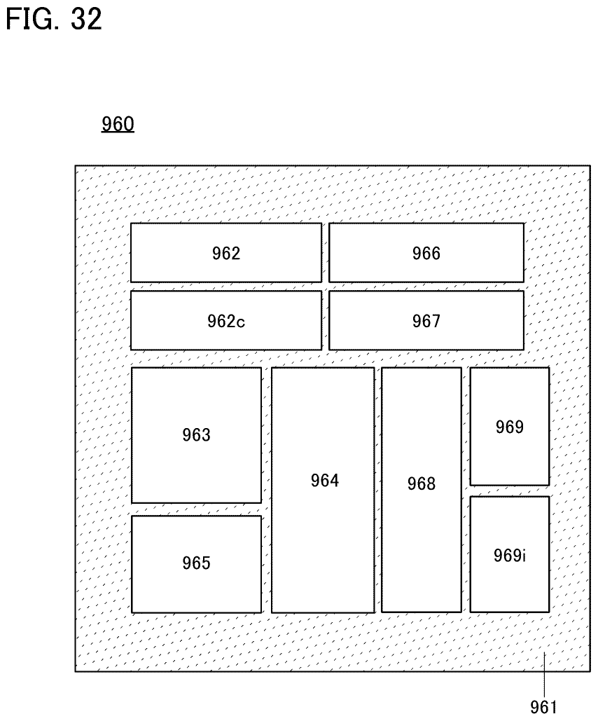

FIG. 32 is a block diagram of an arithmetic device 960. The arithmetic device 960 illustrated in FIG. 32 can be used as a CPU, for example. The arithmetic device 960 can also be used as a processor including a larger number of (several tens to several hundreds of) processor cores capable of parallel processing than a CPU, such as a graphics processing unit (GPU), a tensor processing unit

(TPU), or a neural processing unit (NPU). The arithmetic device 960 illustrated in FIG. 32 includes, over a substrate 961, an arithmetic logic unit (ALU) 962, an ALU controller 962c, an instruction decoder 963, an interrupt controller 964, a timing controller 965, a register 966, a register controller 967, a bus interface 968, a cache 969, and a cache interface 969i. A semiconductor substrate, an SOI substrate, a glass substrate, or the like is used as the substrate 961. The arithmetic device 960 may also include a rewritable ROM and a ROM interface. The cache 969 and the cache interface 969i may be provided in a separate chip.

The cache 969 is connected via the cache interface 969i to a main memory provided in another chip. The cache interface 969i has a function of supplying part of data retained in the main memory to the cache 969. The cache interface 969i also has a function of outputting part of data retained in the cache 969 to the ALU 962, the register 966, or the like through the bus interface 968.

As described later, the memory array 920 can be stacked over the arithmetic device 960. The memory array 920 can be used as a cache. Here, the cache interface 969i may have a function of supplying data retained in the memory array 920 to the cache 969. Moreover, in that case, the driver circuit 910 is preferably included in part of the cache interface 969i.

Note that it is also possible that the cache 969 is not provided and only the memory array 920 is used as a cache.

The arithmetic device 960 illustrated in FIG. 32 is just an example with a simplified structure, and the actual arithmetic device 960 has a variety of structures depending on the application. For example, what is called a multicore structure is preferably employed in which a plurality of cores each including the arithmetic device 960 in FIG. 32 operate in parallel. The larger number of cores can further enhance the arithmetic performance. The number of cores is preferably larger; for example, the number is preferably 2, further preferably 4, still further preferably 8, yet further preferably 12, yet still further preferably 16 or larger. For application requiring extremely high arithmetic performance, e.g., a server, it is preferable to employ the multicore structure including 16 or more, preferably 32 or more, further preferably 64 or more cores. The number of bits that the arithmetic device 960 can handle with an internal arithmetic circuit, a data bus, or the like can be 8, 16, 32, or 64, for example.

An instruction input to the arithmetic device 960 through the bus interface 968 is input to the instruction decoder 963 and decoded, and then input to the ALU controller 962c, the interrupt controller 964, the register controller 967, and the timing controller 965.

The ALU controller 962c, the interrupt controller 964, the register controller 967, and the timing controller 965 conduct various controls in accordance with the decoded instruction. Specifically, the ALU controller 962c generates signals for controlling the operation of the ALU 962. The interrupt controller 964 judges and processes an interrupt request from an external input/output device, a peripheral circuit, or the like on the basis of its priority, a mask state, or the like while the arithmetic device 960 is executing a program. The register controller 967 generates the address of the register 966, and reads/writes data from/to the register 966 in accordance with the state of the arithmetic device 960.

The timing controller 965 generates signals for controlling operation timings of the ALU 962, the ALU controller 962c, the instruction decoder 963, the interrupt controller 964, and the register controller 967. For example, the timing controller 965 includes an internal clock generator for generating an internal clock signal on the basis of a reference clock signal, and supplies the internal clock signal to the above circuits.

In the arithmetic device 960 illustrated in FIG. 32, the register controller 967 selects operation of retaining data in the register 966 in accordance with an instruction from the ALU 962. That is, the register controller 967 selects whether data is retained by a flip-flop or by a capacitor in a memory cell included in the register 966. When data retention by the flip-flop is selected, a power supply potential is supplied to the memory cell in the register 966. When data retention by the capacitor is selected, the data is rewritten into the capacitor, and supply of the power supply potential to the memory cell in the register 966 can be stopped.

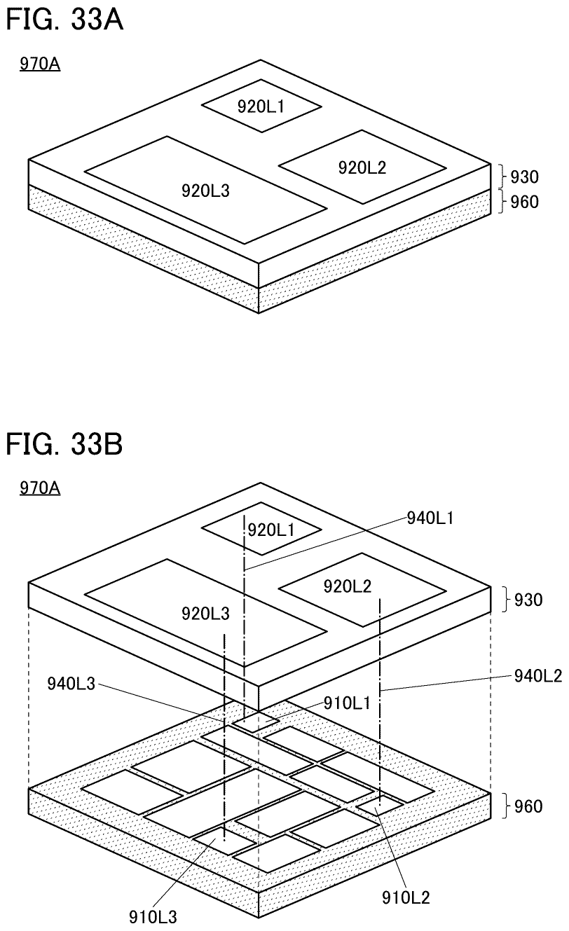

The memory array 920 and the arithmetic device 960 can be provided to overlap with each other. FIGS. 33A and 33B are perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 and each of the memory arrays overlap with each other. For easy understanding of the structure of the semiconductor device 970A, the arithmetic device 960 and the layer 930 are separately illustrated in FIG. 33B.

Providing the arithmetic device 960 and the layer 930 including the memory arrays to overlap with each other can shorten the connection distance therebetween. Accordingly, the communication speed therebetween can be increased. Moreover, a short connection distance leads to lower power consumption.

As a method for stacking the arithmetic device 960 and the layer 930 including the memory arrays, either of the following methods may be employed: a method in which the layer 930 including the memory arrays is stacked directly on the arithmetic device 960, which is also referred to as monolithic stacking, and a method in which the arithmetic device 960 and the layer 930 are formed over two different substrates, the substrates are bonded to each other, and the arithmetic device 960 and the layer 930 are connected to each other with a through via or by a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 969 and the memory arrays 920L1, 920L2, and 920L3 provided in the layer 930 are each used as a cache. In that case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the highest capacity and the lowest access frequency. The memory array 920L1 has the lowest capacity and the highest access frequency.

Note that in the case where the cache 969 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 33B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Although the case where three memory arrays function as caches is described here, the number of memory arrays may be one, two, or four or more.

In the case where the memory array 920L1 is used as a cache, the driver circuit 910L1 may function as part of the cache interface 969i or the driver circuit 910L1 may be connected to the cache interface 969i. Similarly, each of the driver circuits 910L2 and 910L3 may function as part of the cache interface 969i or be connected thereto.

Whether the memory array 920 functions as the cache or the main memory is determined by the control circuit 912 included in each of the driver circuits 910. The control circuit 912 can make some of the memory cells 950 in the semiconductor device 900 function as RAM in accordance with a signal supplied from the arithmetic device 960.

In the semiconductor device 900, some of the memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

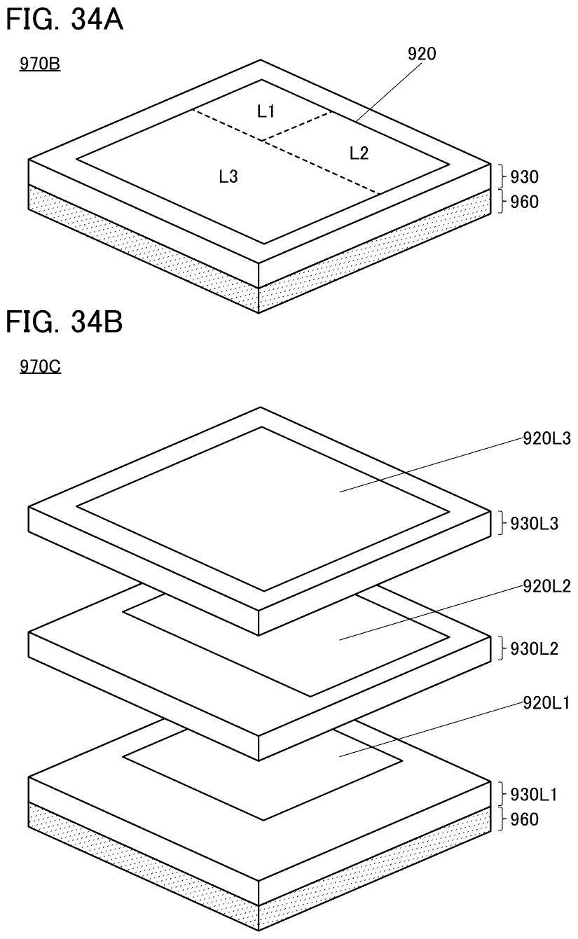

The layer 930 including one memory array 920 may be provided to overlap with the arithmetic device 960. FIG. 34A is a perspective view of a semiconductor device 970B.

In the semiconductor device 970B, one memory array 920 can be divided into a plurality of areas having different functions. FIG. 34A illustrates an example in which a region L1, a region L2, and a region L3 are used as the L1 cache, the L2 cache, and the L3 cache, respectively.

In the semiconductor device 970B, the capacity of each of the regions LI to L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 34B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

This embodiment can be combined with any of the other embodiments and examples as appropriate. In this specification, in the case where a plurality of structure examples are shown in one embodiment, the structure examples can be combined as appropriate.

### Embodiment 5

In this embodiment, a configuration example of a CMOS circuit including an OS transistor of one embodiment of the present invention and a Si transistor will be described.

The Si transistor has higher field-effect mobility and higher operating speed than the OS transistor. The OS transistor has a much lower off-state current than the Si transistor. In particular, the OS transistor containing indium oxide in its semiconductor layer where a channel is formed can have an extremely low off-state current and high field-effect mobility comparable to that of the Si transistor. Using the OS transistor and the Si transistor in combination enables a CMOS circuit that consumes low power and can operate at high speed.

In this embodiment, configuration examples of a NOT circuit, a NOR circuit, and a NAND circuit, which are logic circuits, will be described as examples of a circuit including the Si transistor and the OS transistor. In addition, configuration examples of a delay flip-flop (DFF) circuit and a shift register circuit including a DFF circuit will be described. [NOT circuit]

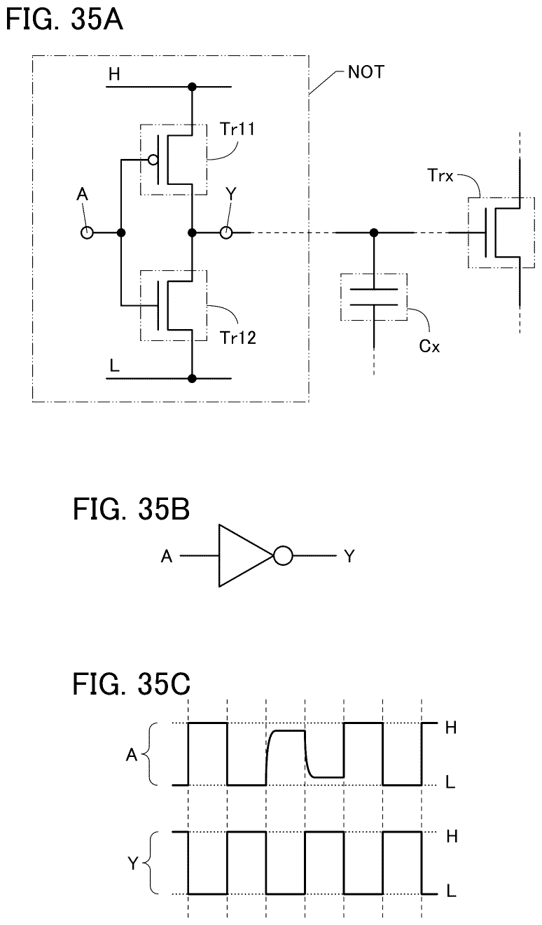

FIG. 35A is a circuit diagram illustrating a configuration example of a NOT circuit (NOT). The NOT circuit is also referred to as an inverting circuit, an inverter circuit, or the like. FIG. 35B illustrates a circuit symbol of the NOT circuit. FIG. 35C is a timing chart showing the operation of the NOT circuit.

The NOT circuit illustrated in FIG. 35A includes a transistor Tr11 and a transistor Tr12. The Si transistor functioning as a p-channel transistor is used as the transistor Tr11, and the OS transistor functioning as an n-channel transistor is used as the transistor Tr12. A potential H (e.g., a high power supply potential VDD) is supplied to one of a source and a drain of the transistor Tr11. The other of the source and the drain of the transistor Tr11 is connected to one of a source and a drain of the transistor Tr12 and a terminal Y. A potential L (e.g., a low power supply potential VSS) is supplied to the other of the source and the drain of the transistor Tr12. A gate of the transistor Tr11 and a gate of the transistor Tr12 are connected to a terminal A.

In the NOT circuit illustrated in FIG. 35A, the terminal A functions as an input terminal, and the terminal Y functions as an output terminal. In the NOT circuit, the potential L is output from the terminal Y when the potential H is input to the terminal A, and the potential H is output from the terminal Y when the potential L is input to the terminal A (see FIG. 35C).

As shown in FIG. 35C, the NOT circuit has a function of correcting an input signal that is distorted due to wiring resistance, parasitic capacitance, noise, or the like into a signal that is not distorted or less distorted, and outputting the corrected signal. The NOT circuit also has a function of amplifying the voltage amplitude of an input signal and outputting the signal. The output from the NOT circuit is supplied to a load such as a capacitor Cx or a transistor Trx.

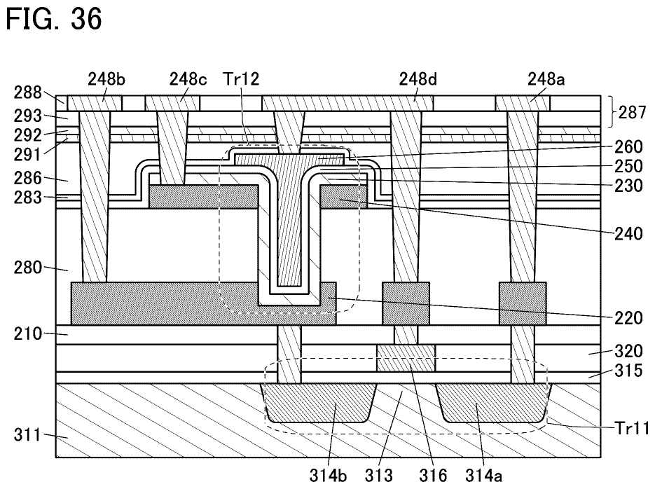

An example of a structure of the NOT circuit is described here with reference to FIG. 36. As illustrated in FIG. 36, the transistor Tr12 is provided above the transistor Tr11. The insulating layer 283, the insulating layer 286, an insulating layer 291, and an insulating layer 292 are stacked in this order over the transistor Tr12, and a wiring region 287 is provided over the insulating layer 292. The wiring region 287 includes an insulating layer 293 over the insulating layer 292, and an insulating layer 288 and conductive layers 248a to 248d over the insulating layer 293. The conductive layers 248a to 248d are embedded in the insulating layer 288.

The transistor Tr11 is a modification example of the transistor 300 illustrated in FIG. 28 and has what is called a planar structure. The components of the transistor Tr11 that are the same as those of the transistor 300 illustrated in FIG. 28 are denoted by the same reference numerals as those of the transistor 300. For the details of the transistor Tr11, the description of the transistor 300 can be referred to.

The description of the transistor 200 in Embodiment 2 (the transistor 200A illustrated in FIG. 4A) can be referred to for the transistor Tr12; thus, the detailed description thereof is omitted.

The low-resistance region 314a functions as one of the source and the drain of the transistor Tr11 and is connected to the conductive layer 248a provided in the wiring region 287 through one or more conductive layers functioning as plugs or wirings. The potential H is supplied to the conductive layer 248a.

The low-resistance region 314b functions as the other of the source and the drain of the transistor Tr11 and is connected to the conductive layer 220 functioning as one of the source and the drain of the transistor Tr12. The conductive layer 220 is connected to the conductive layer 248b provided in the wiring region 287 through one or more conductive layers functioning as plugs or wirings. The conductive layer 248b functions as the terminal Y.

The conductive layer 240 functions as the other of the source and the drain of the transistor Tr12 and is connected to the conductive layer 248c provided in the wiring region 287 through one or more conductive layers functioning as plugs or wirings. The potential L is supplied to the conductive layer 248c.

The conductive layer 316 functions as a gate electrode of the transistor Tr11 and is connected to the conductive layer 248d provided in the wiring region 287 through one or more conductive layers functioning as plugs or wirings. The conductive layer 260 functions as a gate electrode of the transistor Tr12 and is connected to the conductive layer 248d through one or more conductive layers functioning as plugs or wirings. The conductive layer 248d functions as the terminal A.

When all the transistors Tr11 formed over the substrate 311 are p-channel transistors and all the transistors Tr12 formed thereover are n-channel transistors to form the NOT circuit, a complicated step such as formation of an element isolation layer can be simplified, so that the productivity of a semiconductor device including the circuit can be improved.

[NOR circuit]

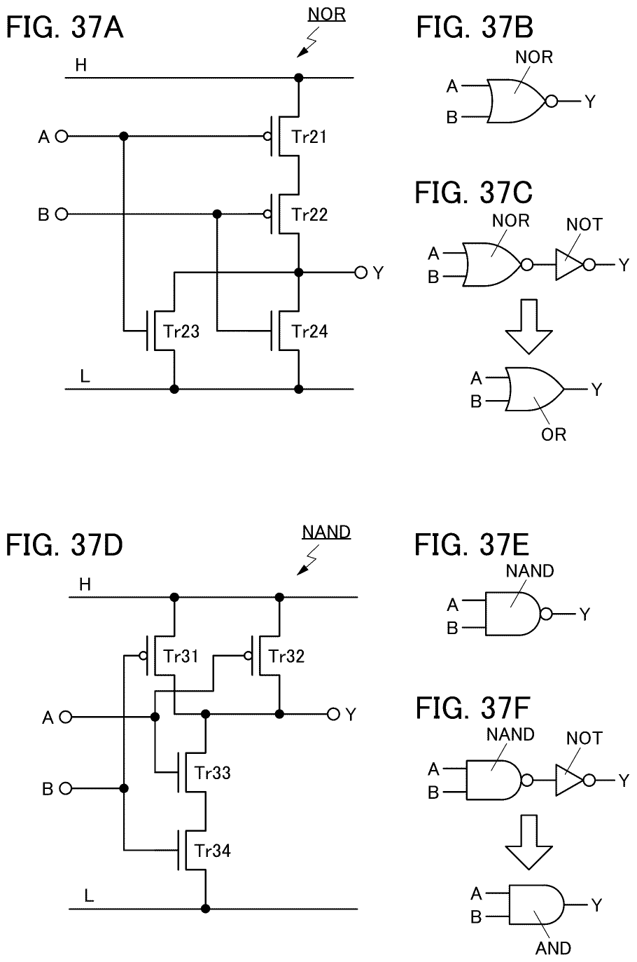

FIG. 37A is a circuit diagram illustrating a configuration example of a two-input and one-output NOR circuit (NOR). FIG. 37B illustrates a circuit symbol of the NOR circuit. The NOR circuit illustrated in FIG. 37A includes a transistor Tr21, a transistor Tr22, a transistor Tr23, and a transistor Tr24. Si transistors functioning as p-channel transistors can be used as the transistors Tr21 and Tr22, and OS transistors functioning as n-channel transistors can be used as the transistors Tr23 and Tr24.

In FIG. 37A, the potential H is supplied to one of a source and a drain of the transistor Tr21. The other of the source and the drain of the transistor Tr21 is connected to one of a source and a drain of the transistor Tr22. The other of the source and the drain of the transistor Tr22 is connected to one of a source and a drain of the transistor Tr23, one of a source and a drain of the transistor Tr24, and the terminal Y. The potential L is supplied to the other of the source and the drain of the transistor Tr23 and the other of the source and the drain of the transistor Tr24.

A gate of the transistor Tr21 is connected to a gate of the transistor Tr23 and the terminal A. A gate of the transistor Tr22 is connected to a gate of the transistor Tr24 and a terminal B.

The NOR circuit illustrated in FIGS. 37A and 37B has a function of outputting the potential H from the terminal Y when the potential L is input to both the terminal A and the terminal B. The NOR circuit also has a function of outputting the potential L from the terminal Y when the potential H is input to one or both of the terminal A and the terminal B.

As illustrated in FIG. 37C, an OR circuit can be obtained when the input of the NOT circuit is connected to the output of the NOR circuit.

[NAND circuit]

FIG. 37D is a circuit diagram illustrating a configuration example of a two-input and one-output NAND circuit (NAND). FIG. 37E illustrates a circuit symbol of the NAND circuit. The NAND circuit illustrated in FIG. 37D includes a transistor Tr31, a transistor Tr32, a transistor Tr33, and a transistor Tr34. Si transistors functioning as p-channel transistors can be used as the transistors Tr31 and Tr32, and OS transistors functioning as n-channel transistors can be used as the transistors Tr33 and Tr34.

In FIG. 37D, the potential H is supplied to one of a source and a drain of the transistor Tr31 and one of a source and a drain of the transistor Tr32. The other of the source and the drain of the transistor Tr31 and the other of the source and the drain of the transistor Tr32 are connected to one of a source and a drain of the transistor Tr33 and the terminal Y. The other of the source and the drain of the transistor Tr33 is connected to one of a source and a drain of the transistor Tr34. The potential L is supplied to the other of the source and the drain of the transistor Tr34.

A gate of the transistor Tr31 is connected to a gate of the transistor Tr34 and the terminal B. A gate of the transistor Tr32 is connected to a gate of the transistor Tr33 and the terminal A.

The NAND circuit illustrated in FIGS. 37D and 37E has a function of outputting the potential L from the terminal Y when the potential H is input to both the terminal A and the terminal B. The NAND circuit also has a function of outputting the potential H from the terminal Y when the potential L is input to one or both of the terminal A and the terminal B.

As illustrated in FIG. 37F, an AND circuit can be obtained when the NAND circuit is combined with the NOT circuit.

### [DFF Circuit]

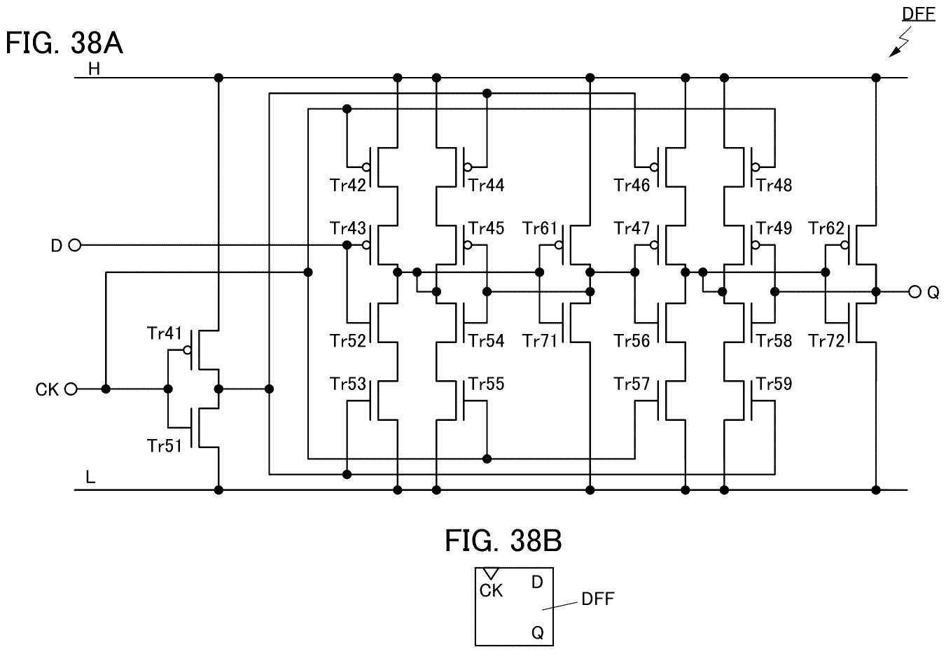

FIG. 38A is a circuit diagram illustrating a configuration example of a D flip-flop (DFF) circuit. FIG. 38B illustrates a circuit symbol of the D flip-flop circuit. The DFF includes a clock signal input terminal CK, an input terminal D, and an output terminal Q.

The D flip-flop circuit illustrated in FIG. 38A includes transistors Tr41 to Tr49, transistors Tr51 to Tr59, a transistor Tr61, a transistor Tr62, a transistor Tr71, and a transistor Tr72. Si transistors functioning as p-channel transistors can be used as the transistors Tr41 to Tr49 and the transistors Tr61 and Tr62, and OS transistors functioning as n-channel transistors can be used as the transistors Tr51 to Tr59 and the transistors Tr71 and Tr72.

The potential H is supplied to one of a source and a drain of the transistor Tr41, one of a source and a drain of the transistor Tr42, one of a source and a drain of the transistor Tr44, one of a source and a drain of the transistor Tr46, one of a source and a drain of the transistor Tr48, one of a source and a drain of the transistor Tr61, and one of a source and a drain of the transistor Tr62.

The other of the source and the drain of the transistor Tr41 is connected to one of a source and a drain of the transistor Tr51, a gate of the transistor Tr44, a gate of the transistor Tr46, a gate of the transistor Tr53, and a gate of the transistor Tr59. A gate of the transistor Tr41 is connected to the clock signal input terminal CK, a gate of the transistor Tr51, a gate of the transistor Tr42, a gate of the transistor Tr48, a gate of the transistor Tr55, and a gate of the transistor Tr57.

The other of the source and the drain of the transistor Tr42 is connected to one of a source and a drain of the transistor Tr43. The other of the source and the drain of the transistor Tr44 is connected to one of a source and a drain of the transistor Tr45. The other of the source and the drain of the transistor Tr43 is connected to the other of the source and the drain of the transistor Tr45, one of a source and a drain of the transistor Tr52, one of a source and a drain of the transistor Tr54, a gate of the transistor Tr61, and a gate of the transistor Tr71. A gate of the transistor Tr43 is connected to a gate of the transistor Tr52 and the input terminal D.

The other of the source and the drain of the transistor Tr52 is connected to one of a source and a drain of the transistor Tr53. The other of the source and the drain of the transistor Tr54 is connected to one of a source and a drain of the transistor Tr55. A gate of the transistor Tr45 is connected to a gate of the transistor Tr54, the other of the source and the drain of the transistor Tr61, one of a source and a drain of the transistor Tr71, a gate of the transistor Tr47, and a gate of the transistor Tr56. The other of the source and the drain of the transistor Tr46 is connected to one of a source and a drain of the transistor Tr47. The other of the source and the drain of the transistor Tr48 is connected to one of a source and a drain of the transistor Tr49.

The other of the source and the drain of the transistor Tr47 is connected to one of a source and a drain of the transistor Tr56, the other of the source and the drain of the transistor Tr49, one of a source and a drain of the transistor Tr58, a gate of the transistor Tr62, and a gate of the transistor Tr72. The other of the source and the drain of the transistor Tr62 is connected to one of a source and a drain of the transistor Tr72, a gate of the transistor Tr49, a gate of the transistor Tr58, and the output terminal Q.

The other of the source and the drain of the transistor Tr56 is connected to one of a source and a drain of the transistor Tr57. The other of the source and the drain of the transistor Tr58 is connected to one of a source and a drain of the transistor Tr59. The potential L is supplied to the other of the source and the drain of the transistor Tr51, the other of the source and the drain of the transistor Tr53, the other of the source and the drain of the transistor Tr55, the other of the source and the drain of the transistor Tr71, the other of the source and the drain of the transistor Tr57, the other of the source and the drain of the transistor Tr59, and the other of the source and the drain of the transistor Tr72.

Data (a potential) that has been supplied to the input terminal D is written to the DFF illustrated in FIGS. 38A and 38B while the potential H is being input to the clock signal input terminal CK. When the signal input to the clock signal input terminal CK changes from the potential H to the potential L, the DFF has a function of retaining the data until the next input of the potential H to the clock signal input terminal CK. The signal (the potential H or the potential L) based on the data retained in the DFF is constantly output from the output terminal Q.

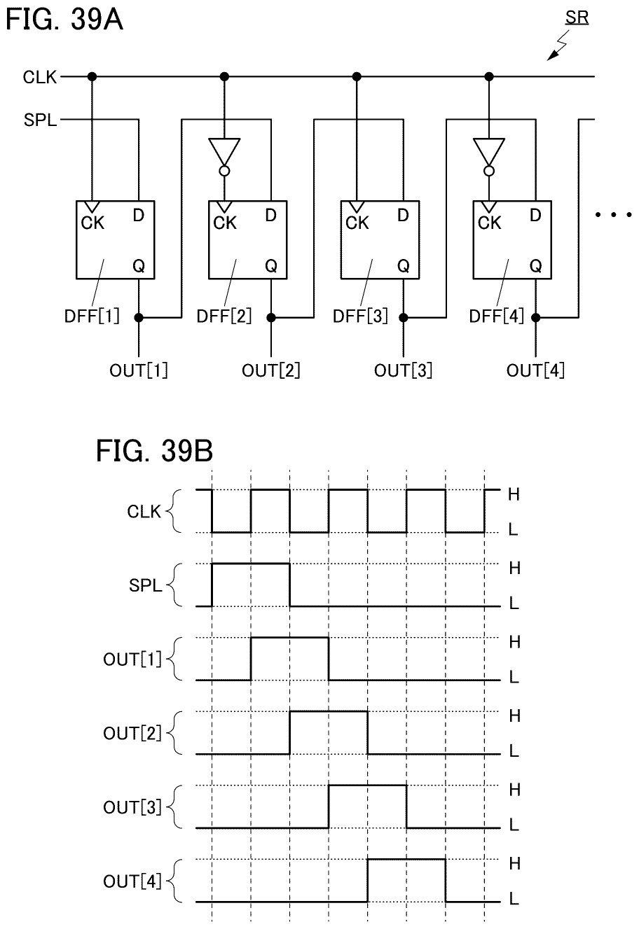

FIG. 39A is a block diagram illustrating a configuration example of a shift register circuit (SR). The SR includes a plurality of DFFs. In this specification and the like, the DFF in the first stage (the first DFF) is denoted by “DFF [1]”, and a potential (data) output from the output terminal Q of the DFF [1] is denoted by “data OUT [1]”. FIG. 39A is a block diagram of the SR including four stages of DFFs (four DFFs [1] to [4]). In FIG. 39A, data output from the output terminals Q of the DFFs [1] to [4] are denoted by data OUT [1] to OUT [4], respectively.

FIG. 39B is a timing chart showing the operation of the SR. Signals CLK, which are clock signals, are input to the clock signal input terminals CK of the DFFs in the odd-numbered stages. Inverted signals of the signals CLK are input to the clock signal input terminals CK of the DFFs in the even-numbered stages.

A signal SPL, which is a pulse signal, is input to the input terminal D of the DFF [1]. The DFF [1] retains a signal corresponding to the signal SPL input in synchronization with the signal CLK and outputs the signal as the data OUT [1]. Note that the data OUT [1] is a value corresponding to the data retained in the DFF [1].

The data OUT [1] is input to the input terminal D of the DFF [2]. The DFF [2] retains a signal corresponding to the data OUT [1] input in synchronization with the signal CLK and outputs the signal as the data OUT [2]. Similarly, the data OUT [2] is input to the input terminal D of the DFF [3], and the data OUT [3] is input to the input terminal D of the DFF [4].

As described above, the SR has a function of sequentially transferring the input signals SPL in synchronization with the signals CLK to the DFFs in the subsequent stages. The SR also has a function of sequentially switching the potentials of the data OUT output from the plurality of DFFs in synchronization with the signals CLK.

The Si transistor and the OS transistor are preferably provided to overlap with each other. When the Si transistor and the OS transistor are provided to overlap with each other, a circuit that occupies a small area can be obtained. In addition, the OS transistor operates stably in a high-temperature environment and has small fluctuation in characteristics. Thus, the OS transistor is unlikely to be affected by heat generation of the Si transistor and can operate stably. When the Si transistor and the OS transistor are provided to overlap with each other, the connection distance between them can be extremely short. As a result, the wiring resistance and the parasitic capacitance can be reduced, so that the circuit can be driven at high speed. In addition, the power consumption of the circuit is reduced.

At least part of this embodiment can be implemented as appropriate in combination with any of the other embodiments described in this specification.

### Embodiment 6

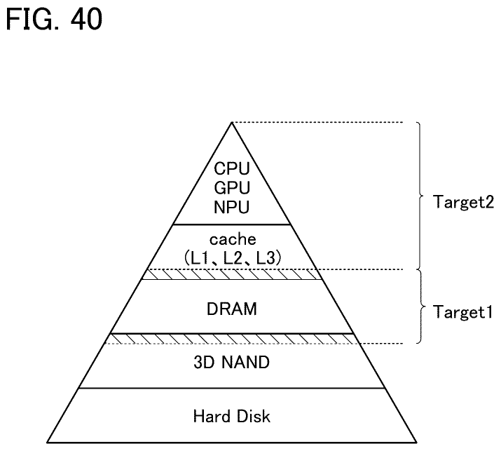

In this embodiment, an example of an application range of a semiconductor device of one embodiment of the present invention will be described with reference to FIG. 40.

A variety of memory devices are used in semiconductor devices such as computers in accordance with the intended use. FIG. 40 is a conceptual diagram showing a hierarchy of memory devices used in semiconductor devices. In the conceptual diagram in FIG. 40, the hierarchy of memory devices is shown by a triangle; the memory devices at higher levels in the triangle require higher operating speed, and the memory devices at lower levels in the triangle require higher memory capacity and higher recording density.

In FIG. 40, memories included as registers in arithmetic processing devices such as a CPU, a GPU, and an NPU, cache memories (sometimes simply referred to as caches, typically L1, L2, and L3 caches), main memories typified by DRAMs, 3D NANDs, and storage memories typified by hard disks (also referred to as hard disk drives (HDDs)) are shown in this order from the highest level in the triangle.

A memory included as a register in an arithmetic processing device such as a CPU, a GPU, or an NPU is used for temporary storage of arithmetic operation results, for example, and thus is very frequently accessed by the arithmetic processing device. Accordingly, high operating speed is required rather than high memory capacity. The register also has a function of retaining settings of the arithmetic processing device, for example.

The cache memory has a function of duplicating and retaining part of data retained in the DRAM. Duplicating frequently used data and retaining the duplicated data in the cache memory facilitate rapid data access. The cache memory requires lower memory capacity but requires higher operating speed than the DRAM. Data that is rewritten in the cache memory is duplicated, and the duplicated data is supplied to the DRAM. Only L1 to L3 caches are shown as the cache memories in the example illustrated in FIG. 40, but one embodiment of the present invention is not limited to the example. For example, a memory device including an oxide semiconductor of one embodiment of the present invention can be suitably used as the last level cache (LLC) or a final level cache (FLC) positioned at the lowest level among the caches.

The DRAM has a function of retaining a program, data, or the like read from the 3D NAND.

The 3D NAND has a function of retaining data that needs to be stored for a long time, a variety of programs used in an arithmetic device (e.g., a model of an artificial neural network), and the like. Therefore, the 3D NAND requires high memory capacity and high recording density rather than high operating speed.

The hard disk has high capacity and a nonvolatile function. Instead of the hard disk, a solid state drive (SSD) or the like can be used.

The memory device including the oxide semiconductor (OS memory) of one embodiment of the present invention can retain data for a long time. Thus, the memory device is suitable for devices in a region denoted as Target 1 in FIG. 40. As indicated by hatching with oblique lines in FIG. 40, Target 1 also includes part of the caches (L1, L2, and L3) and part of the 3D NAND. In other words, Target 1 includes a boundary region between the DRAM and the 3D NAND and a boundary region between the DRAM and the caches (L1, L2, and L3). The memory device including the oxide semiconductor of one embodiment of the present invention operates at high speed, and thus can achieve excellent writing operation and excellent reading operation. Thus, the memory device is suitable for a region denoted as Target 2 in FIG. 40.

For example, the DRAM shown in FIG. 40 is suitably replaced with the memory device including the oxide semiconductor of one embodiment of the present invention. Refresh operation is essential for the DRAM, and the DRAM is a destructive read memory device and thus consumes higher power than other memory devices. Therefore, power consumption can be reduced with a structure not using the DRAM. With this structure, power consumption can be reduced to one-hundredth or less or one-thousandth or less that of a structure using the DRAM. Thus, global expansion of information processing devices, such as supercomputers (also referred to as high performance computers (HPCs)), computers, and servers, having such a structure will lead to global warming mitigation.

As described above, the memory device including the oxide semiconductor of one embodiment of the present invention can be used in a wide range of memories covering from a memory included as a register in an arithmetic processing device such as a CPU, a GPU, or an NPU to a memory in the boundary region between a DRAM and a 3D NAND.

This embodiment can be combined with any of the other embodiments as appropriate. In this specification, in the case where a plurality of structure examples are shown in one embodiment, the structure examples can be combined as appropriate.

### Embodiment 7

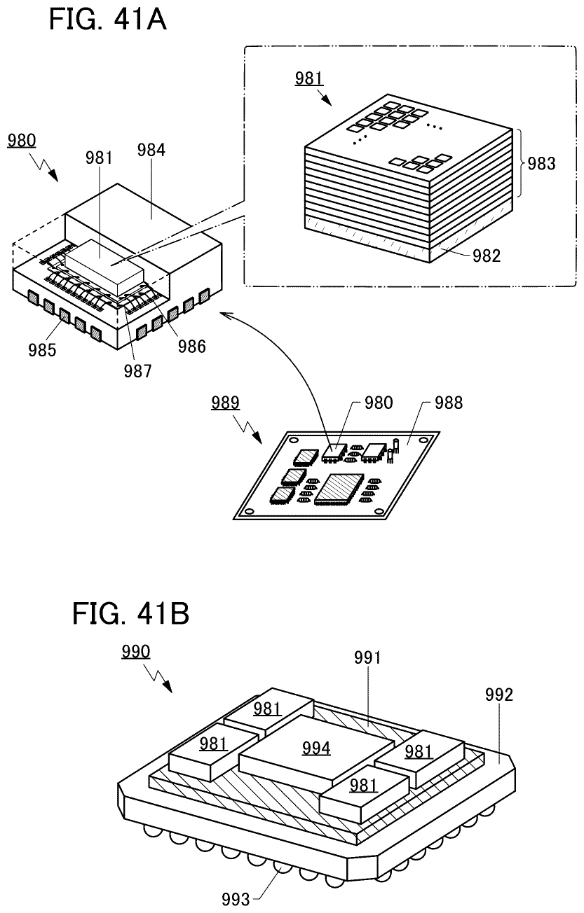

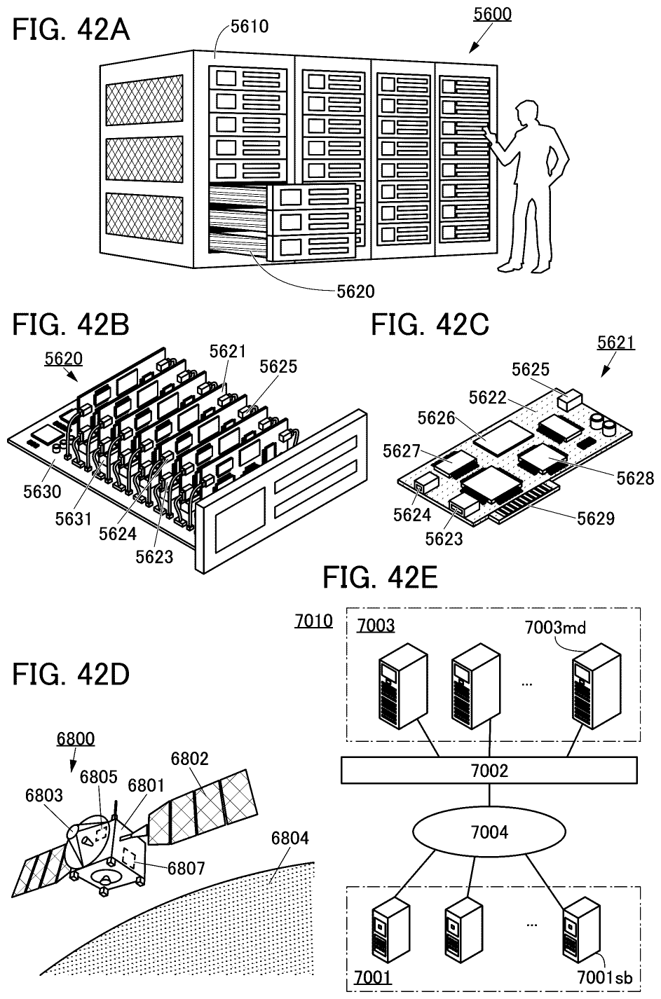

In this embodiment, application examples of the semiconductor device of one embodiment of the present invention will be described with reference to FIGS. 41A and 41B and FIGS. 42A to 42E.

The semiconductor device of one embodiment of the present invention can be used for an electronic component, a large computer, space equipment, a data center (also referred to as DC), and a variety of electronic devices, for example. With the use of the semiconductor device of one embodiment of the present invention, an electronic component, a large computer, space equipment, a data center, and a variety of electronic devices can have lower power consumption and higher performance.

A display device including the semiconductor device of one embodiment of the present invention can be used for a display portion of any of a variety of electronic devices. The display device including the semiconductor device of one embodiment of the present invention can be easily increased in resolution and definition.

Examples of the electronic devices include a digital camera, a digital video camera, a digital photo frame, a mobile phone, a portable game machine, a portable information terminal, and an audio reproducing device, in addition to electronic devices with a relatively large screen, such as a television device, desktop and laptop computers, a monitor of a computer and the like, digital signage, and a large game machine such as a pachinko machine.

In particular, the display device of one embodiment of the present invention can have a high resolution, and thus is suitable for an electronic device having a relatively small display portion. Examples of such an electronic device include watch-type and bracelet-type information terminal devices (wearable devices) and wearable devices that can be worn on the head, such as a VR device like a head-mounted display, a glasses-type AR device, and a mixed reality (MR) device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680 ×4320). In particular, a definition of 4K, 8K, or higher is preferable. The pixel density (resolution) of the display device of one embodiment of the present invention is preferably higher than or equal to 100 ppi, further preferably higher than or equal to 300 ppi, still further preferably higher than or equal to 500 ppi, yet further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of the display device having one or both of such a high definition and a high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, an electric field, current, voltage, electric power, radiation, a flow rate, humidity, gradient, oscillation, a smell, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

### [Electronic Component]

FIG. 41A is a perspective view of a substrate (a circuit board 989) provided with an electronic component 980. The electronic component 980 illustrated in FIG. 41A includes a semiconductor device 981 in a mold 984. FIG. 41A omits some components to show the inside of the electronic component 980. The electronic component 980 includes a land 985 outside the mold 984. The land 985 is electrically connected to an electrode pad 986, and the electrode pad 986 is electrically connected to the semiconductor device 981 through a wire 987. The electronic component 980 is mounted on a printed circuit board 988, for example. A plurality of such electronic components are combined and electrically connected to each other on the printed circuit board 988, which forms the circuit board 989.

The semiconductor device 981 includes a driver circuit layer 982 and a memory layer 983. The memory layer 983 has a structure in which a plurality of memory cell arrays are stacked. A stacked-layer structure of the driver circuit layer 982 and the memory layer 983 can be a monolithic stacked-layer structure. In the monolithic stacked-layer structure, layers can be connected to each other without using a through electrode technique such as a through silicon via (TSV) technique and a bonding technique such as Cu—Cu direct bonding. Monolithically stacking the driver circuit layer 982 and the memory layer 983 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is used, which means that the number of connection pins can be increased. The increase in the number of connection pins enables parallel operations, which can improve the bandwidth of the memory (also referred to as a memory bandwidth).

It is preferable that the plurality of memory cell arrays included in the memory layer 983 be formed with OS transistors and be monolithically stacked. Monolithically stacking the plurality of memory cell arrays can improve one or both of a memory bandwidth and a memory access latency. Note that the bandwidth refers to the data transfer volume per unit time, and the access latency refers to a period of time from data access to the start of data transmission. In the case where the memory layer 983 is formed with Si transistors, the monolithic stacked-layer structure is difficult to form as compared with the case where the memory layer 983 is formed with OS transistors. Thus, an OS transistor is superior to a Si transistor in the monolithic stacked-layer structure.

The semiconductor device 981 may be called a die. In this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

FIG. 41B is a perspective view of an electronic component 990. The electronic component 990 is an example of a system in package (SiP) or a multi-chip module (MCM). In the electronic component 990, an interposer 991 is provided over a package substrate 992 (printed circuit board), and a semiconductor device 994 and a plurality of semiconductor devices 981 are provided over the interposer 991.

The electronic component 990 using the semiconductor device 981 as a high bandwidth memory (HBM) is illustrated as an example. The semiconductor device 994 can be used for an integrated circuit such as a CPU, a GPU, or a field programmable gate array (FPGA).

As the package substrate 992, a ceramic substrate, a plastic substrate, or a glass epoxy substrate can be used, for example. As the interposer 991, a silicon interposer or a resin interposer can be used, for example.

The interposer 991 includes a plurality of wirings and has a function of connecting a plurality of integrated circuits with different terminal pitches. The plurality of wirings are provided in a single layer or multiple layers. In addition, the interposer 991 has a function of connecting an integrated circuit provided on the interposer 991 to an electrode provided on the package substrate 992. Accordingly, the interposer is referred to as a “redistribution substrate” or an “intermediate substrate” in some cases. Furthermore, a through electrode is provided in the interposer 991 and the through electrode is used to connect an integrated circuit and the package substrate 992 in some cases. Moreover, in the case of using a silicon interposer, a TSV can also be used as the through electrode.

An HBM needs to be connected to many wirings to achieve a wide memory bandwidth. Thus, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is unlikely to occur. Furthermore, a surface of a silicon interposer has high planarity; thus, poor connection between the silicon interposer and an integrated circuit provided on the silicon interposer is unlikely to occur. It is particularly preferable to use a silicon interposer for a 2.5D package (2.5-dimensional mounting) in which a plurality of integrated circuits are arranged side by side on the interposer.

In the case where a plurality of integrated circuits with different terminal pitches are connected with use of a silicon interposer, a TSV, and the like, a space for a width of the terminal pitch and the like is needed. Accordingly, in the case where the size of the electronic component 990 is to be reduced, the width of the terminal pitch becomes an issue, which sometimes makes it difficult to provide a large number of wirings for obtaining a wide memory bandwidth. For this reason, the above-described monolithic stacked-layer structure with use of OS transistors is suitable. A composite structure combining memory cell arrays stacked using a TSV and monolithically stacked memory cell arrays may be employed.

A heat sink (a radiator plate) may be provided to overlap with the electronic component 990. In the case of providing a heat sink, the heights of integrated circuits provided on the interposer 991 are preferably equal to each other. For example, in the electronic component 990 described in this embodiment, the heights of the semiconductor devices 981 and the semiconductor device 994 are preferably equal to each other.

To mount the electronic component 990 on another substrate, an electrode 993 may be provided on a bottom portion of the package substrate 992. FIG. 41B illustrates an example in which the electrode 993 is formed of a solder ball. Solder balls are provided in a matrix on the bottom portion of the package substrate 992, so that ball grid array (BGA) mounting can be achieved. Alternatively, the electrode 993 may be formed of a conductive pin. When conductive pins are provided in a matrix on the bottom portion of the package substrate 992, pin grid array (PGA) mounting can be achieved.

The electronic component 990 can be mounted on another substrate by various mounting methods other than BGA and PGA. Examples of a mounting method include staggered pin grid array (SPGA), land grid array (LGA), quad flat package (QFP), quad flat J-leaded package (QFJ), and quad flat non-leaded package (QFN).

### [Large Computer]

FIG. 42A is a perspective view of a large computer 5600. In the large computer 5600 illustrated in FIG. 42A, a plurality of rack mount computers 5620 are stored in a rack 5610. Note that the large computer 5600 may be referred to as a supercomputer.

The computer 5620 can have a structure illustrated in a perspective view of FIG. 42B, for example. In FIG. 42B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 42C is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 42C also illustrates semiconductor devices other than the semiconductor devices 5626, 5627, and 5628, and the following description of the semiconductor devices 5626, 5627, and 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminals 5623, 5624, and 5625 can each serve as, for example, an interface for performing power supply, signal input, or the like to the PC card 5621. For another example, they can each serve as an interface for outputting a signal calculated by the PC card 5621. Examples of the standard for each of the connection terminals 5623, 5624, and 5625 include Universal Serial Bus (USB), Serial ATA (SATA), and Small Computer System Interface (SCSI). In the case where video signals are output from the connection terminals 5623, 5624, and 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be connected to each other.

The semiconductor device 5627 includes a plurality of terminals, and when the terminals are reflow-soldered, for example, to wirings of the board 5622, the semiconductor device 5627 and the board 5622 can be connected to each other. Examples of the semiconductor device 5627 include an FPGA, a GPU, and a CPU. As the semiconductor device 5627, the electronic component 990 can be used, for example.

The semiconductor device 5628 includes a plurality of terminals, and when the terminals are reflow-soldered, for example, to wirings of the board 5622, the semiconductor device 5628 and the board 5622 can be connected to each other. An example of the semiconductor device 5628 is a memory device. As the semiconductor device 5628, the electronic component 990 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention is suitable as space equipment.

The semiconductor device of one embodiment of the present invention includes an OS transistor. A change in electrical characteristics due to radiation irradiation is smaller in an OS transistor than in a Si transistor. That is, the OS transistor is highly resistant to radiation, and thus has high reliability and is suitable in an environment where radiation can enter. For example, the OS transistor is suitably used in outer space. Specifically, the OS transistor can be used as a transistor in a semiconductor device provided in a space shuttle, an artificial satellite, or a space probe. Examples of radiation include X-rays and a neutron beam. Note that outer space refers to, for example, space at an altitude greater than or equal to 100 km, and outer space described in this specification can include one or more of thermosphere, mesosphere, and stratosphere.

FIG. 42D illustrates an artificial satellite 6800 as an example of space equipment. The artificial satellite 6800 includes a body 6801, a solar panel 6802, an antenna 6803, a secondary battery 6805, and a control device 6807. In FIG. 42D, a planet 6804 in outer space is illustrated as an example.

Although not illustrated in FIG. 42D, a battery management system (also referred to as BMS) or a battery control circuit may be provided in the secondary battery 6805. The OS transistor is preferably used in the battery management system or the battery control circuit because of its low power consumption and high reliability even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807.

The artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited to this example. The semiconductor device of one embodiment of the present invention is suitable for space equipment such as a spacecraft, a space capsule, or a space probe, for example.

As described above, the OS transistor has advantageous effects over the Si transistor, such as a wide memory bandwidth and high radiation resistance.

### [Data Center]

The semiconductor device of one embodiment of the present invention is suitable for, for example, a storage system in a data center or the like. Long-term management of data, such as guarantee of data immutability, is required for the data center. In the case where data is managed for a long term, it is necessary to increase the scale of data center facility for installation of storages and servers for storing an enormous amount of data, stable electric power for data retention, cooling equipment for data retention, or the like.

With the use of the semiconductor device of one embodiment of the present invention for the storage system in the data center, electric power required for data retention and the size of a semiconductor device retaining data can be reduced. Thus, the size of the storage system, the amount of electric power for data retention, the size of the cooling equipment, and the like can be reduced. This can reduce the scale of the data center.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

FIG. 42E illustrates a storage system that can be used in a data center. A storage system 7010 illustrated in FIG. 42E includes a plurality of servers 7001sb as a host 7001. The storage system 7010 includes a plurality of memory devices 7003md as a storage 7003. In the illustrated example, the host 7001 and the storage 7003 are connected to each other through a storage area network 7004 and a storage control circuit 7002.

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in the storage to shorten the time taken for storing and outputting data.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downscaling is possible by stacking memory cell arrays.

The use of the semiconductor device of one embodiment of the present invention for one or more selected from an electronic component, a large computer, space equipment, a data center, and an electronic device can reduce power consumption. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. Furthermore, the semiconductor device of one embodiment of the present invention has low power consumption and thus is effective as a global warming countermeasure.

This embodiment can be combined with any of the other embodiments as appropriate. In this specification, in the case where a plurality of structure examples are shown in one embodiment, the structure examples can be combined as appropriate.

### EXAMPLE 1

In this example, samples each including an indium oxide film were fabricated and their cross sections were observed.

First, Sample 1A and Sample 1B were fabricated.

First, a single crystal YSZ substrate was prepared. The substate plane of the prepared YSZ substrate was the (111) plane. Then, an indium oxide film was formed over the YSZ substrate by an ALD method. The targeted thicknesses for Sample 1A and Sample 1B were 10 nm and 2 nm, respectively. In the formation of the indium oxide film, triethylindium (TEI) was used as a precursor, ozone (O₃) was used as an oxidizer, and the substrate temperature was 200° C. The duration of introducing the oxidizer in one cycle was 60 seconds for Sample 1A and 9 seconds for Sample 1B. Note that one cycle includes introduction of a precursor, a purge of the precursor, introduction of an oxidizer, and a purge of the oxidizer.

Through the above steps, Sample 1A and Sample 1B were fabricated.

The cross sections of Sample 1A and Sample 1B fabricated in the above manner were observed. The cross sections were observed by a high-angle annular dark field scanning transmission electron microscopy (HAADF-STEM). The cross sections were observed at an acceleration voltage of 200 kV with an atomic resolution analytical electron microscope JEM-ARM200F produced by JEOL Ltd.

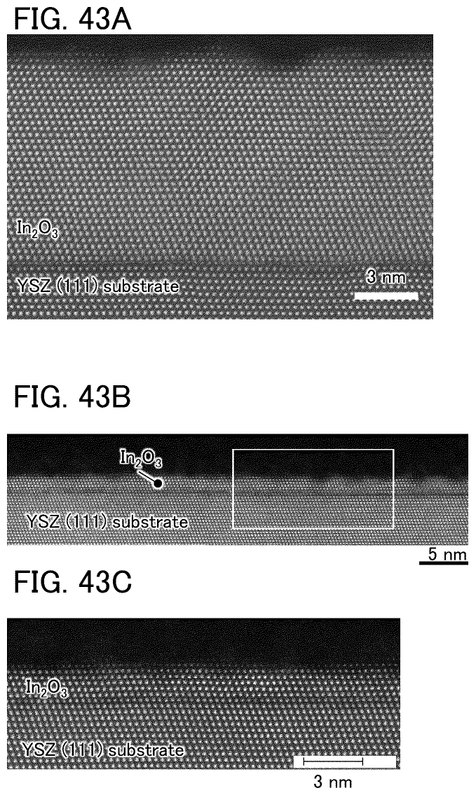

FIG. 43A shows a cross-sectional image of Sample 1A. In FIG. 43A, YSZ (111) substrate represents the YSZ substrate and In₂O₃ represents the indium oxide film. The indium oxide film is found to be crystallized by reflecting the crystal lattice of the YSZ substrate. It is thus confirmed that the indium oxide film formed over the YSZ substrate can epitaxially grow so that a single crystal film can be formed. FIG. 43B shows a cross-sectional image of Sample 1B. FIG. 43C is an enlarged view of a region in a white frame in FIG. 43B. It is confirmed that a single crystal indium oxide film is formed even with an extremely small thickness of approximately 2 nm.

Next, Sample 1C was fabricated.

First, a silicon substrate was prepared. Next, a 100-nm-thick silicon oxide film was formed on the silicon substrate by thermal oxidation treatment. Then, an In—Ga—Zn oxide film with a targeted thickness of 10 nm was formed over the silicon oxide film by a sputtering method. The In—Ga—Zn oxide film was formed using an oxide target with an atomic ratio of In:Ga:Zn=1:3:2.

Next, heat treatment was performed at 400° C. for one hour in a nitrogen atmosphere.

After that, an indium oxide film with a targeted thickness of 10 nm was formed over the In—Ga—Zn oxide film by an ALD method. In the formation of the indium oxide film, TEI was used as a precursor, ozone (O₃) was used as an oxidizer, the duration of introducing the oxidizer in one cycle was 9 seconds, and the substrate temperature was 200° C.

Through the above steps, Sample 1C was fabricated.

A cross-sectional TEM image of Sample 1C fabricated in the above manner was taken. In order to take the cross-sectional TEM image, the fabricated sample was thinned by a focused ion beam (FIB). The cross-sectional TEM image was observed with use of a spherical aberration corrector function. The cross-sectional TEM image was taken at an acceleration voltage of 200 kV with an atomic resolution analytical electron microscope JEM-ARM200F produced by JEOL Ltd.

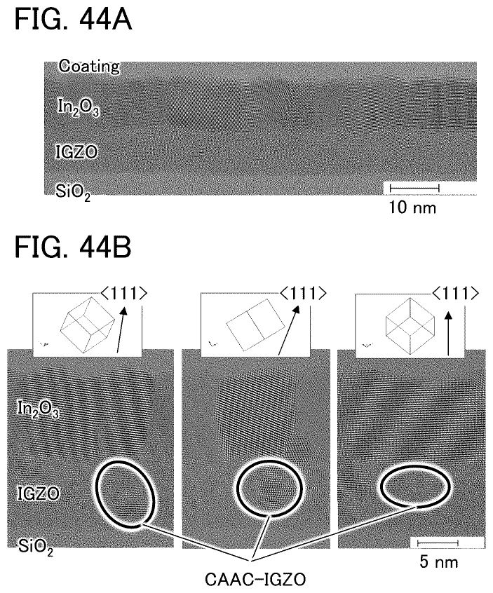

FIG. 44A shows the cross-sectional TEM image of Sample 1C. FIG. 44B shows enlarged views of three different portions. In FIG. 44A or 44B, SiO₂ represents the silicon oxide film, IGZO represents the In—Ga—Zn oxide film, In₂O₃ represents the indium oxide film, and Coating represents a protective film. As shown in FIG. 44B, a CAAC structure (CAAC-IGZO) is observed in the In—Ga—Zn oxide film. That is, the In—Ga—Zn oxide film is found to include a crystal whose <001> orientation is perpendicular or substantially perpendicular to the substrate plane.

In addition, a crystal region was observed in a region of the indium oxide film positioned above the CAAC structure. An FFT pattern was obtained by performing FFT processing on the region to analyze the directions of the crystal axes in the region. The analysis results reveal that the <111>orientations of the crystals are substantially perpendicular to the substrate.

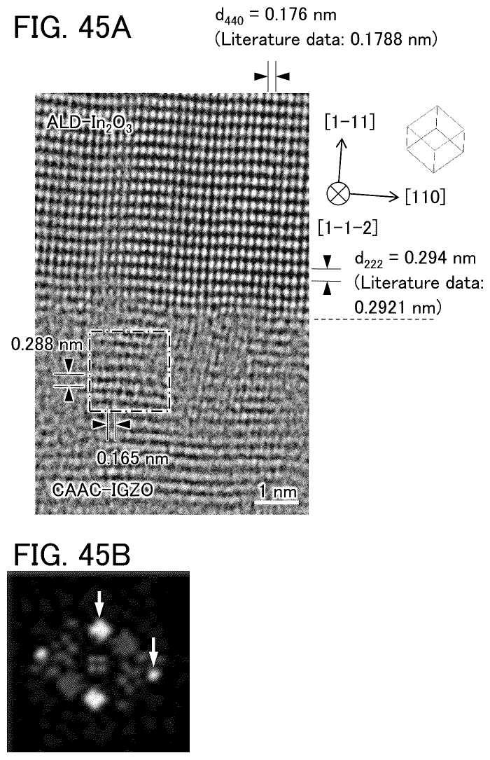

FIG. 45A is an enlarged cross-sectional view of part of the cross section in FIG. 44A. FIG. 45B shows an FFT pattern of a region of the In—Ga—Zn oxide film where the CAAC structure is observed (a region surrounded by a dashed-dotted line in FIG. 45A). In FIG. 45A, ALD-In₂O₃ represents the indium oxide film. FIGS. 45A and 45B reveal that the CAAC structure in the In—Ga—Zn oxide film is similar to a structure of an InGaZnO4 crystal seen from the [1-10] direction.

An FFT pattern was obtained by performing FFT processing on a crystal above the CAAC structure in the indium oxide film to analyze the direction of the crystal axis of the crystal. The analysis results confirm that the [1-11] orientation of the crystal included in the indium oxide film is aligned or substantially aligned with the <001> orientation of the crystal included in the In—Ga—Zn oxide film. It is thus found that the crystal in the indium oxide film is preferentially oriented in the <111> orientation above the CAAC structure in the In—Ga—Zn oxide film. Note that the upper right portion in FIG. 45A shows the directions of the crystal axes of the crystal included in the indium oxide film.

The analysis results of the obtained FFT pattern show that the interplanar spacing d222 of the crystal included in the indium oxide film is 0.294 nm. The lattice spacing in the vertical direction in the CAAC structure in the In—Ga—Zn oxide film is 0.288 nm, which is substantially equal to the interplanar spacing d222 of the crystal included in the indium oxide film. The interplanar spacing d440 of the crystal included in the indium oxide film is 0.176 nm, the lattice spacing in the lateral direction in the CAAC structure in the In—Ga—Zn oxide film is 0.165 nm, and the difference therebetween is approximately 6%.

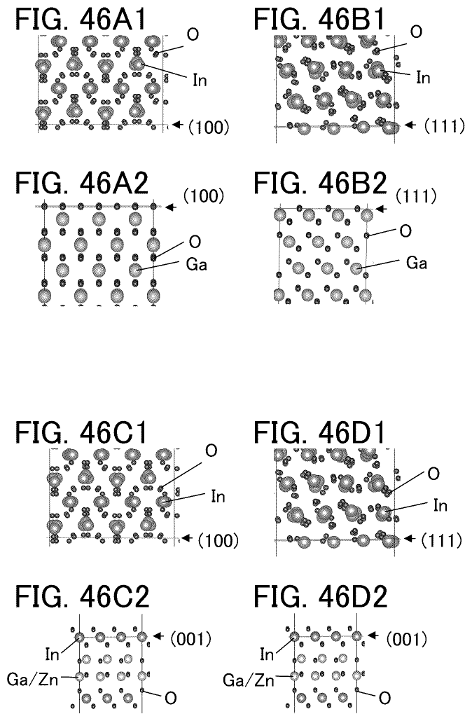

FIGS. 46B1 and 46D1 illustrate the crystal structure of In₂O₃ (bixbyite structure) seen from the direction parallel to the (111) plane, FIG. 46B2 illustrates the crystal structure of YSZ seen from the direction parallel to the (111) plane, and FIG. 46D2 illustrates the crystal structure of InGaZnO₄ seen from the direction parallel to the (001) plane (the direction perpendicular to the c-axis). For example, the lattice constant of an In₂O₃ crystal is said to be 1.01194 nm. In that case, the lattice mismatch degree of the (111) plane of the In₂O₃ crystal with respect to the (111) plane of an YSZ crystal is-1.9%, and the cross-sectional area is 1.843 nm². The lattice mismatch degree of the (111) plane of the In₂O₃ crystal with respect to the (001) plane of an InGaZnO₄ crystal is-0.55% in each of a′ and b′, and the cross-sectional area is 1.793 nm². In this example, the term “cross-sectional area” refers to the area of an interface (superlattice) between a formed film and a film on which the film is formed, and is a value of the area of the interface on the side of the film on which the film is formed. The formed film epitaxially grows per interface; thus, a material having a small area of the interface is preferably used as a base for epitaxial growth. Each of a′ and b′ represents the lattice constant of the superlattice of the InGaZnO₄ crystal at the interface (superlattice) between the In₂O₃ crystal and the InGaZnO₄ crystal.

FIGS. 46A1 and 46C1 illustrate the crystal structure of In₂O₃ seen from the direction parallel to the (100) plane, FIG. 46A2 illustrates the crystal structure of YSZ seen from the direction parallel to the (100) plane, and FIG. 46C2 illustrates the crystal structure of InGaZnO₄ seen from the direction parallel to the (001) plane (the direction perpendicular to the c-axis). The lattice mismatch degree of the (100) plane of the In₂O₃ crystal with respect to the (100) plane of the YSZ crystal is-1.9%, and the cross-sectional area is 1.064 nm². The lattice mismatch degree of the (100) plane of the In₂O₃ crystal with respect to the (001) plane of the InGaZnO₄ crystal is 2.2% in a′ and 1.1% in b′, and the cross-sectional area is 3.964 nm².

Since the lattice mismatch degree of the In₂O₃ crystal with respect to the single crystal YSZ substrate is low and the cross-sectional area is small as described above, a single crystal film of indium oxide is presumed to be formed over the single crystal YSZ substrate. It is also inferred that the crystallinity of the indium oxide film can be increased by the formation of the indium oxide film on the (001) plane of the In—Ga—Zn oxide whose lattice mismatch degree with respect to the single crystal YSZ substrate is lower than that of the In₂O₃ crystal and whose cross-sectional area with the single crystal YSZ substrate is equivalent to that of the In₂O₃ crystal.

The above results indicate that with the use of the In—Ga—Zn oxide and the indium oxide for the oxide layer 229 and the semiconductor layer 230, respectively, described in Embodiment 2, the crystallinity of the semiconductor layer 230 can be increased with the oxide layer 229 used as a seed or a nucleus.

The structures, configurations, methods, and the like described in this example can be used in an appropriate combination with any of the structures, configurations, methods, and the like described in the other embodiments and the like.

### Example 2

In this example, samples each including transistors were fabricated and cross-sectional observation was performed. In addition, the electrical characteristics of the transistors were evaluated.

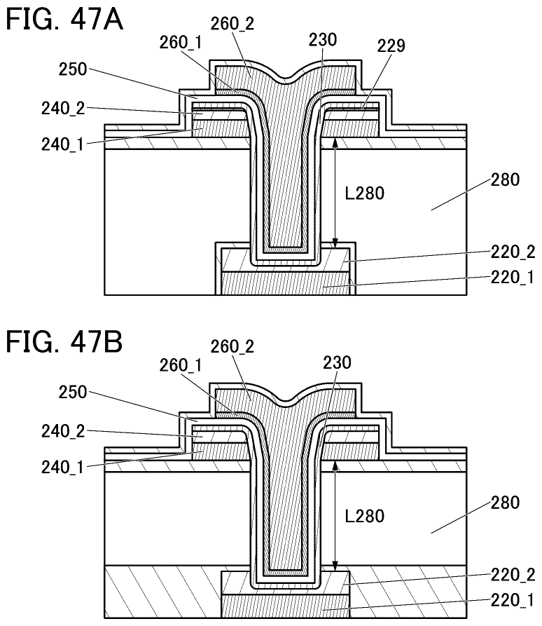

In this example, two samples (Sample 2A and Sample 2B) were fabricated. Sample 2A and Sample 2B each include a transistor over a substrate and the insulating layer 280. FIG. 47A is a cross-sectional view of the transistor fabricated in this example. The transistor included in Sample 2A includes the conductive layer 220_1, the conductive layer 220_2, the conductive layer 240_1, the conductive layer 240_2, the semiconductor layer 230, the insulating layer 250, and the conductive layer 260. The semiconductor layer 230 has a two-layer structure of the semiconductor layer 230_1 and the semiconductor layer 230_2 over the semiconductor layer 230_1. The insulating layer 280 has a three-layer structure of the insulating layers 280_1 to 280_3. The transistor included in Sample 2B includes the oxide layer 229 in addition to the components of the transistor included in Sample 2A. For the transistor structures, the structures in FIGS. 3A to 3D, FIG. 7A, FIG. 12A, and FIG. 16A can be referred to.

Methods for fabricating the transistors in this example will be described below.

First, a conductive film to be the conductive layer 220_1 and a conductive film to be the conductive layer 220_2 were formed in this order over the substrate for each of Sample 2A and Sample 2B. As the conductive film to be the conductive layer 220_1, a stacked-layer structure of a titanium nitride film formed by a sputtering method and a tungsten film formed over the titanium nitride film by a sputtering method was used. As the conductive film to be the conductive layer 220_2, an ITSO film was formed by a sputtering method. Then, these conductive films were processed to form the conductive layers 220_1 and 220 2.

Next, the insulating layer 280 was formed over the conductive layer 220_2. As the insulating layer 280, first, a silicon nitride film was formed by an ALD method. Subsequently, a silicon oxide film was formed by a sputtering method. Then, CMP treatment was performed on the silicon oxide film to planarize the top surface of the silicon oxide film. After that, a silicon nitride film was formed by a sputtering method. That is, the insulating layer 280 had a three-layer structure of the silicon nitride film, the silicon oxide film over the silicon nitride film, and the silicon nitride film over the silicon oxide film. The thickness of the insulating layer 280 over the conductive layer 220 was 95 nm.

Next, a conductive film to be the conductive layer 240_1 and a conductive film to be the conductive layer 240_2 were formed in this order over the insulating layer 280. As the conductive film to be the conductive layer 240_1, a 15-nm-thick tungsten film was formed by a sputtering method. As the conductive film to be the conductive layer 240_2, a 10-nm-thick ITSO film was formed by a sputtering method.

Subsequently, the opening portion 290 reaching the conductive layer 220_2 was formed in the conductive film to be the conductive layer 240_2, the conductive film to be the conductive layer 240_1, and the insulating layer 280. The opening portion 290 was formed to have a circular shape with a diameter of 60 nm in a plan view.

Next, in Sample 2B, an oxide film was formed over the conductive layer 220_2 and the conductive layer 240_2 by a sputtering method. The oxide film was formed using an oxide target with an atomic ratio of In:Ga:Zn=1:3:2. The oxide film with a targeted thickness of 2 nm was formed; thus, at least the oxide layer 229b was formed by the formation of the oxide film. Note that the oxide film was not formed in Sample 2A.

Then, a semiconductor film to be the semiconductor layer 230_1 and a semiconductor film to be the semiconductor layer 230 2 were formed in this order to cover the opening portion 290 for each of Sample 2A and Sample 2B. As the semiconductor film to be the semiconductor layer 230_1, a 10-nm-thick indium oxide film was formed by an ALD method. In the formation, triethylindium was used as a precursor, ozone was used as an oxidizer, the duration of introducing the oxidizer in one cycle was 9 seconds, and the substrate temperature was 200° C. As the semiconductor film to be the semiconductor layer 230_2, a 5-nm-thick metal oxide film was formed by a sputtering method. The semiconductor film to be the semiconductor layer 230_2 was formed using an oxide target with an atomic ratio of In:Ga:Zn=1:1:1.2.

Next, the semiconductor films to be the semiconductor layer 230 and the conductive films to be the conductive layer 240 were processed. By processing the semiconductor films to be the semiconductor layer 230, the semiconductor layer 230 including a region in contact with the conductive layer 220 and a region in contact with the conductive layer 240 was formed. By processing the conductive films to be the conductive layer 240, the conductive layer 240 was formed to be positioned between the insulating layer 280 and the semiconductor layer 230.

Then, the insulating layer 250 was formed over the semiconductor layer 230. As the insulating layer 250, a 1-nm-thick aluminum oxide film, a 2-nm-thick silicon nitride film, a 2-nm-thick hafnium oxide film, and a 1-nm-thick silicon nitride film were formed in this order by an ALD method.

Subsequently, a conductive film to be the conductive layer 260_1 and a conductive film to be the conductive layer 260_2 were formed in this order over the insulating layer 250. As the conductive film to be the conductive layer 260_1, a titanium nitride film was formed by an ALD method. As the conductive film to be the conductive layer 260_2, a tungsten film was formed by a CVD method. After that, these conductive films were processed to form the conductive layers 260_1 and 260_2. Through the above steps, the transistors were formed.

[Evaluation 1 of electrical characteristics of transistor] The Id-Vg characteristics of nine transistors included in each of Sample 2A and Sample 2B were measured. Here, in each of the transistors subjected to the measurement, a length L280 shown in FIG. 47A was 95 nm.

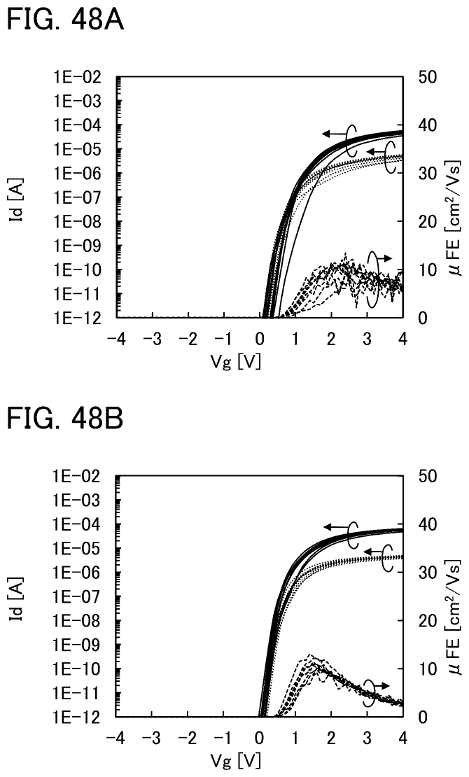

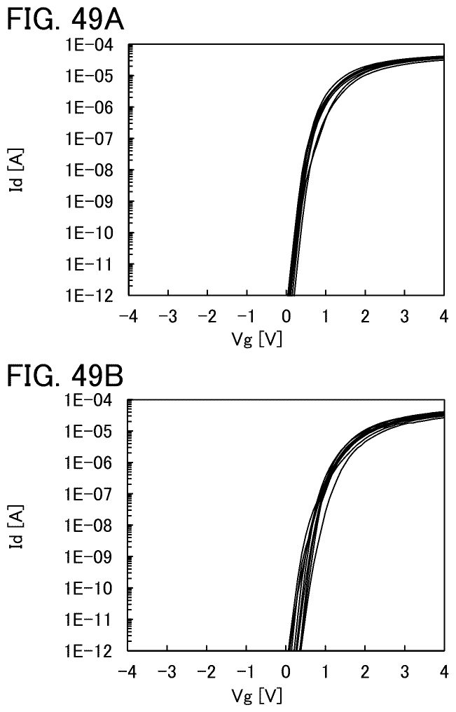

In the measurement, the drain voltage Vd was 1.2 V, 0.8 V, or 0.1 V and the gate voltage Vg was swept from −4 V to +4 V in steps of 0.1 V. The measurement temperature was room temperature. FIGS. 48A and 48B and FIGS. 49A and 49B show the Id-Vg characteristics of the transistors. In each of FIGS. 48A and 48B and FIGS. 49A and 49B, the first vertical axis on the left represents the drain current Id [A], the second vertical axis on the right represents the field-effect mobility uFE [cm²/Vs], and the horizontal axis represents the gate voltage Vg [V]. In FIGS. 48A and 48B, the Id-Vg curves at Vd=0.1 V are denoted by dotted lines, the Id-Vg curves at Vd=1.2 V are denoted by solid lines, and the field-effect mobilities are denoted by dashed lines. In FIGS. 49A and 49B, the Id-Vg curves at Vd=0.8 V are denoted by solid lines. FIG. 48A and FIG. 49A show the Id-Vg characteristics of the transistors included in Sample 2B, and FIG. 48B and FIG. 49B show the Id-Vg characteristics of the transistors included in Sample 2A.

As shown in FIGS. 48A and 48B and FIGS. 49A and 49B, the transistors included in Sample 2A and Sample 2B each have excellent electrical characteristics. Specifically, in the transistors included in Sample 2A at Vd=1.2 V, the median value of the on-state currents was 24.6 uA, the median value of the S values was 101.7 mV/dec., the median value of the threshold voltages (Vth) was 1.22 V, and the standard deviation of the threshold voltages was 197.2 mV. In the transistors included in Sample 2B at Vd=1.2 V, the median value of the on-state currents was 32.9 uA, the median value of the S values was 85.3 mV/dec., the median value of the threshold voltages (Vth) was 0.86 V, and the standard deviation of the threshold voltages was 88.9 mV. Note that the threshold voltages (Vth) were calculated by a root Id method described later. The on-state currents were the values of the drain currents Id at Vg=Vth+2.5 V.

The median value of the threshold voltages of the transistors included in Sample 2B at Vd =1.2 V calculated by a constant current method was 0.37 V and the standard deviation of the threshold voltages was 55.1 mV. In the constant current method, gate voltage (Vg) at which a value of drain current (Id) x channel length (L)/channel width (W) in the Id-Vg characteristics of a transistor is 1 nA (1×10⁻⁹ A) is regarded as Vth. The channel length (L) at the time of calculating the threshold voltages was 110 nm.

In the transistors included in Sample 2A at Vd=0.8 V, the average value (Ave.) of the on-state currents at a gate voltage of 3 V was 22.5 uA, the standard deviation (o) of the threshold voltages was 0.11 V, and the average value of the S values was 95.7 mV/dec. In the transistors included in Sample 2B at Vd=0.8 V, the average value of the on-state currents at a gate voltage of 3 V was 28.8 uA, the standard deviation of the threshold voltages was 0.05 V, and the average value of the S values was 86.7 mV/dec. Note that the threshold voltage at Vd=0.8 V was the value of Vg at the intersection of the Id-Vg curve and a straight line of Id=1 pA (=1.0×10⁻¹² A).

Table 4 shows the on-state currents, the threshold voltages, and the S values of the transistors included in Sample 2A and Sample 2B at Vd=0.8 V.

TABLE 4

| | | On-state current | Threshold voltage | S value |
|---|---|---|---|---|
| Sample | | [μA] | [V] | [mv/dec.] |
| 2B | Ave. | 28.8 | 0.10 | 86.7 |
| | σ | 3.3 | 0.05 | 3.6 |
| 2A | Ave. | 22.5 | 0.23 | 95.7 |
| | σ | 3.5 | 0.11 | 8.2 |

As described above, the transistors included in Sample 2B had better electrical characteristics than the transistors included in Sample 2A.

### [Cross-Sectional Observation]

Cross-sectional TEM images of the fabricated samples were taken. In order to take the cross-sectional TEM images, the fabricated samples were thinned by an FIB. The cross-sectional TEM images were observed with use of a spherical aberration corrector function. The cross-sectional TEM images were taken at an acceleration voltage of 200 kV with an atomic resolution analytical electron microscope JEM-ARM200F produced by JEOL Ltd.

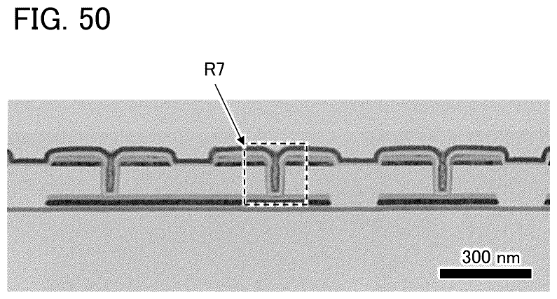

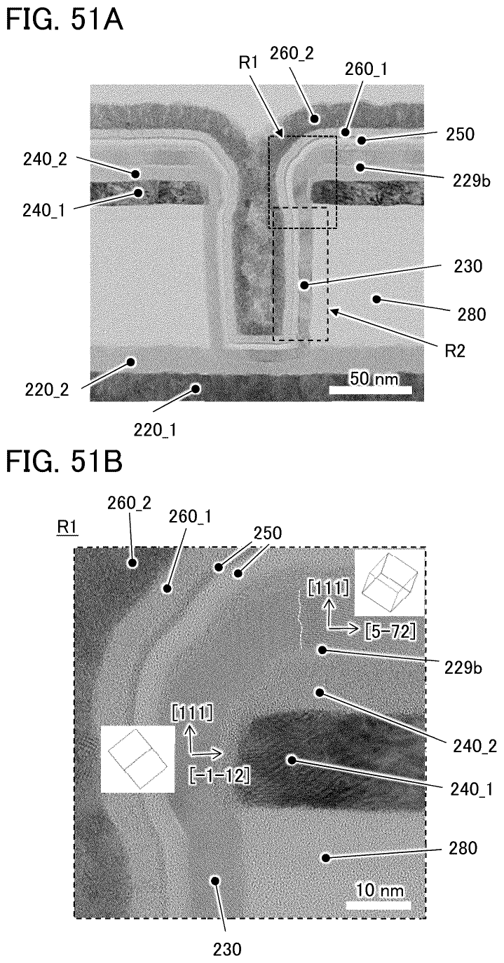

The cross-sectional TEM images of the fabricated samples are shown in FIG. 50, FIGS. 51A and 51B, FIG. 52, FIGS. 53A and 53B, FIGS. 54A and 54B, FIG. 55, FIGS. 56A and 56B, and

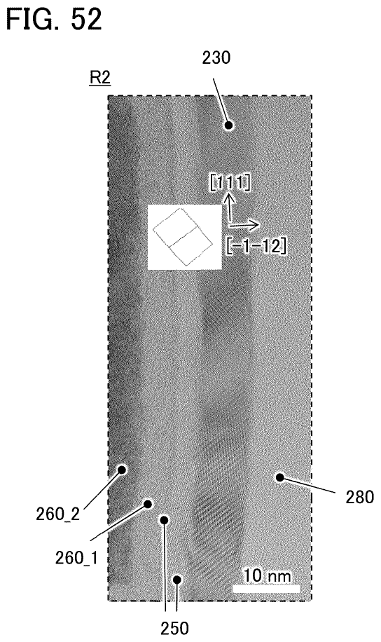

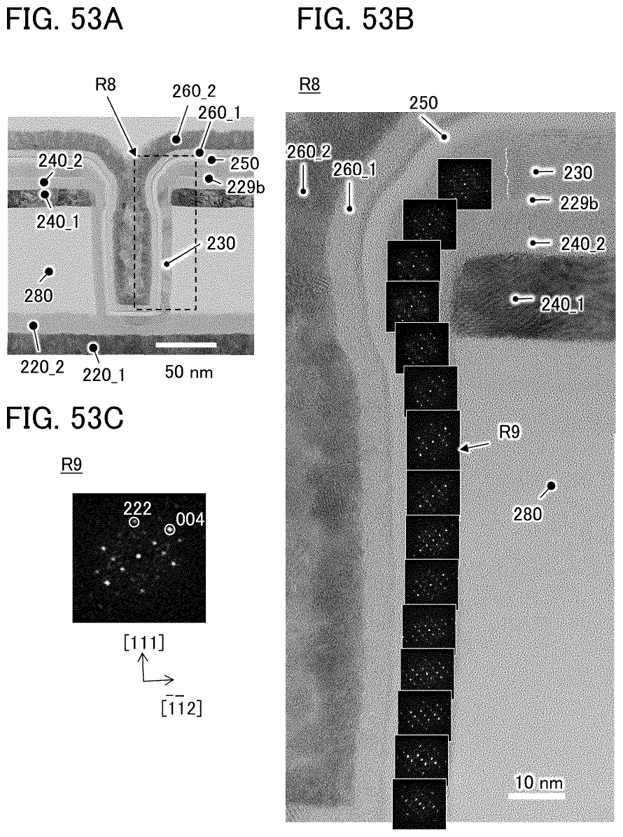

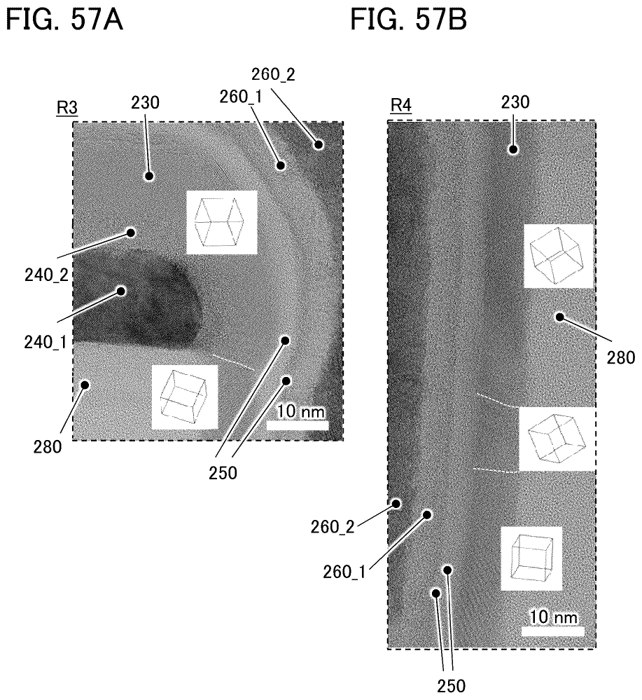

FIGS. 57A and 57B. FIG. 50, FIGS. 51A and 51B, FIG. 52, and FIGS. 53A and 53B are the cross-sectional TEM images of Sample 2B. FIG. 50 is the cross-sectional TEM image of the transistors included in Sample 2B and their vicinities. FIG. 51A and FIG. 53A are enlarged cross-sectional TEM images of a region R7 shown in FIG. 50. FIG. 51B is an enlarged cross-sectional TEM image of a region R1 shown in FIG. 51A. FIG. 52 is an enlarged cross-sectional TEM image of a region R2 shown in FIG. 51A. FIG. 53B is an enlarged cross-sectional TEM image of a region R8 shown in FIG. 53A. FIG. 53B shows FFT patterns of the channel formation region between the conductive layer 240 and the conductive layer 220. FIG. 53C is an enlarged view of the FFT pattern indicated by R9 in FIG. 53B.

As shown in FIGS. 51A and 51B and FIG. 52, the oxide layer 229b over and in the vicinity of the conductive layer 240 is observed; however, no oxide film is observed in the vicinity of the side surface of the insulating layer 280 in the opening portion.

According to FIG. 51B and FIG. 52, lattice fringes are observed in the entire semiconductor layer 230, indicating that the semiconductor layer 230 includes crystals. When the crystal orientations

are focused on, it is confirmed that the orientations (indicated by arrows) above the conductive layer 240, in the vicinity of the side surface of the conductive layer 240 in the opening portion, and in the vicinity of the side surface of the insulating layer 280 in the opening portion are aligned with each other. Specifically, the orientations are perpendicular or substantially perpendicular to the top surface of the oxide layer 229b. That is, it is presumed from FIG. 51B and FIG. 52 that the crystals whose orientations are aligned with each other are formed in the entire semiconductor layer 230 with the oxide layer 229b used as a seed while the semiconductor layer 230 is not affected by the shape of the formation surface.

The [-1-12] orientation of the crystal in the vicinity of the side surface of the insulating layer 280 in the opening portion is perpendicular or substantially perpendicular to the side surface of the insulating layer 280 in the opening portion, and the [-1-12] orientation of the crystal in the vicinity of the side surface of the conductive layer 240 in the opening portion is also perpendicular or substantially perpendicular to the side surface of the insulating layer 280 in the opening portion. That

is, it can be said that the crystals whose orientations are aligned with each other are formed along the side surface of the insulating layer 280 in the opening portion while drawing a smooth curve even in the edge portion.

As shown in FIGS. 53B and 53C, uniform FFT patterns are continuously observed in the channel formation region. Specifically, the FFT patterns each show the orientation substantially perpendicular to the substrate and the [-1-12] orientation substantially parallel to the substrate. The FFT patterns each show the orientation substantially perpendicular to the substrate and the

[-1-12] orientation substantially parallel to the substrate also along the side surface of the conductive layer 240.

FIG. 8F illustrates the crystal structure of In₂O₃ (bixbyite structure) seen from the direction perpendicular to the (111) plane (the orientation). Note that FIG. 8F illustrates a unit lattice

and its principal axes, and does not illustrate an indium atom or an oxygen atom. The (1-10) plane, the (−110) plane, the (10⁻¹) plane, the (−101) plane, the (01-1) plane, the (0-11) plane, the (−1-12) plane, and the (5-72) plane in FIG. 8F are orthogonal to the (111) plane. In the case where the (hkl) plane is orthogonal to the (111) plane as illustrated in FIG. 8F, h+k+1=0 is satisfied. For example,

the (−1-12) plane is orthogonal to the (111) plane. The [-1-12] orientation is orthogonal to the orientation.

From the above, it is indicated that when the (001) plane of the crystal included in the oxide layer 229 formed using an In—Ga—Zn oxide is flat, the crystal in the indium oxide film grows due to the influence of a seed crystal even though the crystal in the indium oxide film is away from the seed crystal or has a curved surface or a vertical surface that is not on the same plane as the seed crystal. This crystal engineering phenomenon can be regarded as being similar to epitaxial lateral overgrowth (ELO).

When the indium oxide film is formed by an ALD method on the seed crystal, the indium oxide having a bixbyite structure is deposited. It is inferred that this reaction proceeds in the lateral direction to a region farther from the seed crystal so that the indium oxide film having high crystallinity is formed on an insulating film.

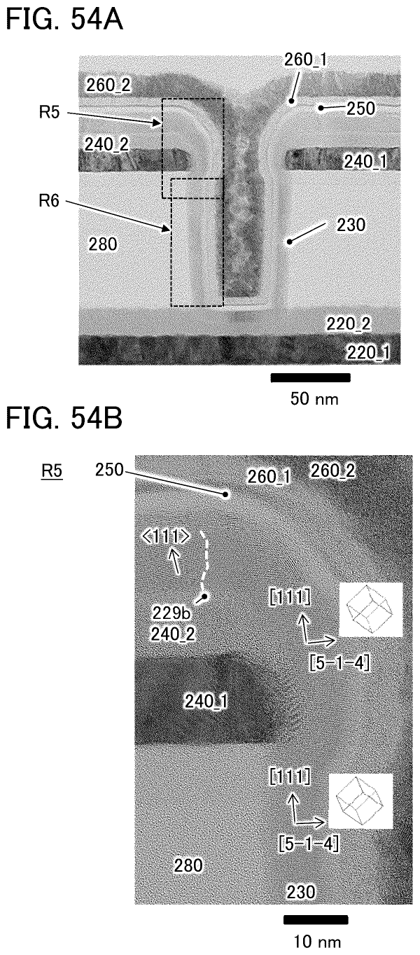

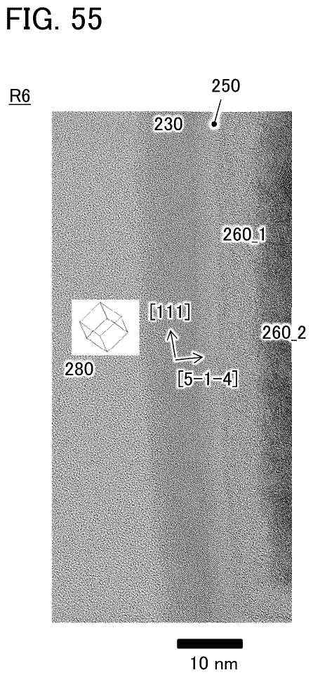

FIGS. 54A and 54B and FIG. 55 show cross-sectional TEM images of another region in Sample 2B. FIG. 54B is an enlarged cross-sectional TEM image of a region R5 shown in FIG. 54A, and FIG. 55 is an enlarged cross-sectional TEM image of a region R6 shown in FIG. 54A. The transistor observed in the cross-sectional TEM image of FIG. 54A is different from the transistor observed in the cross-sectional TEM image of FIG. 51A.

According to FIGS. 54A and 54B and FIG. 55, lattice fringes are observed in the entire semiconductor layer 230 also in the transistor observed in the cross-sectional TEM image of FIG. 54A, indicating that the semiconductor layer 230 includes crystals. When the crystal orientations are

focused on, it is confirmed that the orientations (indicated by arrows) above the conductive layer 240, in the vicinity of the side surface of the conductive layer 240 in the opening portion, and in the vicinity of the side surface of the insulating layer 280 in the opening portion are aligned with each other. Specifically, the orientations are perpendicular or substantially perpendicular to the top surface of the oxide layer 229b. The [5-1-4] orientation of the crystal in the vicinity of the side surface of the insulating layer 280 in the opening portion is perpendicular or substantially perpendicular to the side surface of the insulating layer 280 in the opening portion, and the [5-1-4] orientation of the crystal in the vicinity of the side surface of the conductive layer 240 in the opening portion is also perpendicular or substantially perpendicular to the side surface of the insulating layer 280 in the opening portion.

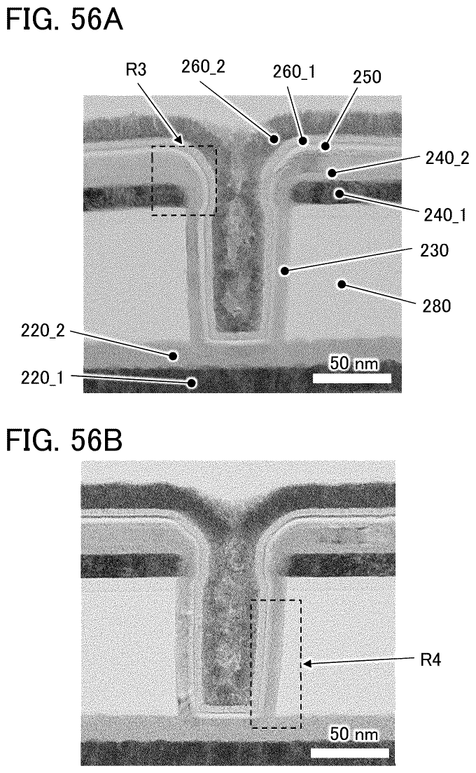

FIGS. 56A and 56B and FIGS. 57A and 57B are cross-sectional TEM images of Sample 2A. FIGS. 56A and 56B show the cross-sectional TEM images of different regions. FIG. 57A is an enlarged cross-sectional TEM image of a region R3 shown in FIG. 56A, and FIG. 57B is an enlarged cross-sectional TEM image of a region R4 shown in FIG. 56B.

FIGS. 57A and 57B reveal that the semiconductor layer 230 has crystallinity and a crystal grain boundary is observed in the semiconductor layer 230. The transistors included in Sample 2B have better electrical characteristics than the transistors included in Sample 2A presumably because carrier scattering or the like at the crystal grain boundary is inhibited and thus current easily flows and a threshold voltage variation is reduced in each of the transistors included in Sample 2B.

Described below is the principle where the orientations above the conductive layer 240, in the vicinity of the side surface of the conductive layer 240 in the opening portion, and in the vicinity of the side surface of the insulating layer 280 in the opening portion are aligned with each other, i.e., a portion of the semiconductor layer 230 that includes the channel formation region is single-crystallized.

First, the mechanism of crystal growth of indium oxide is described using interface energy. The interface energy refers to energy loss due to formation of an interface between a crystal structure and an amorphous structure, and can be calculated by the following formula.

$$\begin{matrix}[ Formula 2 ] & \\ {E}_{interface} = ( {E}_{a / c} - {E}_{amo} - {E}_{cry} ) \div S & ( 2 )\end{matrix}$$

Here, E_{interface} is the interface energy, Eₐₘₒ is the total energy of an amorphous structure model, E_{cry} is the total energy of a single crystal structure model, E_{a/c} is the total energy of a model where an amorphous structure and a single crystal structure are bonded, and S is a bonding cross-sectional area, which is a contact area between the amorphous structure and the single crystal structure in the model where the amorphous structure and the single crystal structure are bonded.

As the interface energy is lower, the energy loss due to crystallization is smaller. Thus, a crystal grows such that the surface area of a crystal plane with a low interface energy is maximized. That is, the crystal growth rate in the direction along the crystal plane with a low interface energy is fast, whereas the crystal growth rate in the direction perpendicular to the crystal plane with a low interface energy is slow.

The model where the amorphous structure and the single crystal structure are bonded was created in the following manner. First, a model including a single crystal structure was prepared. Next, molecular dynamics calculation was performed using the NVT ensemble to melt the half of the model at 5000 K. Then, molecular dynamics calculation was performed to optimize the structure of the model the half of which is melted. In this manner, the model where the amorphous structure and the single crystal structure are bonded was created. Subsequently, molecular dynamics calculation was performed using the NVT ensemble to rapidly cool down the created model to 200 K, so that the energy in the equilibrated state was calculated. The calculated energy was used as the total energy of the model where the amorphous structure and the single crystal structure are bonded.

For the molecular dynamics calculation, open source software LAMMPS was used. In this example, M3GNet (see Non-Patent Document 3) was used as the molecular force field.

Table 5 shows the interface energy of each of the (100) plane, the (110) plane, the (1-10) plane, and the (111) plane of an indium oxide crystal.

TABLE 5

| Crystal plane | (100) | (1-10) | (110) | (111) |
|---|---|---|---|---|
| Interface energy | 5.94 | 3.48 | 2.12 | 1.92 |
| (eV/nm²) | | | | |

Table 5 reveals that indium oxide has a tendency in which the interface energy of the (111) plane is the lowest, followed in order by that of the (110) plane, that of the (1-10) plane, and that of the (100) plane. Since the interface energy of the (111) plane is the lowest in indium oxide, an indium oxide crystal presumably grows while maximizing the surface area of the (111) plane. Accordingly, it is presumed that indium oxide is preferentially oriented in the (111) plane.

The above is the description of the mechanism of the crystal growth of indium oxide.

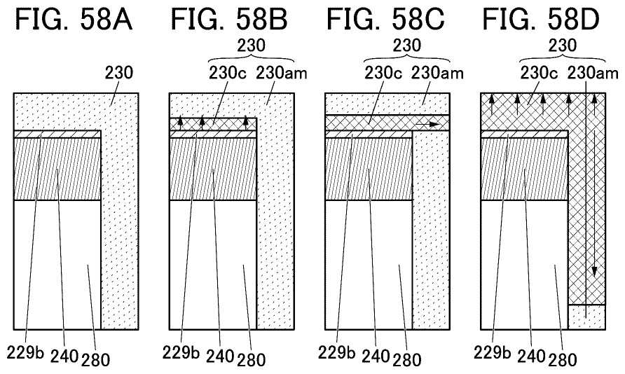

Next, in view of the above mechanism, the principle where the portion of the semiconductor layer 230 that includes the channel formation region is single-crystallized will be described with reference to FIGS. 58A to 58D.

First, an indium oxide film is formed by an ALD method as the semiconductor layer 230. The indium oxide film immediately after the formation has low crystallinity, e.g., an amorphous structure (see FIG. 58A). Next, a crystal grain 230c is formed over the CAAC structure of the oxide layer 229b by solid phase epitaxial growth (see FIG. 58B). In that case, the surface of the crystal grain 230c is the (111) plane.

The crystal grain 230c grows while maximizing the surface area of the (111) plane. That is, a region of a semiconductor layer 230 am having an amorphous structure that is positioned in the horizontal direction of the crystal grain 230c is being single-crystallized by solid phase epitaxial growth (see FIG. 58C). Thus, the crystal growth of the crystal grain 230c proceeds to a region farther from the CAAC structure of the oxide layer 229b.

After the crystal growth of the crystal grain 230c to the side surface of the indium oxide film in the opening portion 290, a region of the semiconductor layer 230 am having an amorphous structure that is positioned in the vertical direction (also referred to as the direction perpendicular to the substrate) of the crystal grain 230c is being single-crystallized by solid phase epitaxial growth (see FIG. 58D).

It is inferred that the portion of the semiconductor layer 230 that includes the channel formation region is single-crystallized in the above manner. It is also inferred that the indium oxide film in which a crystal grain boundary is not observed in the current flow direction (the direction perpendicular or substantially perpendicular to the substrate plane) can be formed in a portion that is in contact with the side surface of the insulating layer 280 in the opening portion 290.

[EDX analysis]

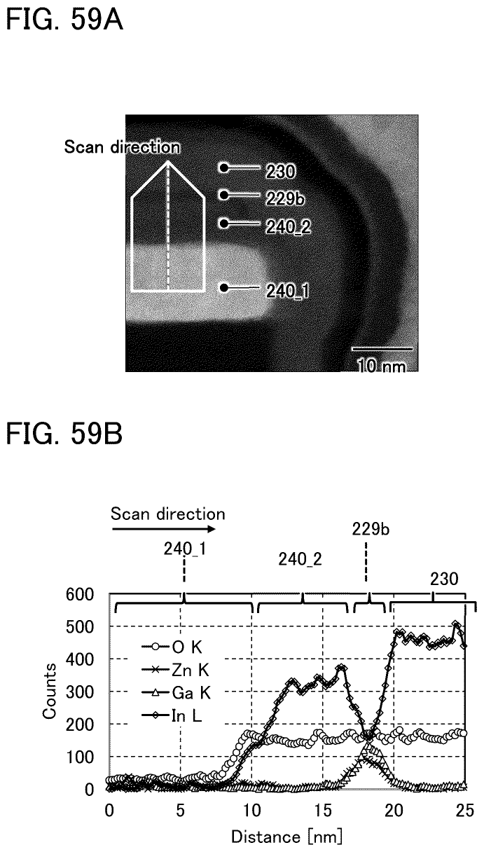

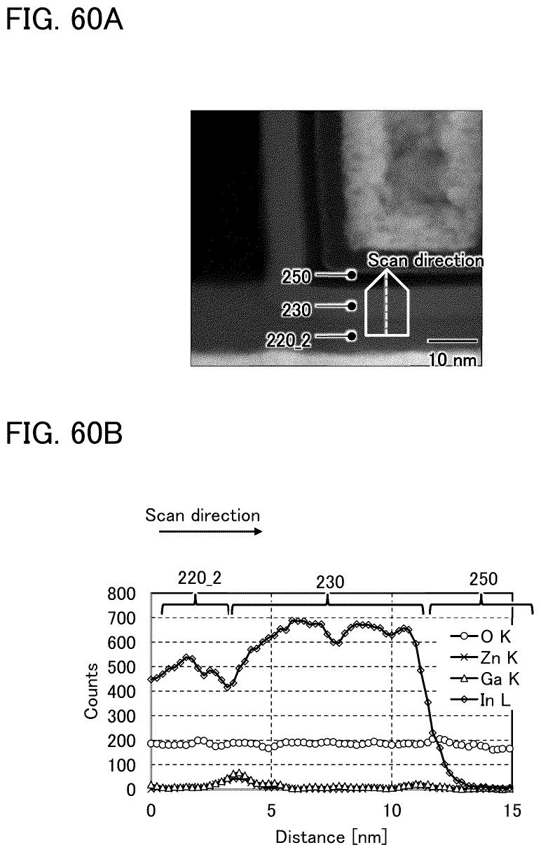

Next, the cross section of Sample 2B was subjected to elementary analysis by EDX. FIG. 59B shows the results of STEM-EDX line analysis along the analysis direction denoted by “Scan direction” in a cross-sectional HAADF-STEM image shown in FIG. 59A. FIG. 60B shows the results of STEM-EDX line analysis along the analysis direction denoted by “Scan direction” in a cross-sectional HAADF-STEM image shown in FIG. 60A. In each of FIG. 59B and FIG. 60B, the vertical axis represents the count value (Counts) of characteristic X-rays and the horizontal axis represents the distance [nm]. The EDX analysis results of four elements of O, Zn, Ga, and In are shown. For the HAADF-STEM analysis and the STEM-EDX analysis, JEM-ARM200F NEOARM produced by JEOL Ltd. was used. As the STEM-EDX detector, JED-2300T was used.

As the analysis shown in FIG. 59A, EDX analysis was performed on the conductive layer 240_1, the conductive layer 240_2, the oxide layer 229b, and the semiconductor layer 230 along the direction substantially perpendicular to the top surface of the conductive layer 240_2. As the analysis shown in FIG. 60A, EDX analysis was performed on the conductive layer 220_2, the semiconductor layer 230, and the insulating layer 250 along the direction substantially perpendicular to the top surface of the conductive layer 220_2.

As shown in FIG. 59B, the detection intensity of each of the elements is low in a region corresponding to the conductive layer 240_1 formed using tungsten. In a region corresponding to the conductive layer 240_2 formed using ITSO, In and O are mainly detected. In a region corresponding to the semiconductor layer 230, In and O are mainly detected, indicating that indium oxide is formed.

A region where Ga, Zn, In, and O are mainly detected is observed between the conductive layer 240_2 and the semiconductor layer 230, indicating that an In—Ga—Zn oxide as the oxide layer 229b is formed over the conductive layer 240_2.

As shown in FIG. 60B, In and O are mainly detected in a region corresponding to the conductive layer 220_2 formed using ITSO. In a region corresponding to the semiconductor layer 230, In and O are mainly detected, indicating that indium oxide is formed. Although In, Ga, Zn, and O are detected in a region between the conductive layer 220_2 and the semiconductor layer 230, the detected amounts of Ga and Zn are small. This reveals that an In—Ga—Zn oxide is formed on the bottom portion of the opening portion 290 but is too thin to be recognized as a film, and the In—Ga—Zn oxide does not function as a seed or a nucleus. This difference is caused probably because the oxide film is formed by a sputtering method and thus is not formed on the bottom of the deep and minute opening portion. [Off-state current I]

In this section, evaluation of the off-state currents of transistors will be described. In order to evaluate the off-state currents of the transistors, Sample 3B and Sample 3C were prepared.

Sample 3B and Sample 3C each include a device under test (DUT) subjected to the evaluation of the off-state currents. Since an OS transistor has an extremely low off-state current, 20000 transistors connected in parallel were prepared as the DUT in this example.

For the transistors included in the DUT of Sample 3B, the structure of the transistors included in Sample 2B described above can be referred to.

The transistors included in the DUT of Sample 3C have the same structure as the transistors included in Sample 2A except that the semiconductor layer 230 has a three-layer structure. Thus, for the components other than the semiconductor layer 230, the description of the structure of the transistors included in Sample 2A can be referred to.

A semiconductor film to be the semiconductor layer 230_3, the semiconductor film to be the semiconductor layer 230_1, and the semiconductor film to be the semiconductor layer 230_2 were formed in this order to cover the opening portion 290. As the semiconductor film to be the semiconductor layer 230_3, a 0.5-nm-thick gallium oxide film was formed by an ALD method. In the formation of the gallium oxide film, triethylgallium was used as a precursor, ozone was used as an oxidizer, and the substrate temperature was 200° C. As the semiconductor film to be the semiconductor layer 230_1, a 5-nm-thick indium oxide film was formed by an ALD method. In the formation, triethylindium was used as a precursor, ozone was used as an oxidizer, the duration of introducing the oxidizer in one cycle was 60 seconds, and the substrate temperature was 200° C. As the semiconductor film to be the semiconductor layer 230_2, a 5-nm-thick metal oxide film was formed by a sputtering method. The semiconductor film to be the semiconductor layer 230_2 was formed using an oxide target with an atomic ratio of In:Ga:Zn=1:1:1.2.

In this manner, the transistors were fabricated, and Sample 3C including the transistors was fabricated.

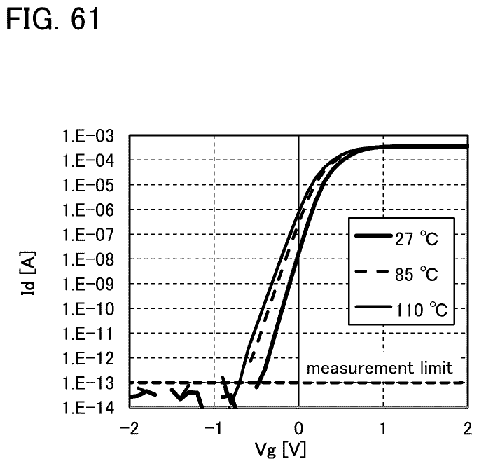

FIG. 61 shows the Id-Vg curves of the transistors included in Sample 3B in the environments at 110° C., 85° C., and 27° C. The drain-source voltage was 0.8 V. The lower measurement limit of the measurement apparatus is approximately 1×10⁻¹³ A, and it is indicated that the off-state currents are below the lower measurement limit. Thus, it is difficult to estimate the off-state currents of the transistors from the measurement data of the Id-Vg curves.

Next, a method for quantitatively evaluating an extremely low off-state current of a transistor will be described.

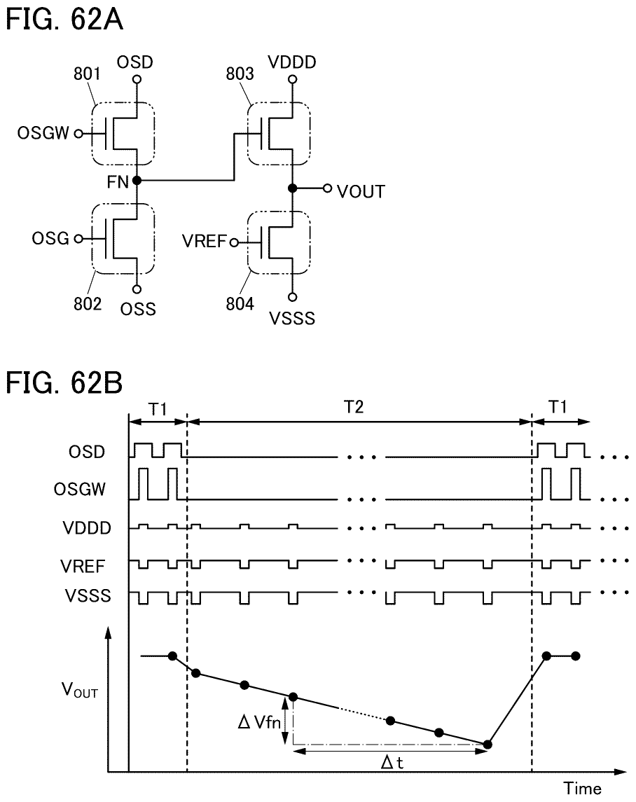

FIG. 62A illustrates a circuit used for the measurement of the off-state currents. The circuit illustrated in FIG. 62A includes a transistor 801, a transistor 802, a transistor 803, and a transistor 804. A gate of the transistor 801 is connected to a terminal OSGW, one of a source and a drain of the transistor 801 is connected to a terminal OSD, a gate of the transistor 802 is connected to a terminal OSG, one of a source and a drain of the transistor 802 is connected to a terminal OSS, a gate of the transistor 803 is connected to the other of the source and the drain of the transistor 801 and the other of the source and the drain of the transistor 802, one of a source and a drain of the transistor 803 is connected to a terminal VDDD, a gate of the transistor 804 is connected to a terminal VREF, one of a source and a drain of the transistor 804 is connected to a terminal VSSS, and the other of the source and the drain of the transistor 803 is connected to the other of the source and the drain of the transistor 804 and a terminal VOUT. A node connected to the gate of the transistor 803 is denoted as a node FN.

The circuit is composed of a program circuit, a read circuit, and a DUT. The program circuit has a function of accumulating charge in the node FN. The read circuit has a function of monitoring a potential VEN of the node FN with a potential Vour. The DUT serves as a main leakage source of the charge accumulated in the node FN. In FIG. 62A, the transistor 801 corresponds to the program circuit, the transistor 802 corresponds to the DUT, and a circuit including the transistors 803 and 804 corresponds to the read circuit.

Next, a measurement method will be described with reference to FIG. 62B. In this measurement, the transistor 802 was kept in a non-conduction state. In this example, a potential of −1.5 V was applied to the terminal OSG and a potential of 0 V was applied to the terminal OSS.

In Period T1, charge is accumulated in the node FN. First, the transistor 801 is turned on, the potential of the terminal OSD is written to the node FN, and the transistor 801 is turned off. In order to ensure adequate writing of the potential to the node FN, the potential is written twice to the node FN. After that, the transistor 801 is turned off and the potential VEN of the node FN is retained. In this example, a potential of 2 V was applied to the terminal OSGW and a potential of 0.8 V was applied to the terminal OSD to turn on the transistor 801. A potential of −2 V was applied to the terminal OSGW and a potential of 0.45 V was applied to the terminal OSD to turn off the transistor 801. In this manner, the potential VEN of the node FN was set to 0.8 V.

In Period T2, the potential VEN of the node FN is retained. The potential VEN of the node FN is read n times in Period T2. When the node FN is kept in a floating state in Period T2, charge flows due to the off-state current of the transistor 802 and the potential VEN of the node FN changes over time. That is, the potential VEN of the node FN changes in accordance with a change in the amount of charge retained in the node FN. The potential Vour of the terminal VOUT changes accordingly. Thus, the amount of change in the potential VEN can be obtained by measuring the change in the potential VOUT. In this example, a potential of 2 V was applied to the terminal VDDD, a potential of −1 V was applied to the terminal VREF, and a potential of −2 V was applied to the terminal VSSS at the time of reading the potential VOUT. Before and after the reading of the potential VOUT, a potential of 1.5 V was applied to each of the terminal VDDD, the terminal VREF, and the terminal VSSS.

In this example, in order to confirm the reproducibility of the results, the writing operation performed twice and the reading operation performed n times during data retention were regarded as one set, and a plurality of sets of measurement were performed.

The off-state current Ioff of each of the transistors in the DUT was calculated with the equation, off-state current Ioff=parasitic capacitance Cfn x potential change AVfn/measurement time At. Note that the parasitic capacitance Cfn of a drain terminal and the amount of change AVfn in the potential VEN over the measurement time At were measured in advance.

In Sample 3B and Sample 3C, the off-state currents were evaluated using the DUTs including the transistors in each of which the width of the opening portion 290 was 60 nm.

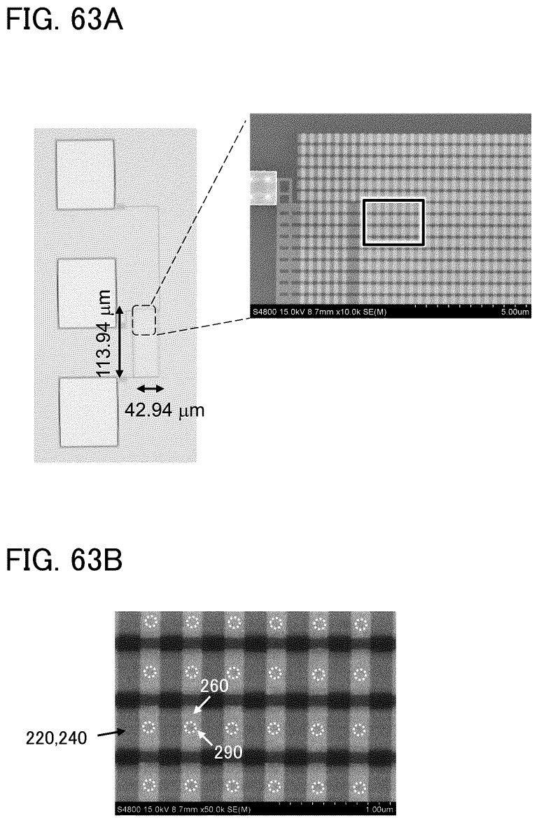

FIG. 63A shows an optical micrograph and a SEM image including the 20000 transistors connected in parallel in each of the DUTs. The optical micrograph is shown on the left side in FIG. 63A, and the SEM image of a region surrounded by dashed lines in the optical micrograph is shown on the right side in FIG. 63A. The SEM image was observed at a magnification of 10000 times.

FIG. 63B shows a SEM image of a region surrounded by a solid line in the SEM image shown on the right side in FIG. 63A. The SEM image was observed at a magnification of 50000 times.

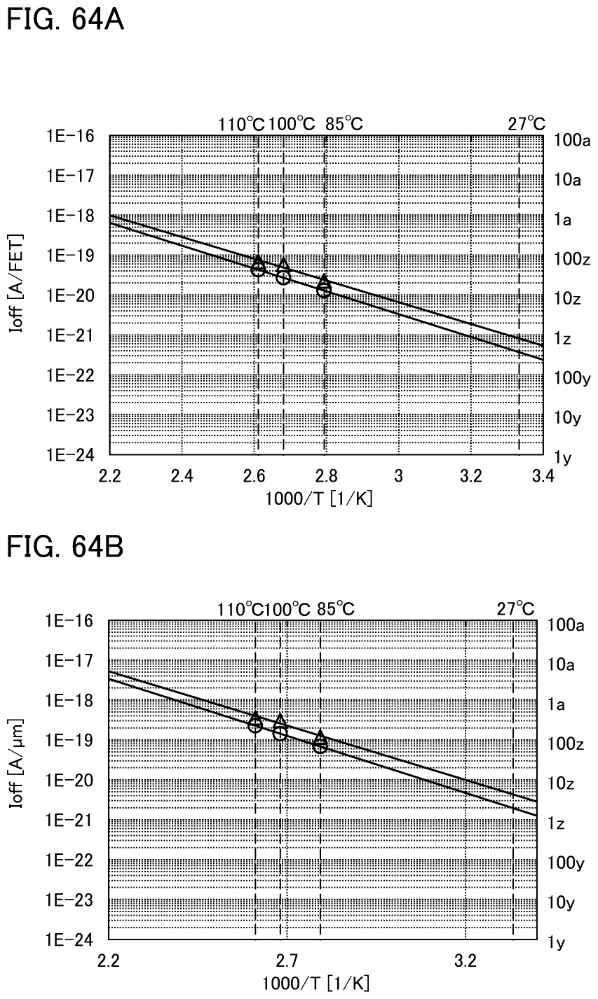

FIG. 64A is an Arrhenius plot showing the results of calculating the off-state currents of the transistors included in each of Sample 3B and Sample 3C. In FIG. 64A, the horizontal axis represents the reciprocal of temperature T (1000/T) [1/K] and the vertical axis represents the off-state current Ioff per transistor [A/FET]. Here, the calculated values of the off-state currents in the environments at 110° C., 100° C., and 85° C. are plotted. The circles represent the calculated values of the off-state currents of the transistors included in Sample 3B, the triangles represent the calculated values of the off-state currents of the transistors included in Sample 3C, and the solid lines represent regression lines obtained from the calculated values.

According to FIG. 64A, in the environment at 85° C., the off-state current per transistor in Sample 3B is 1.29×10⁻²⁰ A/FET and the off-state current per transistor in Sample 3C is 2.25×10⁻²⁰ A/FET. These results reveal that the transistors included in Sample 3B and Sample 3C each have an extremely low off-state current.

FIG. 64B is an Arrhenius plot which shows the results of calculating the off-state currents and in which the vertical axis in FIG. 64A is changed into the off-state current Ioff per micrometer of channel width [A/μm]. According to FIG. 64B, the off-state current per micrometer of channel width of the transistor in Sample 3B is 68.4 zA/μm (6.84×10⁻²⁰ A/μm) in the environment at 85° C. and 1.95 zA/μm (1.95×10⁻²¹ A/μm) in the environment at 27° C. (the extrapolated value). The off-state current per micrometer of channel width of the transistor in Sample 3C is 91.4 zA/μm (9.14×10⁻²⁰ A/μm) in the environment at 85° C.

In this example, Sample 2D was also fabricated. Sample 2D includes a transistor over a substrate and the insulating layer 280. FIG. 47B is a cross-sectional view of the transistor included in Sample 2D. The transistor included in Sample 2D is different from the transistor included in Sample 2A mainly in the structures of the conductive layer 220 and the insulating layer 280. Thus, for the components other than the conductive layer 220 and the insulating layer 280, the description of the components of the transistor included in Sample 2A can be referred to. For the structure of the transistor included in Sample 2D, the structure in FIG. 18 can also be referred to.

In Sample 2D, a stacked-layer structure of a titanium nitride film formed by an ALD method and a tungsten film formed over the titanium nitride film by a CVD method was used as the conductive film to be the conductive layer 220 1. As the conductive film to be the conductive layer 220_2, an ITSO film was formed by a sputtering method. Then, these conductive films were processed to form the conductive layers 220_1 and 220 2.

As the insulating layer 280, first, a silicon nitride film was formed by an ALD method, and a silicon nitride film was formed by a sputtering method over the silicon nitride film. Next, CMP treatment was performed on the silicon nitride film to planarize the top surface of the silicon nitride film. After that, a silicon oxide film was formed by a sputtering method, and a silicon nitride film was formed by a sputtering method.

### [Evaluation 2 of Electrical Characteristics of Transistor]

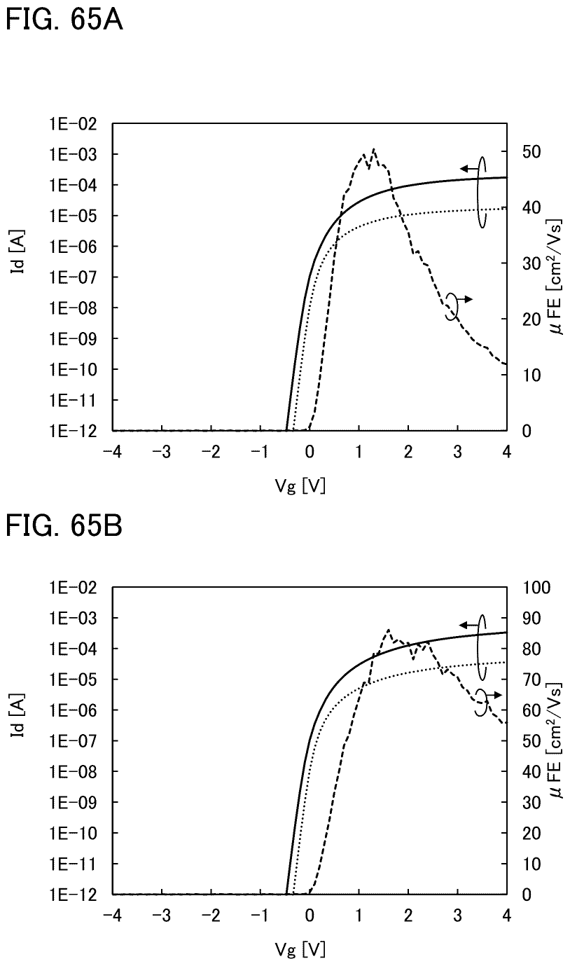

The Id-Vg characteristics of the transistor included in Sample 2D were measured. Here, in the transistor subjected to the measurement, the length L280 shown in FIG. 47B was 105 nm. In the measurement, the drain voltage Vd was 1.2 V or 0.1 V and the gate voltage was swept from −4 V to +4 V in steps of 0.1 V. The measurement temperature was room temperature. FIG. 65A shows the Id-Vg characteristics of the transistor. In FIG. 65A, the first vertical axis on the left represents the drain current Id [A], the second vertical axis on the right represents the field-effect mobility uFE [cm²/Vs], and the horizontal axis represents the gate voltage Vg [V]. In FIG. 65A, the Id-Vg curve at Vd=0.1 V is denoted by a dotted line, the Id-Vg curve at Vd=1.2 V is denoted by a solid line, and the field-effect mobility is denoted by a dashed line.

As shown in FIG. 65A, the transistor included in Sample 2D has excellent electrical characteristics. Specifically, the field-effect mobility uFE of the transistor included in Sample 2D was 50.4 cm²/Vs, the on-state current thereof was 94.8 uA, the S value thereof was 79.6 mV/dec., and the shift voltage Vsh thereof was-0.47 V. The shift voltage Vsh is defined as the value of Vg at the intersection of the tangent with the maximum slope of the Id-Vg curve and Id=1.0×10⁻¹² A. The on-state current here is the value of the drain current Id at Vg=Vsh+2.5 V in the Id-Vg curve at Vd=1.2 V. The same applies to the on-state currents described later.

Here, the Id-Vg characteristics at the time when the external resistance connected to the transistor was zero were estimated. Specifically, the total resistance was calculated from the measured drain current Id and drain voltage Vd. Next, the resistance at the time when the external resistance was zero was calculated by subtracting the external resistance from the total resistance. Note that the external resistance was 3297 Q. Then, conversion into the drain current Id was performed using the calculated resistance and the drain voltage Vd. In this manner, the Id-Vg characteristics at the time when the external resistance was zero were estimated.

A method for estimating the external resistance will be described in detail. Formula (3) below can be obtained from the value of current flowing through a channel of an FET in a linear region (a formula of gradual channel approximation). In Formula (3), W is the channel width of the FET, L is the channel length of the FET, u is the electron mobility, and Cox is the gate capacitance.

$$\begin{matrix}[ Formula 3 ] & \\ {I}_{d} = \frac{W}{L} μ {C}_{o x} [ ( {V}_{g} - {V}_{th} ) {V}_{d} - \frac{1}{2} {V}_{d}^{2} ] & ( 3 )\end{matrix}$$

In consideration of the influence of the external resistance Rext, the external resistance is regarded as being connected in series to the channel resistance of the FET, so that the series resistance can be expressed by Formula (4) below. In Formula (4), Rtotal is the total resistance. [Formula 4]

$$\begin{matrix}[ Formula 4 ] & \\ {R}_{total} = \frac{{V}_{d}}{{I}_{d}} + {R}_{e x t} & ( 4 )\end{matrix}$$

When Formula (3) is substituted into Formula (4) to be simplified as a function of Vg-Vth, the total resistance Rtotal can be expressed by Formula (5) below.

$$\begin{matrix}[ Formula 5 ] & \\ {R}_{total} = \frac{A}{{V}_{d} - {V}_{t h}} + C & ( 5 )\end{matrix}$$

Here, A can be expressed by Formula (6) below.

$$\begin{matrix}[ Formula 6 ] & \\ A = \frac{L}{W μ {C}_{ox}} & ( 6 )\end{matrix}$$

Next, the measured Id-Vg characteristics are fitted using Formula (5) to determine the parameters of A and C. Note that C is a resistance component independent of (Vg-Vth) and thus can be estimated as the external resistance.

FIG. 65B shows the estimated Id-Vg characteristics. According to FIG. 65B, in the case where the external resistance is zero, the field-effect mobility uFE of the transistor included in Sample 2D is 86.0 cm²/Vs and the on-state current thereof is 128.3 uA.

The EOT of the gate insulating layer of the transistor included in Sample 2D was 3.5 nm. Here, the Id-Vg characteristics at the time when the external resistance was zero and the EOT was 1.0 nm were estimated. Note that gate leakage due to a reduction in the thickness of the gate insulating layer was not taken into consideration.

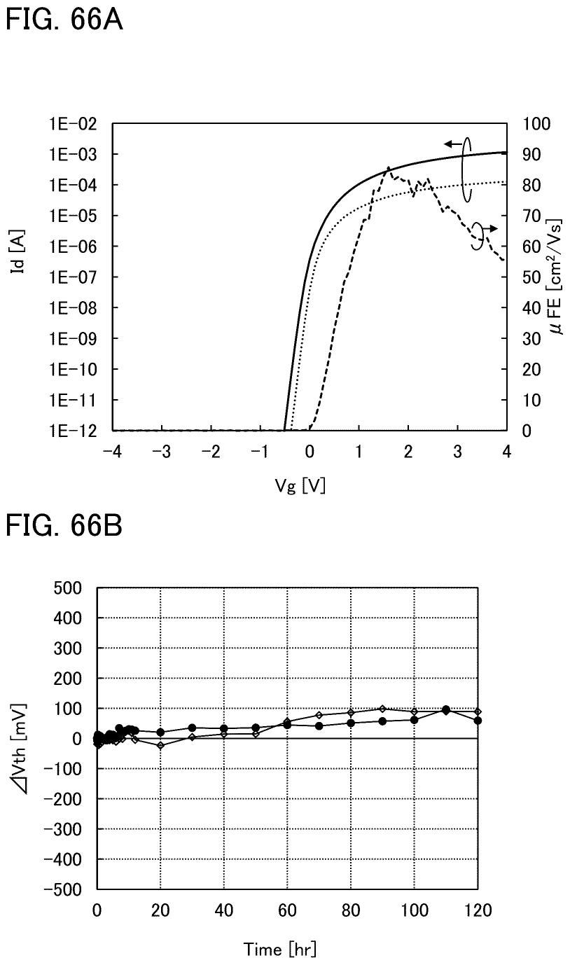

FIG. 66A shows the estimated Id-Vg characteristics. According to FIG. 66A, in the case where the external resistance is zero and the EOT is 1.0 nm, the field-effect mobility μFE of the transistor included in Sample 2D is 85.7 cm²/Vs and the on-state current thereof is 433.7 μA.

Next, the reliability of the transistor included in Sample 2D was evaluated by a +GBT stress test. In a +GBT stress test, while a substrate is being heated, a source electrode and a drain electrode of a transistor are set to the same potential, and a potential higher than the potential applied to the source electrode and the drain electrode is applied to a gate electrode for a certain period of time.

In the +GBT stress test of this example, the set temperature was 125° C., the drain voltage Vd and the source voltage Vs were each 0 V, and the gate voltage Vg was +1.98 V. In this example, two elements were subjected to the stress test.

During the +GBT stress test, Id-Vg measurement was performed at certain intervals. The Id-Vg measurement was performed under the conditions where the drain voltage Vd of the transistor was 0.1 V or 1.2 V, the source voltage Vs was 0 V, and the gate voltage Vg was swept from −1.8 V to +1.8 V. A semiconductor parameter analyzer produced by Keysight Technologies was used for the Id-Vg measurement. In the +GBT stress test, AVth representing the amount of change in the threshold voltage Vth from the start of the measurement was used as an index of the amount of change in the electrical characteristics of the transistor. Here, the threshold voltage (Vth) can be calculated by a root Id method. Note that a root Id method refers to a method in which, in a plot of the Id-Vg characteristics where the horizontal axis represents the gate voltage Vg and the vertical axis represents the square root of drain current Id (Id1/2), gate voltage at the intersection of the straight line of Id1/2-0 (i.e., Vg axis) and the tangent to the curve at a point where the slope of the curve is the maximum is defined as threshold voltage.

FIG. 66B shows the results of the +GBT stress test on Sample 2D. In FIG. 66B, the horizontal axis represents the stress time [hr], and the vertical axis represents ΔVth [mV].

According to FIG. 66B, as for Sample 2D, the amount of change in the threshold voltage (ΔVth) of each of the two elements is less than or equal to 100 mV even after 120-hour stress application. These results reveal that the transistor included in Sample 2D has high reliability.

### [Off-State Current 2]

Sample 3A and Sample 3D each including a DUT were prepared, and the off-state currents of transistors included in each of Sample 3A and Sample 3D were evaluated. For the transistors included in the DUT of Sample 3A, the structure of the transistors included in Sample 2A described above can be referred to. For the transistors included in the DUT of Sample 3D, the structure of the transistor included in Sample 2D described above can be referred to. The width of the opening portion 290 was 60 nm in each of the transistors included in the DUTs of Sample 3A and Sample 3D.

As a comparative example, a reference sample including a silicon transistor (a Si-FET) with a channel width W of 120 nm and a channel length L of 60 nm was prepared.

For a method for evaluating the off-state currents of the transistors included in the DUTs of Sample 3A and Sample 3D, the above description can be referred to. In the evaluation of the off-state currents of the transistors included in Sample 3D, −2.0 V was applied to the gate terminal of each of the transistors included in the DUT, 0 V was applied to the source terminal thereof, and 0.8 V was applied to the drain terminal thereof. In the evaluation of the off-state current of the transistor included in the reference sample, 0 V was applied to the gate terminal and the source terminal of the transistor and 1.2 V was applied to the drain terminal thereof.

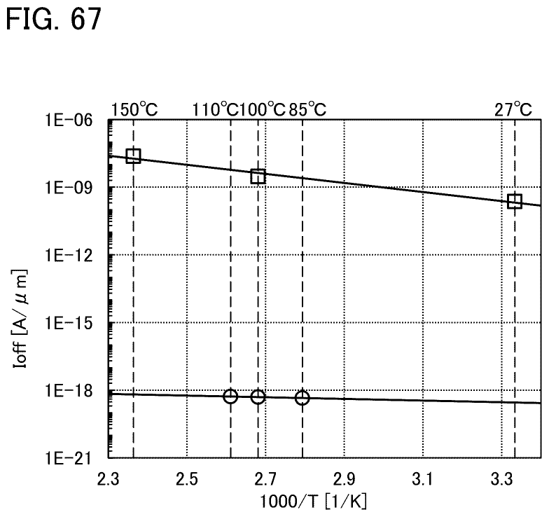

FIG. 67 is an Arrhenius plot showing the results of calculating the off-state currents of the transistors included in Sample 3D and the reference sample. In FIG. 67, the horizontal axis represents the reciprocal of temperature T (1000/T) [1/K] and the vertical axis represents the off-state current Ioff per micrometer of channel width [A/μm]. The circles represent the calculated values of the off-state currents of the transistors included in Sample 3D, the squares represent the calculated values of the off-state current of the silicon transistor, and the solid lines represent regression lines obtained from the calculated values.

According to FIG. 67, the off-state current per micrometer of channel width of the transistor in Sample 3D is 68.4 zA/μm (6.84×10⁻²⁰ A/μm) in the environment at 85° C. and 0.28 aA/μm (0.28 ×10⁻¹⁸ A/μm) in the environment at 27° C. (the extrapolated value). This off-state current in the environment at 27° C. is lower than the off-state current of the silicon transistor in the environment at 27° C. (0.23 nA/μm) by nine or more orders of magnitude. These results reveal that the off-state current and the temperature dependence of the OS transistor are low.

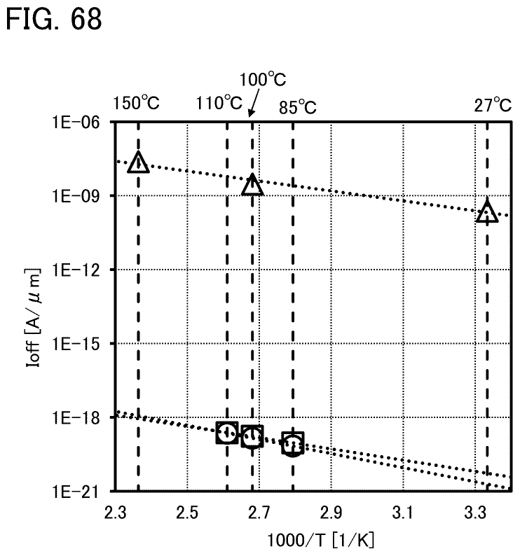

FIG. 68 is an Arrhenius plot showing the results of calculating the off-state currents of the transistors included in Sample 3A, Sample 3B, and the reference sample. In FIG. 68, the horizontal axis represents the reciprocal of temperature T (1000/T) [1/K] and the vertical axis represents the off-state current Ioff per micrometer of channel width [A/μm]. The squares represent the calculated values of the off-state currents of the transistors included in Sample 3A, the circles represent the calculated values of the off-state currents of the transistors included in Sample 3B, the triangles represent the calculated values of the off-state current of the silicon transistor, and the dotted lines represent regression lines obtained from the calculated values. According to FIG. 68, the off-state current per micrometer of channel width of the transistor in Sample 3A is 91.4 zA/μm (9.14×10⁻²⁰ A/μm) in the environment at 85° C.

The structures, configurations, methods, and the like described in this example can be used in an appropriate combination with any of the structures, configurations, methods, and the like described in the other embodiments and the like.

### Example 3

In this example, circuit simulation was performed.

### <Circuit Simulation>

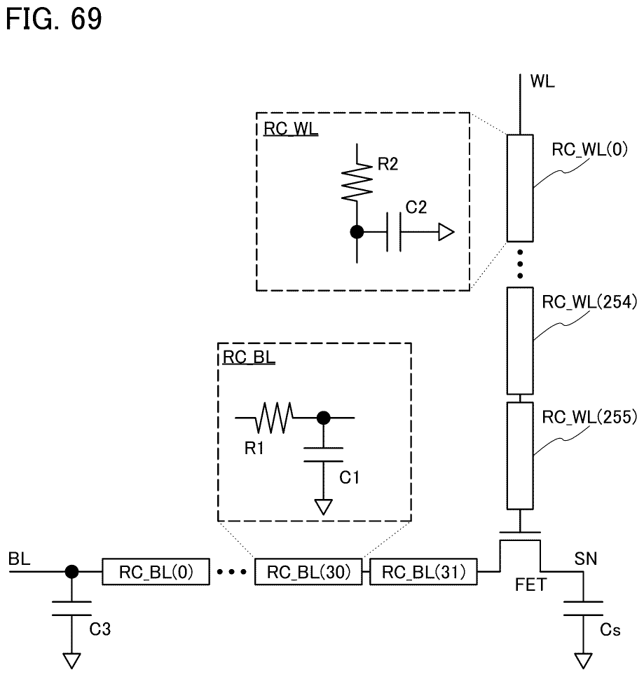

FIG. 69 is a circuit diagram used for the circuit simulation. FIG. 69 includes a memory cell included in a memory array and a circuit connected to a wiring of the memory cell. Specifically, the memory cell has a structure similar to that of the memory cell 951 illustrated in FIG. 30A. To a wiring BL of the memory cell, 32 circuits RC_BL corresponding to a load supplied to the wiring BL from another memory cell included in the memory array are connected. To a wiring WL, 256 circuits RC_WL corresponding to a load supplied from another memory cell included in the memory array are connected. The characteristics of the transistor in Sample 2D fabricated in Example 2 were used for the circuit simulation. Note that the measured threshold value of the Id-Vg characteristics of the transistor was shifted to a threshold value suitable for circuit operation to be used for the simulation.

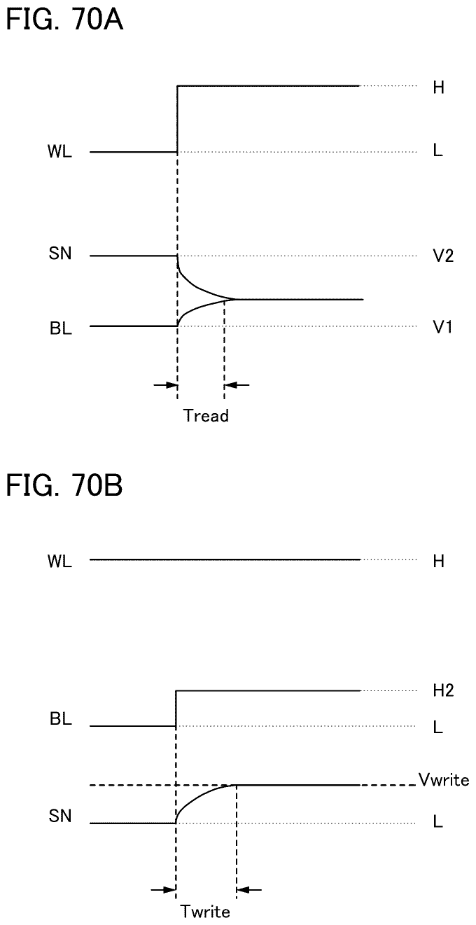

A reading operation is described. In FIG. 70A, a high voltage potential H of the wiring WL has two conditions: 2.0 V and 1.8 V, and a low voltage potential L is set to 0 V. A potential V2 of a node SN is set to 0.54 V. A potential V1 of the wiring BL is set to 0.40 V. A read time Tread is the time until the potentials of the wiring BL and the node SN match 95%.

A writing operation is described. In FIG. 70B, the high voltage potential H of the wiring WL has two conditions: 2.0 V and 1.8 V. A high voltage potential H₂ of the wiring BL is set to 0.8 V, and the low voltage potential L is set to 0 V. In addition, Vwrite is set to 80% (0.64 V) of the high voltage potential H₂ of the wiring BL, and the write time Twrite is the time taken for charging the node SN from 0 V to Vwrite.

The simulation of the writing and reading operations was performed on the assumption that the temperature is from −40° C. to 110° C. Note that in the model used in the circuit simulation, the threshold voltage is changed from the measured electrical characteristics such that a current value corresponds to a retention time of 0.64 seconds.

The necessary amount of change in threshold value is estimated as follows.

First, the necessary amount of change is estimated such that a change in the potential of the node SN is less than or equal to 0.1 V in consideration of a change in off-leakage current according to a change in gate-source voltage of the transistor due to the change in the potential of the node SN. Specifically, the potential of the node SN is changed in steps of 0.1 mV to calculate the time required for the change. The amount of change in current due to a change in the potential of the node SN by 0.1 mV is obtained using the S value calculated from the Id-Vg characteristics, and the amount of change is subtracted from the off-leakage current. By using the off-leakage current at the time when the time required for the change reaches 0.64 seconds, the S value calculated above, and the like, the necessary amount of change in threshold value is estimated to be −1.052 V.

Table 6 and Table 7 show parameters used for the circuit simulation. Table 6 shows the parameters assuming a structure in which the insulating layer 250 is placed between the conductive layer 260 and the conductive layer 240 as in the transistor in FIG. 3A or the like in the above embodiment. Table 7 shows the parameters assuming a structure in which an interlayer film is provided between the conductive layer 240 and the conductive layer 265 connected to the conductive layer 260 to reduce the capacitance between the wirings as in the transistor in FIG. 20A or the like in the above embodiment.

TABLE 6

| | | |
|---|---|---|
| Cs | 3.0 | fF |
| C1 | 0.15 | fF |
| R1 | 32.2 | Ω |
| C2 | 0.15 | fF |
| R2 | 45 | Ω |
| C3 | 1.2 | fF |

TABLE 7

| | | |
|---|---|---|
| Cs | 1.77 | fF |
| C1 | 0.073 | fF |
| R1 | 32.22 | Ω |
| C2 | 0.079 | fF |
| R2 | 45 | Ω |
| C3 | 1.2 | fF |

Table 8 shows the results of calculating the write time Twrite and the read time Tread on the assumption of the operation at a temperature from −40° C. to 110° C. Nine transistors are measured and the standard deviation o is calculated, so that o is 30.9 mV. The simulation was performed on the assumption that the variation is +50.

In Table 8, the description “N” in the structure represents the calculation results using the parameters shown in Table 6, and the description “PU” in the structure represents the calculation results using the parameters shown in Table 7.

TABLE 8

| WL | Structure | Twrite | Tread |
|---|---|---|---|
| 1.8 V | N | 20.1 ns | 5.15 ns |
| | PU | 17.3 ns | 3.70 ns |
| 2.0 V | N | 1.69 ns | 1.65 ns |
| | PU | 1.21 ns | 1.05 ns |

An interlayer film is provided between the conductive layer 265 and the conductive layer 240 to reduce the capacitance between the wirings, whereby both the write time and the read time can be shortened.

Note that in order to examine the influence of a variation in transistor characteristics on the writing characteristics and the reading characteristics, the writing characteristics and the reading characteristics of the case where the standard deviation o is changed are estimated. The high voltage potential H of the wiring WL is set to 1.8 V.

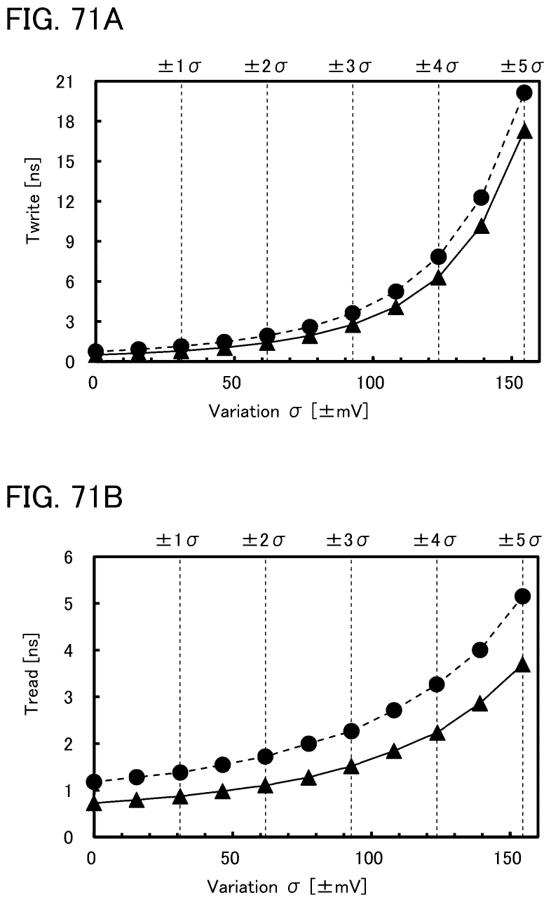

FIGS. 71A and 71B show the calculation results of the write time Twrite and the read time Tread. Note that the solid line represents the case where the parameters shown in Table 7 are used (PU), and the dashed line represents the case where the parameters shown in Table 6 are used (N). In each graph, the horizontal axis represents the value of the standard deviation o as variation. The vertical axis in FIG. 71A represents the write time Twrite, and the vertical axis in FIG. 71B represents the read time Tread.

The above results demonstrate that the memory subjected to the simulation has excellent writing characteristics and excellent reading characteristics.

This application is based on Japanese Patent Application Serial No. 2024-091007 filed with Japan Patent Office on Jun. 4, 2024, Japanese Patent Application Serial No. 2024-107923 filed with Japan Patent Office on Jul. 4, 2024, Japanese Patent Application Serial No. 2024-112390 filed with Japan Patent Office on Jul. 12, 2024, Japanese Patent Application Serial No. 2024-134395 filed with Japan Patent Office on Aug. 9, 2024, and Japanese Patent Application Serial No. 2024-229001 filed with Japan Patent Office on Dec. 25, 2024, the entire contents of which are hereby incorporated by reference.

What is claimed is:

1. A transistor comprising:
an indium oxide film; and
a metal oxide film over the indium oxide film,
wherein the metal oxide film comprises indium, gallium, and zinc, and
wherein a <111> orientation of a crystal in the indium oxide film is parallel or substantially parallel to a <001> orientation of a crystal in the metal oxide film.

2. The transistor according to claim 1, wherein a region of the indium oxide film where a channel is formed is a single crystal.

3. The transistor according to claim 1, wherein a crystal grain boundary is not observed in a region of the indium oxide film where a channel is formed.

4. The transistor according to claim 1, wherein the indium oxide film is provided over a silicon oxide film or a silicon nitride film.

5. A transistor comprising:
a first metal oxide film over a substrate; and
an indium oxide film over the first metal oxide film,
wherein a crystal grain boundary is not observed in a region of the indium oxide film where a channel is formed, and
wherein a resistivity of the first metal oxide film is lower than a resistivity of the indium oxide film.

6. The transistor according to claim 5, wherein a <001> orientation of a crystal in the first metal oxide film is perpendicular or substantially perpendicular to a surface of the substrate.

7. The transistor according to claim 5, wherein the first metal oxide film comprises indium and tin.

8. The transistor according to claim 5, further comprising a second metal oxide film over the indium oxide film,
wherein the first metal oxide film comprises indium, tin, and silicon,
wherein the second metal oxide film comprises indium, gallium, and zinc,
wherein the second metal oxide film has a crystal structure,
wherein a c-axis of the crystal structure is perpendicular or substantially perpendicular to a surface of the substrate, and
wherein the first metal oxide film has an amorphous structure.

9. The transistor according to claim 5, wherein a <111> orientation of a crystal in the indium oxide film is perpendicular or substantially perpendicular to a surface of the substrate.

10. The transistor according to claim 5, further comprising a second metal oxide film over the indium oxide film,
wherein the second metal oxide film comprises indium, gallium, and zinc, and
wherein a <001> orientation of a crystal in the second metal oxide film is perpendicular or substantially perpendicular to a surface of the substrate.

11. A transistor comprising:
a first indium oxide film over a substrate; and
a second indium oxide film over the first indium oxide film,
wherein a crystal axis of a crystal in the second indium oxide film is aligned or substantially aligned with a crystal axis of a crystal in the first indium oxide film, and
wherein a resistivity of the first indium oxide film is lower than a resistivity of the second indium oxide film.

12. The transistor according to claim 11, further comprising a second metal oxide film over the second indium oxide film,
wherein the second metal oxide film comprises indium, gallium, and zinc,
wherein the second metal oxide film has a crystal structure, and
wherein a c-axis of the crystal structure is perpendicular or substantially perpendicular to a surface of the substrate.
